(19) United States
(12) Patent Application Publication
(10) Pub. No.: US 2025/0008780 A1
(43) Pub. Date: Jan. 2, 2025

(54) DISPLAY APPARATUS

(71) Applicant: Semiconductor Energy Laboratory Co., Ltd., Atsugi-shi, Kanagawa-ken (JP)

(72) Inventors: Masataka NAKADA, Tochigi (JP); Masahiro KATAYAMA, Isehara (JP); Rai SATO, Tochigi (JP); Yasuharu HOSAKA, Tochigi (JP); Toshimitsu OBONAI, Shimotsuke (JP); Masayoshi DOBASHI, Shimotsuga (JP); Koji KUSUNOKI, Isehara (JP); Tomonori NAKAYAMA, Atsugi (JP)

(21) Appl. No.: 18/707,700

(22) PCT Filed: Nov. 17, 2022
(86) PCT No.: PCT/IB2022/061057

§ 371 Date: May 6, 2024

(30) Foreign Application Priority Data
Nov. 30, 2021 (JP) 2021-194831

(51) Int. Cl. H10K 59/122; H10K 59/131

(52) U.S. Cl. CPC H10K 59/122; H10K 59/131

(57) ABSTRACT

A display apparatus with high resolution is provided. The display apparatus includes a transistor, a light-emitting device, a first insulating layer, a second insulating layer, and a first conductive layer. The transistor includes a semiconductor layer and a second conductive layer electrically connected to the semiconductor layer. The light-emitting device includes a pixel electrode. The first insulating layer is provided over the transistor and includes a first opening reaching the second conductive layer. The first conductive layer covers the first opening. The second insulating layer is provided over the first insulating layer and includes a second opening in a region overlapping with the first opening. The pixel electrode covers a top surface of the second insulating layer and the second opening. The pixel electrode is electrically connected to the second conductive layer through the first conductive layer. An end portion of the first insulating layer is positioned over the second conductive layer. An end portion of the second insulating layer is positioned over the first conductive layer. An end portion of the second insulating layer is positioned outward from the end portion of the first insulating layer.

### TECHNICAL FIELD

One embodiment of the present invention relates to a display apparatus, a display module, and an electronic device. One embodiment of the present invention relates to a manufacturing method of a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method of driving any of them, and a manufacturing method of any of them.

### BACKGROUND ART

Recent display apparatuses have been expected to be applied to a variety of uses. Usage examples of large-sized display apparatuses include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display apparatuses have been required. As devices requiring high-resolution display apparatuses, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display apparatuses, for example. Light-emitting devices utilizing an electroluminescence (hereinafter referred to as EL) phenomenon (also referred to as EL devices or EL elements) have features such as ease of reduction in thickness and weight, high-speed response to input signals, and driving with a constant DC voltage power source, and have been used in display apparatuses.

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a display apparatus with high resolution. An object of one embodiment of the present invention is to provide a display apparatus with high definition. An object of one embodiment of the present invention is to provide a display apparatus with high display quality. An object of one embodiment of the present invention is to provide a highly reliable display apparatus. An object of one embodiment of the present invention is to provide a novel display apparatus.

An object of one embodiment of the present invention is to provide a method of manufacturing a display apparatus with high resolution. An object of one embodiment of the present invention is to provide a method of manufacturing a display apparatus with high definition. An object of one embodiment of the present invention is to provide a method of manufacturing a display apparatus with high display quality. An object of one embodiment of the present invention is to provide a method of manufacturing a highly reliable display apparatus. An object of one embodiment of the present invention is to provide a method of manufacturing a display apparatus with a high yield. An object of one embodiment of the present invention is to provide a method of manufacturing a novel display apparatus.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a transistor, a light-emitting device, a first insulating layer, a second insulating layer, and a first conductive layer. The transistor includes a semiconductor layer and a second conductive layer electrically connected to the semiconductor layer. The light-emitting device includes a pixel electrode. The first insulating layer is provided over the transistor and includes a first opening reaching the second conductive layer. The first conductive layer covers the first opening. The second insulating layer is provided over the first insulating layer and includes a second opening in a region overlapping with the first opening. The pixel electrode covers a top surface of the second insulating layer and the second opening. The pixel electrode is electrically connected to the second conductive layer through the first conductive layer. An end portion of the first insulating layer is positioned over the second conductive layer. An end portion of the second insulating layer is positioned over the first conductive layer. An end portion of the second insulating layer is positioned outward from the end portion of the first insulating layer.

In the above display apparatus, each of the first insulating layer and the second insulating layer preferably contains an organic material.

The above display apparatus preferably includes a layer. The pixel electrode preferably includes a third conductive layer and a fourth conductive layer over the third conductive layer. The third conductive layer preferably covers the top surface of the second insulating layer and the second opening. The third conductive layer preferably has a depressed portion along a shape of a side surface of the second insulating layer and a top surface of the second conductive layer. The layer is preferably provided to fill the depressed portion. The fourth conductive layer preferably covers a top surface of the third conductive layer and a top surface of the layer. The fourth conductive layer preferably contains a material having a property of reflecting visible light.

In the above display apparatus, the layer is preferably an insulating layer. Alternatively, in the above display apparatus, the layer is preferably a conductive layer.

The above display apparatus preferably includes a third insulating layer. The third insulating layer is preferably provided in contact with the top surface of the second insulating layer. The third insulating layer preferably contains an inorganic material. The pixel electrode preferably includes a region in contact with a top surface of the third insulating layer.

The above display apparatus preferably includes a fourth insulating layer. The fourth insulating layer is preferably provided in contact with the top surface of the first insulating layer. The fourth insulating layer preferably contains an inorganic material. The first conductive layer preferably includes a region in contact with a top surface of the fourth insulating layer.

The above display apparatus preferably includes a fifth insulating layer and a sixth insulating layer. The light-emitting device preferably includes the pixel electrode, a common electrode, and an EL layer interposed between the pixel electrode and the common electrode. The fifth insulating layer preferably covers a side surface and part of a top surface of the EL layer. The sixth insulating layer preferably covers a side surface and part of a top surface of the EL layer with the fifth insulating layer therebetween. The common electrode preferably covers the sixth insulating layer.

In the above display apparatus, the fifth insulating layer preferably contains an inorganic material. The sixth insulating layer preferably contains an organic material.

The above display apparatus preferably includes a fifth insulating layer. The light-emitting device preferably includes the pixel electrode, a common electrode, and an EL layer interposed between the pixel electrode and the common electrode. The fifth insulating layer preferably covers a side surface and part of a top surface of the pixel electrode. The EL layer preferably includes a region in contact with a top surface of the fifth insulating layer. The common electrode preferably covers the fifth insulating layer.

In the above display apparatus, the transistor includes a gate insulating layer interposed between the semiconductor layer and a gate electrode. The semiconductor layer preferably includes metal oxide. The concentration of a metal element included in the metal oxide in the gate insulating layer is preferably lower than or equal to 2× 10¹⁹ atoms/cm³.

### Effect of the Invention

One embodiment of the present invention can provide a display apparatus with high resolution. A display apparatus with high definition can be provided. A display apparatus with high display quality can be provided. A highly reliable display apparatus can be provided. A novel display apparatus can be provided.

One embodiment of the present invention can provide a method of manufacturing a display apparatus with high resolution. A method of manufacturing a display apparatus with high definition can be provided. A method of manufacturing a display apparatus with high display quality can be provided. A method of manufacturing a highly reliable display apparatus can be provided. A method of manufacturing a display apparatus with a high yield can be provided. A method of manufacturing a novel display apparatus can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a top view illustrating an example of a display apparatus.

FIG. 2 is a cross-sectional view illustrating an example of a display apparatus.

FIG. 3A is a cross-sectional view illustrating an example of a display apparatus. FIG. 3B and FIG. 3C are top views illustrating examples of openings.

FIG. 4A and FIG. 4B illustrate band diagrams.

FIG. 5A is a cross-sectional view illustrating an example of a display apparatus. FIG. 5B is a top view illustrating an example of a light-emitting device.

FIG. 6A and FIG. 6B are cross-sectional views illustrating examples of a display apparatus.

FIG. 7A and FIG. 7B are cross-sectional views illustrating examples of a display apparatus.

FIG. 8A and FIG. 8B are cross-sectional views illustrating examples of a display apparatus.

FIG. 9A and FIG. 9B are cross-sectional views illustrating examples of a display apparatus.

FIG. 10A and FIG. 10B are cross-sectional views illustrating examples of a display apparatus.

FIG. 11A and FIG. 11B are cross-sectional views illustrating examples of a display apparatus.

FIG. 12A and FIG. 12B are cross-sectional views illustrating examples of a display apparatus.

FIG. 13 is a cross-sectional view illustrating an example of a display apparatus.

FIG. 14 is a cross-sectional view illustrating an example of a display apparatus.

FIG. 15 is a cross-sectional view illustrating an example of a display apparatus.

FIG. 16 is a cross-sectional view illustrating an example of a display apparatus.

FIG. 17 is a cross-sectional view illustrating an example of a display apparatus.

FIG. 18 is a cross-sectional view illustrating an example of a display apparatus.

FIG. 19 is a top view illustrating an example of a display apparatus.

FIG. 20 is a cross-sectional view illustrating an example of a display apparatus.

FIG. 21A to FIG. 21D are cross-sectional views illustrating an example of a method of manufacturing a display apparatus.

FIG. 22A to FIG. 22C are cross-sectional views illustrating an example of a method of manufacturing a display apparatus.

FIG. 23A and FIG. 23B are cross-sectional views illustrating an example of a method of manufacturing a display apparatus.

FIG. 24A and FIG. 24B are cross-sectional views illustrating an example of a method of manufacturing a display apparatus.

FIG. 25A and FIG. 25B are cross-sectional views illustrating an example of a method of manufacturing a display apparatus.

FIG. 26A and FIG. 26B are cross-sectional views illustrating an example of a method of manufacturing a display apparatus.

FIG. 27A and FIG. 27B are cross-sectional views illustrating an example of a method of manufacturing a display apparatus.

FIG. 28 is a cross-sectional view illustrating an example of a method of manufacturing a display apparatus.

FIG. 29A and FIG. 29B are cross-sectional views illustrating an example of a method of manufacturing a display apparatus.

FIG. 30A and FIG. 30B are cross-sectional views illustrating an example of a method of manufacturing a display apparatus.

FIG. 31A and FIG. 31B are cross-sectional views illustrating an example of a method of manufacturing a display apparatus.

FIG. 32A and FIG. 32B are cross-sectional views illustrating an example of a method of manufacturing a display apparatus.

FIG. 33A and FIG. 33B are cross-sectional views illustrating an example of a method of manufacturing a display apparatus.

FIG. 34A and FIG. 34B are cross-sectional views illustrating an example of a method of manufacturing a display apparatus.

FIG. 35A and FIG. 35B are cross-sectional views illustrating an example of a method of manufacturing a display apparatus.

FIG. 36 is a cross-sectional view illustrating an example of a method of manufacturing a display apparatus.

FIG. 37A and FIG. 37B are cross-sectional views illustrating an example of a method of manufacturing a display apparatus.

FIG. 38 is a cross-sectional view illustrating an example of a method of manufacturing a display apparatus.

FIG. 39A and FIG. 39B are cross-sectional views illustrating an example of a method of manufacturing a display apparatus.

FIG. 40 is a cross-sectional view illustrating an example of a method of manufacturing a display apparatus.

FIG. 41 is a cross-sectional view illustrating an example of a method of manufacturing a display apparatus.

FIG. 42 is a cross-sectional view illustrating an example of a method of manufacturing a display apparatus.

FIG. 43A to FIG. 43G are diagrams illustrating examples of pixels.

FIG. 44A to FIG. 44K are diagrams illustrating examples of a pixel.

FIG. 45 is a perspective view illustrating an example of a display apparatus.

FIG. 46 is a cross-sectional view illustrating an example of a display apparatus.

FIG. 47 is a cross-sectional view illustrating an example of a display apparatus.

FIG. 48 is a cross-sectional view illustrating an example of a display apparatus.

FIG. 49A to FIG. 49F are diagrams illustrating structure examples of a light-emitting device.

FIG. 50A to FIG. 50C are diagrams illustrating structure examples of a light-emitting device.

FIG. 51A and FIG. 51B are diagrams illustrating structure examples of a light-receiving device.

FIG. 51C to FIG. 51E are diagrams illustrating structure examples of a display apparatus.

FIG. 52A to FIG. 52D are diagrams illustrating examples of electronic devices.

FIG. 53A to FIG. 53F are diagrams illustrating examples of electronic devices.

FIG. 54A to FIG. 54G are diagrams illustrating examples of electronic devices.

FIG. 55 is a graph showing the amount of change in electrical characteristics of a transistor by an NBTIS test.

FIG. 56A and FIG. 56C are graphs each showing Id-Vg characteristics of a transistor. FIG. 56B and FIG. 56D are graphs each showing the amount of change in electrical characteristics of a transistor by an NBTIS test.

FIG. 57A to FIG. 57C are graphs showing the metal concentration in an insulating layer.

FIG. 58A and FIG. 58C are graphs showing calculation models. FIG. 58B and FIG. 58D are graphs of density of states obtained by calculation.

FIG. 59A to FIG. 59D are graphs showing the amount of change in electrical characteristics of transistors by an NBTIS test.

FIG. 60 is a cross-sectional STEM image of a sample in Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure in which at least light-emitting layers of light-emitting devices having different emission wavelengths are separately formed may be referred to as a SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other depending on the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to such a shape that at least part of a side surface of a component is inclined with respect to a substrate surface. For example, the tapered shape preferably includes a region where the angle formed by the inclined side surface and the substrate surface (such an angle is also referred to as a taper angle) is less than 90°. Note that the side surface and the substrate surface of the structure are not necessarily completely flat and may be substantially flat with a slight curvature or substantially flat with slight unevenness.

Note that in this specification and the like, a mask layer is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

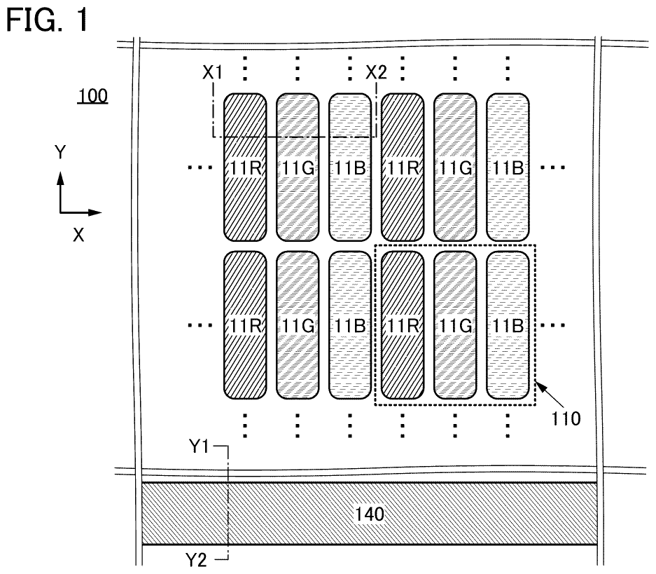

In this embodiment, a display apparatus of one embodiment of the present invention will be described with reference to FIG. 1 to FIG. 20.

One embodiment of the present invention is a display apparatus including a transistor, a light-emitting device, a first insulating layer, a second insulating layer, and a first conductive layer. The first insulating layer is provided over the transistor, the second insulating layer is provided over the first insulating layer, and the light-emitting device is provided over the second insulating layer. The transistor includes a semiconductor layer and a second conductive layer electrically connected to the semiconductor layer. The second conductive layer functions as a source or a drain of the transistor. The first insulating layer includes a first opening reaching the second conductive layer. The first conductive layer is provided to cover the first opening. The second insulating layer includes a second opening in a region overlapping with the first opening. A pixel electrode included in the light-emitting device is provided to cover a top surface of the second insulating layer and the second opening. The pixel electrode is electrically connected to the second conductive layer through the first conductive layer.

The first insulating layer and the second insulating layer each function as a planarization layer. The first insulating layer and the second insulating layer each preferably contain an organic material. When two or more insulating layers functioning as planarization layers are stacked over the transistor, unevenness due to the transistor is reduced, so that the formation surface of the light-emitting device can be flat. Accordingly, the processing accuracy of the light-emitting device can be increased and thus the display apparatus can have high resolution.

The transistor is included in a pixel circuit that controls the light-emitting device. The transistor is electrically connected to the pixel electrode provided to cover the second opening through the first conductive layer provided to cover the first opening. When the second opening is provided in a region overlapping with the first opening, the area occupied by the pixel circuit can be reduced. Thus, the display apparatus can have high resolution. The end portion of the first insulating layer on the first opening side is positioned over the second conductive layer, and the end portion of the second insulating layer on the second opening side is positioned over the first conductive layer. Furthermore, the end portion of the second insulating layer is positioned outward from the end portion of the first insulating layer. In other words, the second insulating layer includes a portion protruding beyond the end portion of the first insulating layer. That is, in a top view (also referred to as a plan view), the second opening is provided inside the first opening. It can also be said that the first opening includes the second opening. With such a structure, the shape of the formation surface of the pixel electrode can be smooth, so that a connection defect of the pixel electrode and an increase in electric resistance can be prevented. Thus, the display apparatus can have high display quality.

FIG. 1 is a top view (also referred to as a plan view) illustrating a display apparatus 100 of one embodiment of the present invention. The display apparatus 100 includes a display portion in which a plurality of pixels 110 are arranged in a matrix and a connection portion 140 outside the display portion. The pixels 110 each include a plurality of subpixels. FIG. 1 illustrates the pixels 110 in two rows and two columns. As the structure where the pixels 110 each include three subpixels (a subpixel 11R, a subpixel 11G, and a subpixel 11B), the subpixels in two rows and six columns are illustrated. The connection portion 140 can also be referred to as a cathode contact portion.

Each subpixel includes a display device (also referred to as a display element). Examples of the display device include a liquid crystal device (also referred to as a liquid crystal element) and a light-emitting device (also referred to as a light-emitting element). As the light-emitting device, an OLED (Organic Light-Emitting Diode) or a QLED (Quantum-dot Light-Emitting Diode) is preferably used, for example. Examples of a light-emitting substance included in the light-emitting device include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material). An LED (Light Emitting Diode) such as a micro-LED can also be used as the light-emitting device.

The emission color of the light-emitting device can be infrared, red, green, blue, cyan, magenta, yellow, white, or the like. When the light-emitting device has a microcavity structure, the color purity can be increased.

In the following description, a structure where a light-emitting device is used as the display device is given as an example.

A display apparatus of one embodiment of the present invention includes light-emitting devices separately formed for respective emission colors and can perform full-color display.

The top surface shapes of the subpixels illustrated in FIG. 1 correspond to the top surface shapes of the light-emitting regions of the light-emitting devices. Examples of the top surface shape of the subpixel include polygons such as a triangle, a quadrangle (including a rectangle and a square), and a pentagon; polygons with rounded corners; an ellipse; and a circle.

Each subpixel includes a pixel circuit controlling the light-emitting device. The pixel circuit is not limited to the range of the subpixels illustrated in FIG. 1, and the components of the circuit may be placed outside the range of the subpixels. For example, transistors included in a pixel circuit of a subpixel 11R may be positioned within the range of a subpixel 11G illustrated in FIG. 1, or some or all of the transistors may be positioned outside the range of the subpixel 11R.

Although FIG. 1 illustrates the subpixel 11R, the subpixel 11G, and a subpixel 11B that have the same or substantially the same aperture ratio (also referred to as the same or substantially the same sizes of light-emitting regions), one embodiment of the present invention is not limited thereto. The aperture ratio of each of the subpixel 11R, the subpixel 11G, and the subpixel 11B can be determined as appropriate. The subpixel 11R, the subpixel 11G, and the subpixel 11B may have different aperture ratios, or two or more of them may have the same or substantially the same aperture ratio.

The pixel 110 illustrated in FIG. 1 employs stripe arrangement. The pixel 110 illustrated in FIG. 1 is composed of three subpixels: the subpixel 11R, the subpixel 11G, and the subpixel 11B. The subpixel 11R, the subpixel 11G, and the subpixel 11B emit light of different colors. The subpixel 11R, the subpixel 11G, and the subpixel 11B are subpixels of three colors of red (R), green (G), and blue (B) or subpixels of three colors of yellow (Y), cyan (C), and magenta (M), for example. The number of color types of subpixels is not limited to three and may be four or more. The four subpixels are subpixels of four colors of R, G, B, and white (W), subpixels of four colors of R, G, B, and Y, or subpixels of four types of R, G, B, and infrared light (IR), for example.

In this specification and the like, the row direction is referred to as X direction and the column direction is referred to as Y direction, in some cases. The X direction and the Y direction intersect with each other and are, for example, orthogonal to each other (see FIG. 1). FIG. 1 illustrates an example in which subpixels of different colors are arranged in the X direction and subpixels of the same color are arranged in the Y direction.

Although the top view in FIG. 1 illustrates an example in which the connection portion 140 is positioned in one side of the display portion, the position of the connection portion 140 is not particularly limited. The connection portion 140 is provided in at least one of the upper side, the right side, the left side, and the lower side of the display portion in the top view, and may be provided so as to surround the four sides of the display portion. The top surface shape of the connection portion 140 is not particularly limited and can be a belt-like shape, an L shape, a U shape, a frame-like shape, or the like. The number of the connection portions 140 can be one or more.

### Structure Example 1 of Display Apparatus

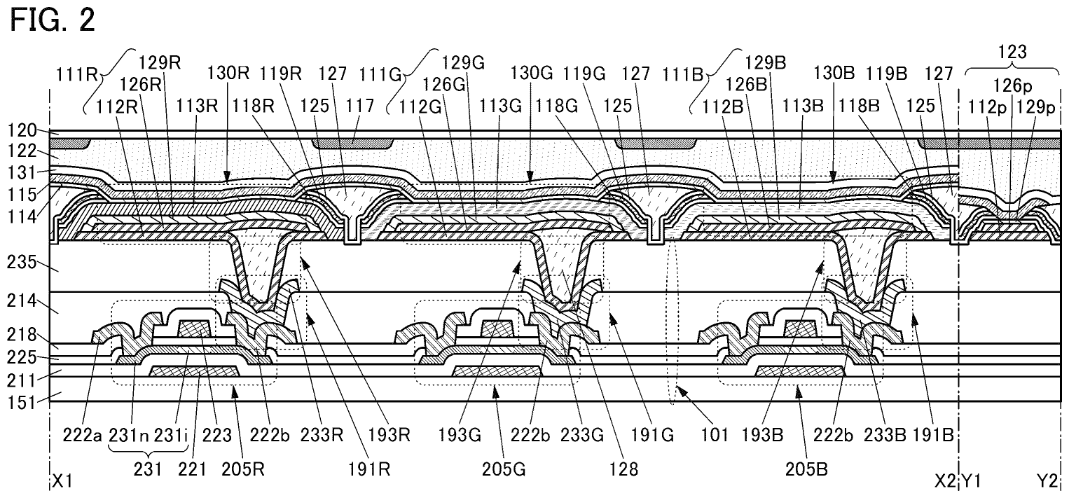

FIG. 2 is a cross-sectional view taken along the dashed-dotted line X1-X2 and the dashed-dotted line Y1-Y2 in FIG. 1.

As illustrated in FIG. 2, in the display apparatus 100, a light-emitting device 130R, a light-emitting device 130G, and a light-emitting device 130B are provided over a layer 101, and a protective layer 131 is provided to cover these light-emitting devices. A substrate 120 is attached onto the protective layer 131 with a resin layer 122.

The layer 101 includes a transistor 205R, a transistor 205G, and a transistor 205B. An insulating layer 214 and an insulating layer 235 over the insulating layer 214 are provided to cover the transistor 205R, the transistor 205G, and the transistor 205B. The insulating layer 214 includes an opening 191R, an opening 191G, and an opening 191B, and a conductive layer 233R, a conductive layer 233G, and a conductive layer 233B are provided to cover the openings. The insulating layer 235 includes an opening 193R, an opening 193G, and an opening 193B, and electrodes of the light-emitting device 130R, the light-emitting device 130G, and the light-emitting device 130B are provided to cover the openings. The light-emitting device 130R is electrically connected to the transistor 205R through the conductive layer 233R. The light-emitting device 130G is electrically connected to the transistor 205G through the conductive layer 233G. The light-emitting device 130B is electrically connected to the transistor 205B through the conductive layer 233B.

Note that in the case of describing matters common to the light-emitting device 130R, the light-emitting device 130G, and the light-emitting device 130B, these light-emitting devices are sometimes referred to as a light-emitting device 130 by omitting the alphabets that distinguish them from each other. In the same manner, in the description common to the components that are distinguished by alphabets, such as the transistor 205R, the transistor 205G, and the transistor 205B, reference numerals without alphabets are sometimes used.

Each of the light-emitting device 130R, the light-emitting device 130G, and the light-emitting device 130B includes a pair of electrodes and a layer interposed between the pair of electrodes. The layer includes at least a light-emitting layer. One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130R includes a pixel electrode 111R over the insulating layer 235, the island-shaped layer 113R over the pixel electrode 111R, a common layer 114 over the island-shaped layer 113R, and a common electrode 115 over the common layer 114. In the light-emitting device 130R, the layer 113R and the common layer 114 can be collectively referred to as an EL layer.

The light-emitting device 130G includes a pixel electrode 111G over the insulating layer 235, an island-shaped layer 113G over the pixel electrode 111G, the common layer 114 over the island-shaped layer 113G, and the common electrode 115 over the common layer 114. In the light-emitting device 130G, the layer 113G and the common layer 114 can be collectively referred to as an EL layer.

The light-emitting device 130B includes a pixel electrode 111B over the insulating layer 235, an island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113R, the layer 113G, or the layer 113B, and the layer shared by the plurality of light-emitting devices is referred to as the common layer 114. Note that in this specification and the like, the layer 113R, the layer 113G, and the layer 113B are sometimes referred to as island-shaped EL layers, EL layers formed in an island shape, or the like, in which case the common layer 114 is not included.

The layer 113R, the layer 113G, and the layer 113B each have an island shape and are separated from one another. When the EL layer is provided in an island shape for each light-emitting device, a leakage current between adjacent light-emitting devices can be inhibited. This can prevent crosstalk due to unintended light emission, so that a display apparatus with extremely high contrast can be obtained. Specifically, a display apparatus having high current efficiency at low luminance can be obtained.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 preferably includes a pixel circuit having a function of controlling the light-emitting device 130. The pixel circuit can include a transistor, a capacitor, and a wiring, for example. Note that the layer 101 may include one or both of a gate line driver circuit (a gate driver) and a source line driver circuit (a source driver) in addition to the pixel circuit. The layer 101 may further include one or both of an arithmetic circuit and a memory circuit.

The layer 101 can have a structure where a pixel circuit is provided over a semiconductor substrate or an insulating substrate. As the semiconductor substrate, a single crystal semiconductor substrate or a polycrystalline semiconductor substrate using silicon or silicon carbide as a material, a compound semiconductor substrate of silicon germanium or the like, or an SOI substrate can be used. As the insulating substrate, a glass substrate, a quartz substrate, a sapphire substrate, a ceramic substrate, or an organic resin substrate can be used. Note that the shape of the semiconductor substrate and the insulating substrate may be circular or square. As the semiconductor substrate and the insulating substrate, a substrate having at least heat resistance high enough to withstand heat treatment performed later can be used.

The layer 101 can have a stacked-layer structure in which a plurality of transistors are provided over a substrate 151 and an insulating layer is provided to cover these transistors, for example. FIG. 2 illustrates the transistor 205R, the transistor 205G, and the transistor 205B as transistors included in the layer 101. Note that FIG. 2 is a cross-sectional view of the transistor 205R, the transistor 205G, and the transistor 205B in the channel length direction.

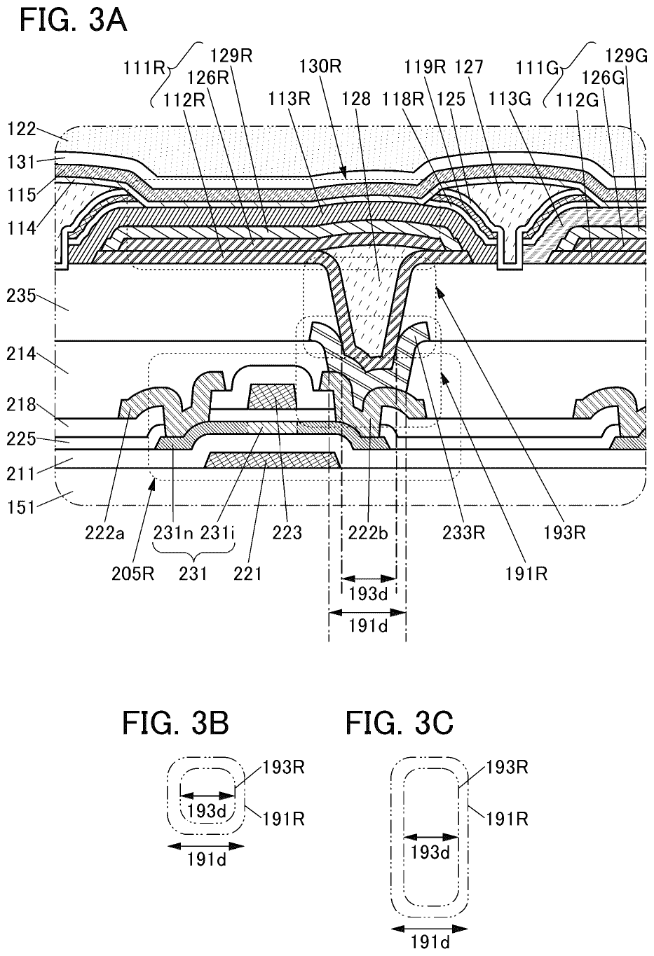

A transistor that can be used in the display apparatus of one embodiment of the present invention will be described using the transistor 205R as an example. FIG. 3A is an enlarged view of the transistor 205R, the light-emitting device 130R, and the vicinity thereof illustrated in FIG. 2.

The transistor 205R includes a semiconductor layer 231, an insulating layer 218, and a conductive layer 223 that are stacked in this order. Part of the insulating layer 225 functions as a gate insulating layer of the transistor 205R. The conductive layer 223 functions as a gate electrode of the transistor 205R. The transistor 205R is what is called a top-gate transistor, in which the gate electrode is provided over the semiconductor layer 231. The semiconductor layer 231 includes a channel formation region 231i and a pair of low-resistance regions 231n. The channel formation region 231i includes a region overlapping with the conductive layer 223 with the insulating layer 218 therebetween.

The transistor 205R further includes the insulating layer 218, a conductive layer 222a, and a conductive layer 222b. The insulating layer 218 is provided over the insulating layer 225 and the conductive layer 223. The insulating layer 218 and the insulating layer 225 include openings reaching the low-resistance regions 231n. The conductive layer 222a and the conductive layer 222b are provided to cover the openings. The conductive layer 222a is electrically connected to one of the pair of low-resistance regions 231n, and the conductive layer 222b is electrically connected to the other of the pair of low-resistance regions 231n. One of the conductive layer 222a and the conductive layer 222b functions as a source, and the other functions as a drain. The transistor 205R can be referred to as a TGSA (Top Gate Self Align) transistor.

The insulating layer 218 has a function of a protective layer of the transistor 205R. It is further preferable to use a material that does not easily allow diffusion of impurities for the insulating layer 218. Providing the insulating layer 218 can effectively inhibit diffusion of impurities into the transistors from the outside and increase the reliability of the display apparatus. Examples of the impurities include water and hydrogen. The insulating layer 218 can be an insulating layer containing an inorganic material or an insulating layer containing an organic material. For example, an inorganic insulating material such as oxide or nitride can be suitably used for the insulating layer 218. More specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or both of an acrylic resin and a polyimide resin can be used. As the organic material, a photosensitive material may be used. A stack including two or more of the above insulating films may also be used. The insulating layer 218 may have a stacked-layer structure of an insulating layer containing an inorganic material and an insulating layer containing an organic material.

A structure may be employed in which a gate is provided above and below the semiconductor layer 231 and the semiconductor layer 231 is interposed between the two gates. As illustrated in FIG. 2 and FIG. 3A, the transistor 205R includes a conductive layer 221 and an insulating layer 211 between the substrate 151 and the semiconductor layer 231. The conductive layer 221 includes a region overlapping with the semiconductor layer 231 with the insulating layer 211 therebetween and a region overlapping with the conductive layer 223 with the semiconductor layer 231 therebetween.

In the transistor 205R, the conductive layer 223 has a function of a first gate electrode (also referred to as a top gate electrode), and the conductive layer 221 has a function of a second gate electrode (also referred to as a bottom gate electrode). In the transistor 205R, part of the insulating layer 225 functions as a first gate insulating layer, and part of the insulating layer 211 functions as a second gate insulating layer. A portion of the semiconductor layer 231 that overlaps with at least one of the conductive layer 223 and the conductive layer 221 functions as a channel formation region of the transistor 205R. Note that for easy explanation, a portion of the semiconductor layer 231 that overlaps with the conductive layer 223 is sometimes referred to as a channel formation region; however, a channel can also be actually formed in a portion not overlapping with the conductive layer 223 and overlapping with the conductive layer 221 (a portion including the low-resistance regions 231n).

The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

The transistor 205G and the transistor 205B can each have the same structure as the transistor 205R. The description of the transistor 205R can be referred to for the transistor 205G and the transistor 205B; thus, the detailed description thereof is omitted. Note that the transistor 205R, the transistor 205G, and the transistor 205B may have different structures.

The semiconductor layer 231 of a transistor 205 included in the display apparatus of one embodiment of the present invention preferably includes metal oxide (also referred to as an oxide semiconductor or OS) showing semiconductor characteristics. That is, a transistor including metal oxide in its channel formation region (hereinafter also referred to as an OS transistor) is preferably used for the display apparatus of this embodiment. An OS transistor has extremely higher field-effect mobility than a transistor containing amorphous silicon. In addition, the OS transistor has extremely low leakage current between a source and a drain in an off state (hereinafter also referred to as off-state current), and electric charge accumulated in a capacitor that is connected in series to the transistor can be retained for a long period. Furthermore, power consumption of the display apparatus can be reduced with the use of an OS transistor.

Here, in some cases, the display apparatus is used in an environment with high temperatures or strong external light. In the display apparatus, part of light emitted from the light-emitting device 130 reaches the transistor 205 in some cases. When the electrical characteristics of the transistor are changed by the high temperatures or light, the display quality of the display apparatus might be decreased. For this reason, the transistor 205 used in the display apparatus preferably has a small change in electrical characteristics caused by high temperatures and light, that is, the transistor 205 preferably has high reliability. With use of highly reliable transistors against high temperatures and light for a display apparatus, the display apparatus can have high display quality and high reliability.

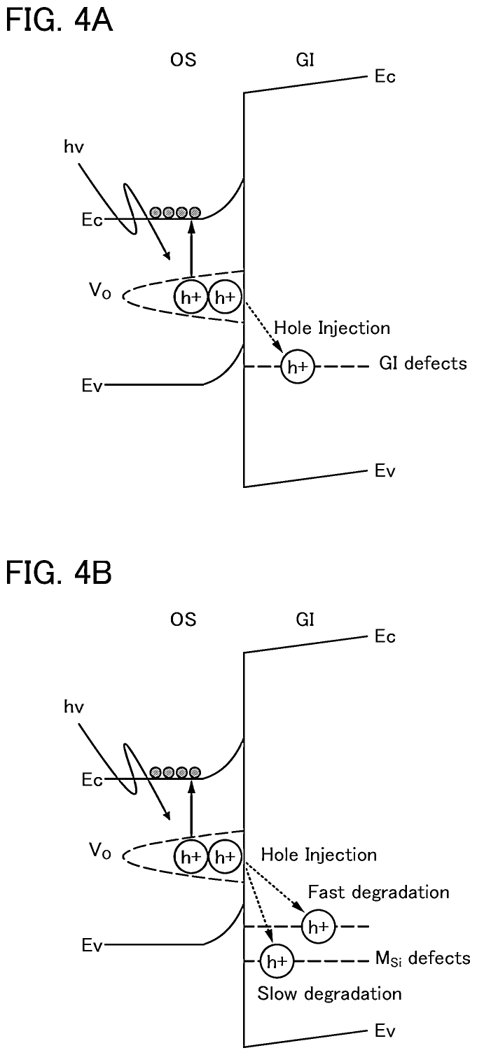

The mechanism of change in electrical characteristics of an OS transistor due to light is described with reference to FIG. 4A. In FIG. 4A, a band diagram of metal oxide (OS) included in the semiconductor layer 231 is illustrated on the left side, and a band diagram of oxide containing silicon included in the insulating layer 225 functioning as a gate insulating layer (GI) is illustrated on the right side. Note that in FIG. 4A, a hole is shown by a circle with “h+” and an electron is shown by a black circle.

The mechanism of change in electrical characteristics of an OS transistor due to light is estimated as follows. First, when metal oxide is irradiated with light (hv), an electron (a carrier) in the valence band (Ev) or a deep density of states (dDOS) of the metal oxide is excited into the conduction band (Ec). The deep density of states of the metal oxide is presumed to be attributed to oxygen vacancies (Vo) in the metal oxide. Next, holes are generated in the valence band (Ev) or the deep density of states of the metal oxide by electron excitation into the conduction band (Ec) of the metal oxide. When a negative bias is applied between the gate and the source, holes are accumulated at the interface between the metal oxide and the gate insulating layer and in the vicinity thereof. At this time, when defect states (“GI defects” in FIG. 4A) exists at the interface and in its vicinity, a hole is trapped by the defect states (“Hole Injection” in FIG. 4A). Consequently, the threshold voltage of the OS transistor is shifted in the negative direction.

The number of defect states included in the insulating layer 225 functioning as the gate insulating layer is preferably small. For the insulating layer 225, an oxide containing silicon can be used, for example. Specifically, for the insulating layer 225, silicon oxide or silicon oxynitride can be used. In this case, as examples of defect states in the gate insulating layer, an oxygen atom bonded to one silicon atom and a nitrogen atom bonded to two silicon atoms are given. Note that the oxygen atom bonded to one silicon atom is referred to as a non-bridging oxygen hole center (NBOHC) and the nitrogen atom bonded to two silicon atoms is referred to as No in some cases. NBOHC and No each include a dangling bond, and when a hole is trapped by the dangling bond, the threshold voltage might be changed. Thus, the insulating layer 225 preferably has few NBOHC and No.

As the defect state in the insulating layer 225, a state derived from a defect caused by diffusion of atoms contained in metal oxide to the insulating layer 225 is given. For example, a defect in which a silicon atom contained in the insulating layer 225 is replaced with a metal atom contained in the metal oxide is given. When the metal oxide is an In—Ga—Zn oxide, a defect in which a silicon atom is replaced with an indium atom, a gallium atom, or a zinc atom is given as the defect. In this specification and the like, a defect in which a silicon atom is replaced with an indium atom is referred to as In_{Si}, a defect in which a silicon atom is replaced with a gallium atom is referred to as Ga_{Si}, and a defect in which a silicon atom is replaced with a zin atom is referred to as Zn_{Si}. Note that it is found from the first-principles calculation that Zn_{Si} generation energy is higher than each of In_{Si} generation energy and Ga_{Si} generation energy. Thus, Zn_{Si} is estimated to be less likely to be generated than In_{Si} and Ga_{Si}. Note that in this specification and the like, defects in which a silicon atom contained in the insulating layer 225 is replaced with a metal atom contained in the metal oxide are collectively referred to as M_{Si} in some cases (“M_{Si} defects” in FIG. 4B). For example, in the case where an In—Ga—Zn oxide is used for the semiconductor layer 231, In_{Si}, Ga_{Si}, and Zn_{Si} are collectively referred to as M_{Si} in some cases.

From the time dependence of the amount of change in threshold voltage in the NBTIS test, it is considered that the NBTIS degradation has two or more degradation factors with different time constants. A degradation factor with a large time constant is derived from M_{Si}, and a degradation factor with a small time constant is derived from a defect other than M_{Si} (e.g., NBOHC and No). FIG. 4B shows a state derived from M_{Si} and a state derived from a defect other than M_{Si} (e.g., NBOHC and No). In addition, a degradation with a small time constant, that is, a degradation with a high speed (“Fast degradation” in FIG. 4B), and a degradation with a large time constant, that is, a degradation with a low speed (“Slow degradation” in FIG. 4B), are schematically indicated by arrows.

The metal oxide included in the semiconductor layer 231 preferably has high crystallinity. When the crystallinity of the metal oxide is high, a metal element contained in the metal oxide can be prevented from diffusing into the insulating layer 225. Thus, formation of In_{Si}, Ga_{Si}, and Zn_{Si} can be inhibited.

In the insulating layer 225, the concentration of the metal element contained in the metal oxide is preferably low. The concentration of the metal element in the insulating layer 225 is preferably lower than or equal to 2×10¹⁹ atoms/cm³, further preferably lower than or equal to 1×10¹⁹ atoms/cm³, still further preferably lower than or equal to 8×10¹⁸ atoms/cm³, yet still further preferably lower than or equal to 5×10¹⁸ atoms/cm³. The concentration of the metal element in the insulating layer 225 can be measured by secondary ion mass spectrometry (SIMS), for example. For example, in the case where an In—Ga—Zn oxide is used for the semiconductor layer 231, the indium concentration, the gallium concentration, and the zinc concentration in the insulating layer 225 are preferably within the above ranges. Note that the concentration of the metal element in the insulating layer 225 is preferably as low as possible; thus, the lower limit of the concentration is not necessarily provided.

Note that also in the case where the conductive layer 221 is provided as the second gate electrode (also referred to as a bottom gate electrode) as illustrated in FIG. 2 and the like, the concentration of the metal element contained in the metal oxide in the insulating layer 225 functioning as the first gate insulating layer is preferably within the above ranges. Furthermore, in the insulating layer 211 functioning as the second gate insulating layer, the concentration of the metal element contained in the metal oxide is preferably within the above ranges.

One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

A transistor used in the display apparatus of one embodiment of the present invention has preferably small change in electrical characteristics especially in an NBTIS test (hereinafter also referred to as NBTIS degradation).

Although the TGSA transistor is described as an example here, there is no particular limitation on the structure of the transistor that can be used in the display apparatus of one embodiment of the present invention.

The insulating layer 214 and the insulating layer 235 over the insulating layer 214 are provided over the transistor 205R, the transistor 205G, and the transistor 205B. Each of the insulating layer 214 and the insulating layer 235 has a function of reducing unevenness due to the transistor 205R, the transistor 205G, and the transistor 205B and planarizing a top surface of the layer 101. Note that in this specification and the like, each of the insulating layer 214 and the insulating layer 235 is referred to as a planarization layer in some cases.

As each of the insulating layer 214 and the insulating layer 235, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

Alternatively, for each of the insulating layer 214 and the insulating layer 235, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for each of the insulating layer 214 and the insulating layer 235, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used. For the insulating layer 214 and the insulating layer 235, the same organic material or different organic materials may be used.

The insulating layer 214 may have a stacked-layer structure of an organic insulating layer and an inorganic insulating layer. For example, the insulating layer 214 can have a stacked-layer structure of an organic insulating layer and an inorganic insulating layer over the organic insulating layer. An inorganic insulating layer provided on the outermost surface of the insulating layer 214 can function as an etching protective layer. This can inhibit a decrease in the flatness of the insulating layer 214, which is caused by etching of part of the insulating layer 214 in the formation of the conductive layer 233. Similarly, the insulating layer 235 may have a stacked-layer structure of an organic insulating layer and an inorganic insulating layer. This can inhibit a decrease in the flatness of the insulating layer 235, which is caused by etching of part of the insulating layer 235 in the formation of the pixel electrode 111 and the layer 113. Alternatively, the insulating layer 214 may have a stacked-layer structure of an inorganic insulating layer and an organic insulating layer over the inorganic insulating layer. The same applies to the insulating layer 235.

By providing two or more insulating layers functioning as planarization layers over the transistor 205R, the transistor 205G, and the transistor 205B, a formation surface of the light-emitting device 130 (here, the insulating layer 235) can be flat.

Here, the low flatness of the top surface of the insulating layer 235, which is the formation surface of the light-emitting device 130, might cause a defect such as a connection defect due to disconnection of the common electrode or an increase in electric resistance due to the locally thinned regions of the common electrode 115. In addition, the low flatness of the top surface of the insulating layer 235 might lower the processing accuracy of the layer to be formed over the insulating layer 235.

In the display apparatus of one embodiment of the present invention, by providing two or more insulating layers functioning as planarization layers over the transistor 205R, the transistor 205G, and the transistor 205B, the formation surface of the light-emitting device 130 can be flat. Accordingly, making the top surface of the insulating layer 235 flat increases the processing accuracy of the light-emitting device 130 and the like provided over the insulating layer 235, whereby the display apparatus can have high resolution. Furthermore, since a connection defect due to disconnection of the common electrode and an increase in electric resistance due to the locally thinned regions of the common electrode 115 can be prevented, the display apparatus can have high display quality.

Although a stacked-layer structure of two insulating layers functioning as planarization layers (the insulating layer 214 and the insulating layer 235) is described here, one embodiment of the present invention is not limited thereto. The stacked-layer structure may include three or more insulating layers functioning as planarization layers. Although each of the insulating layer 214 and the insulating layer 235 has a single-layer structure in FIG. 2 and the like, one embodiment of the present invention is not limited thereto. The insulating layer 214 and the insulating layer 235 may each have a stacked-layer structure.

The insulating layer 214 includes the opening 191R, the opening 191G, and the opening 191B.

The opening 191R includes a region overlapping with the conductive layer 222b of the transistor 205R, and the conductive layer 222b of the transistor 205R is exposed in the opening 191R. The conductive layer 233R is provided to cover the opening 191R. The conductive layer 233R includes a region in contact with a side surface of the insulating layer 214 and a top surface of the conductive layer 222b of the transistor 205R. The conductive layer 233R may include a region in contact with a top surface of the insulating layer 214.

The opening 191G includes a region overlapping with the conductive layer 222b of the transistor 205G, and the conductive layer 222b of the transistor 205G is exposed in the opening 191G. The conductive layer 233G is provided to cover the opening 191G. The conductive layer 233G includes a region in contact with a side surface of the insulating layer 214 and a top surface of the conductive layer 222b of the transistor 205G. The conductive layer 233G may include a region in contact with a top surface of the insulating layer 214.

The opening 191B includes a region overlapping with the conductive layer 222b of the transistor 205B, and the conductive layer 222b of the transistor 205B is exposed in the opening 191B. The conductive layer 233B is provided to cover the opening 191B. The conductive layer 233B includes a region in contact with a side surface of the insulating layer 214 and a top surface of the conductive layer 222b of the transistor 205B. The conductive layer 233B may include a region in contact with a top surface of the insulating layer 214.

The insulating layer 235 includes the opening 193R, the opening 193G, and the opening 193B.

The opening 193R includes a region overlapping with the conductive layer 233R, and the conductive layer 233R is exposed in the opening 193R. The pixel electrode 111R is provided to cover the opening 193R. The pixel electrode 111R includes a region in contact with a side surface of the insulating layer 235 and a top surface of the conductive layer 233R. That is, the light-emitting device 130R is electrically connected to the transistor 205R through the conductive layer 233R.

The opening 193G includes a region overlapping with the conductive layer 233G, and the conductive layer 233G is exposed in the opening 193G. The pixel electrode 111G is provided to cover the opening 193G. The pixel electrode 111G includes a region in contact with a side surface of the insulating layer 235 and a top surface of the conductive layer 233G. That is, the light-emitting device 130G is electrically connected to the transistor 205G through the conductive layer 233G.

The opening 193B includes a region overlapping with the conductive layer 233B, and the conductive layer 233B is exposed in the opening 193B. The pixel electrode 111B is provided to cover the opening 193B. The pixel electrode 111B includes a region in contact with a side surface of the insulating layer 235 and a top surface of the conductive layer 233B. That is, the light-emitting device 130B is electrically connected to the transistor 205B through the conductive layer 233B.

The opening 191R is provided over the conductive layer 222b of the transistor 205R. Similarly, the opening 191G is provided over the conductive layer 222b of the transistor 205G. The opening 191B is provided over the conductive layer 222b of the transistor 205B. That is, the end portion of the insulating layer 214 is preferably positioned over the conductive layer 222b of the transistor 205R, the conductive layer 222b of the transistor 205G, and the conductive layer 222b of the transistor 205B. In FIG. 3A, a width 191d of the opening 191R in the cross-sectional view is indicated by a double-headed arrow. The width 191d can also be regarded as a distance between end portions of the insulating layer 214 that face each other over the conductive layer 222b of the transistor 205R.

The opening 193R is provided over the conductive layer 233R. Similarly, the opening 193G is provided over the conductive layer 233G. The opening 193B is provided over the conductive layer 233B. That is, the end portion of the insulating layer 235 is preferably positioned over the conductive layer 233R, the conductive layer 233G, and the conductive layer 233B. In FIG. 3A, a width 193d of the opening 193R in the cross-sectional view is indicated by a double-headed arrow. The width 193d can also be regarded as a distance between end portions of the insulating layer 235 that face each other over the conductive layer 233R.

The conductive layer 222b, the conductive layer 233R, and the pixel electrode 111R of the transistor 205R preferably include a region where they overlap with one another. Similarly, the conductive layer 222b, the conductive layer 233G, and the pixel electrode 111G of the transistor 205G preferably include a region where they overlap with one another. The conductive layer 222b, the conductive layer 233B, and the pixel electrode 111B of the transistor 205B preferably include a region where they overlap with one another. The opening 193R preferably includes a region overlapping with the opening 191R. The opening 193G preferably includes a region overlapping with the opening 191G. The opening 193B preferably includes a region overlapping with the opening 191B. When the opening 193R, the opening 193G, and the opening 193G are provided in regions overlapping with the opening 191R, the opening 191G, and the opening 191B, respectively, the area occupied by the pixel circuit can be reduced. Accordingly, the display apparatus can have high resolution.

Examples of the top surface shapes of the opening 191R, the opening 191G, the opening 191B, the opening 193R, the opening 193G, and the opening 193B include a triangular shape, a quadrangular shape (including a rectangular shape and a square shape), a polygonal shape, these shapes with rounded corners, an elliptical shape, and a circular shape. FIG. 3B and FIG. 3C illustrate examples of the top surface shapes of the opening 191R and the opening 193R. Each of the top views of FIG. 3B and FIG. 3C illustrates an example in which the opening 191R, the opening 191G, the opening 191B, the opening 193R, the opening 193G, and the opening 193B have rounded corners. Note that the top surface shapes of the opening 191R, the opening 191G, and the opening 191B may be the same as or different from one another. The top surface shapes of the opening 193R, the opening 193G, and the opening 193B may be the same as or different from one another. The top surface shapes of the opening 191R, the opening 191G, and the opening 191B may be the same as or different from the top surface shapes of the opening 193R, the opening 193G, and the opening 193B. For example, in the top view, the opening 191R, the opening 191G, and the opening 191B may have shapes with rounded corners, and the opening 193R, the opening 193G, and the opening 193B may have circular shapes.

As illustrated in FIG. 3B and FIG. 3C, the opening 193R is preferably positioned inside the opening 191R. Similarly, the opening 193G is preferably positioned inside the opening 191G. The opening 193G is preferably positioned inside the opening 191G. That is, the end portion of the insulating layer 214 is preferably positioned outward from the end portion of the insulating layer 235. In the case where the opening 193R is provided inside the opening 191R, the unevenness on the formation surface of the pixel electrode 111R can be reduced and thus the formation surface can be smooth, and connection defects due to disconnection of the pixel electrode 111R can be inhibited as compared with the case where the opening 193R is provided outside the opening 191R. Furthermore, an increase in electric resistance which occurs when the thickness of the pixel electrode 111R is locally thinned can be inhibited. Similarly, by providing the opening 193G inside the opening 191G, the shape of the formation surface of the pixel electrode 111G can be smooth, so that a connection defect of the pixel electrode 111G and an increase in electric resistance can be prevented. By providing the opening 193B inside the opening 191B, the shape of the formation surface of the pixel electrode 111B can be smooth, so that a connection defect of the pixel electrode 111B and an increase in electric resistance can be prevented. Thus, the display apparatus can have high display quality. Since the area occupied by the opening 193R, the opening 193G, the opening 193G, the opening 191R, the opening 191G, and the opening 191B are reduced, the area occupied by the pixel circuit is reduced; thus, the display apparatus can have high resolution.

The width 191d and the width 193d are each preferably small. When the width 191d and the width 193d are small, the area occupied by the pixel circuit is reduced, so that the display apparatus can be obtained. The width 191d is, for example, preferably less than or equal to 6 μm, further preferably less than or equal to 4 μm, still further preferably less than or equal to 3 μm, yet still further preferably less than or equal to 2 μm. The width 193d is preferably less than or equal to 6 μm, further preferably less than or equal to 4 μm, still further preferably less than or equal to 3 μm, yet still further preferably less than or equal to 2 μm. The display apparatus in which the width 191d and the width 193d are small can have high resolution.

Furthermore, the width 193d is preferably smaller than the width 191d. When the width 193d is smaller than the width 191d, the shape of the formation surface of the pixel electrode 111 can be smooth, a connection defect due to disconnection of the pixel electrode 111 can be inhibited. Furthermore, an increase in electric resistance which occurs when the thickness of the pixel electrode 111 is locally thinned can be inhibited.

Note that the top surface shape of the opening 191 corresponds to the shape of the end portion of the insulating layer 214 in the top view. In the top view, the width 191d of the opening 191 refers to the shorter side of the smallest rectangle that is circumscribed around the opening 191. Similarly, the top surface shape of the opening 193 corresponds to the shape of the end portion of the insulating layer 235 in the top view. In the top view, the width 193d of the opening 193 refers to the shorter side of the smallest rectangle that is circumscribed around the opening 193.

The pixel electrode 111R, the pixel electrode 111G, and the pixel electrode 111B included in the light-emitting device 130R, the light-emitting device 130G, and the light-emitting device 130B, respectively, are described.

The pixel electrode 111R included in the light-emitting device 130R has a stacked-layer structure including a conductive layer 112R, a conductive layer 126R over the conductive layer 112R, and a conductive layer 129R over the conductive layer 126R. Similarly, the pixel electrode 111G included in the light-emitting device 130G has a stacked-layer structure including a conductive layer 112G, a conductive layer 126G over the conductive layer 112G, and a conductive layer 129G over the conductive layer 126G. The pixel electrode 111B included in the light-emitting device 130B has a stacked-layer structure including a conductive layer 112B, a conductive layer 126B over the conductive layer 112B, and a conductive layer 129B over the conductive layer 126B.

The conductive layer 112R is electrically connected to the conductive layer 233R through the opening 193R provided in the insulating layer 235. The conductive layer 112R is electrically connected to the conductive layer 222b included in the transistor 205 through the conductive layer 233R. The end portion of the conductive layer 112R is positioned outward from the end portion of the conductive layer 126R. The end portion of the conductive layer 126R is positioned inward from the end portion of the conductive layer 129R. The end portion of the conductive layer 112R is positioned inward from the end portion of the conductive layer 129R. In other words, the end portion of the conductive layer 126R is positioned over the conductive layer 112R. The end portion of the conductive layer 129R is positioned over the conductive layer 112R. A top surface and a side surface of the conductive layer 126R are covered with the conductive layer 129R.

For the conductive layer 112R, no particular limitations are imposed on the properties of transmitting and reflecting visible light. As the conductive layer 112R, a conductive layer having a property of transmitting visible light or a conductive layer having a property of reflecting visible light can be used. As the conductive layer having a property of transmitting visible light, an oxide conductive layer can be used, for example. Specifically, an In—Si—Sn oxide (also referred to as ITSO) can be suitably used as the conductive layer 112R. Examples of the conductive layer having a property of reflecting visible light include metal such as aluminum, titanium, chromium, nickel, copper, yttrium, zirconium, silver, tin, zinc, platinum, gold, molybdenum, tantalum, and tungsten, and an alloy containing the metal as its main component (e.g., an alloy of silver, palladium, and copper (APC: Ag—Pd—Cu)). The conductive layer 112R may have a stacked-layer structure of a conductive layer having a property of transmitting visible light and a conductive layer having a property of reflecting visible light over the conductive layer. For the conductive layer 112R, a material with high adhesion to the formation surface of the conductive layer 112R (here, the insulating layer 235) is preferably used. Accordingly, film separation of the conductive layer 112R can be inhibited.

As the conductive layer 126R, a conductive layer having a property of transmitting visible light can be used. The conductive layer 126R may have a stacked-layer structure of a conductive layer having a property of transmitting visible light and a conductive layer having a property of reflecting visible light over the conductive layer. For the conductive layer 126R, a material that can be used for the conductive layer 112R can be used. Specifically, a stacked-layer structure of In—Si—Sn oxide (ITSO) and an alloy of silver, palladium, and copper (APC) over the In—Si—Sn oxide (ITSO) can be suitably used as the conductive layer 126R.

For the conductive layer 129R, a material that can be used for the conductive layer 112R can be used. As the conductive layer 129R, a conductive layer having a property of transmitting visible light can be used. Specifically, In—Si—Sn oxide (ITSO) can be used for the conductive layer 129R.

In the case where a material that is easily oxidized is used for the conductive layer 126R, a material that is not easily oxidized is used for the conductive layer 129R and the conductive layer 126R is covered with the conductive layer 129R, whereby oxidation of the conductive layer 129R can be inhibited. In addition, precipitation of a metal component included in the conductive layer 126R can be inhibited. For example, in the case where a material containing silver is used for the conductive layer 126R, In—Si—Sn oxide (ITSO) can be suitably used for the conductive layer 126R. Thus, oxidation of the conductive layer 126R can be inhibited, and precipitation of silver can be inhibited

The structure of the pixel electrode 111 that can be applied to the display apparatus of one embodiment of the present invention is not limited to the structure of the pixel electrode 111 illustrated in FIG. 2 and the like.

Detailed description of the conductive layer 112G, the conductive layer 126G, and the conductive layer 129G of the light-emitting device 130G and the conductive layer 112B, the conductive layer 126B, and the conductive layer 129B of the light-emitting device 130B is omitted because these conductive layers are similar to the conductive layer 112R, the conductive layer 126R, and the conductive layer 129R of the light-emitting device 130R.

The conductive layer 112R, the conductive layer 112G, and the conductive layer 112B are formed to cover the opening 193R, the opening 193G, and the opening 193B provided in the insulating layer 235. A layer 128 is embedded in each of the depressed portions of the conductive layer 112R, the conductive layer 112G, and the conductive layer 112B.

The layer 128 has a planarization function for the depressed portions of the conductive layer 112R, the conductive layer 112G, and the conductive layer 112B. The conductive layer 126R, the conductive layer 126G, and the conductive layer 126B electrically connected to the conductive layer 112R, the conductive layer 112G, and the conductive layer 112B, respectively, are provided over the conductive layer 112R, the conductive layer 112G, the conductive layer 112B, and the layer 128. Thus, regions overlapping with the depressed portions of the conductive layer 112R, the conductive layer 112G, and the conductive layer 112B can also function as the light-emitting regions, increasing the aperture ratio of the pixels.

There is no particular limitation on the conductivity of the layer 128, and the layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 127 can be used, for example.

When the layer 128 is a conductive layer, the layer 128 can serve as part of a pixel electrode.

A top surface of the conductive layer 112R and a top and side surfaces of the conductive layer 129R are covered with the layer 113R. Similarly, a top surface of the conductive layer 112G and a top and side surface of the conductive layer 129G are covered with the layer 113G, and a top and side surface of the conductive layer 126B and a top and side surfaces of the conductive layer 129B are covered with the layer 113B. Accordingly, regions provided with the conductive layer 126R, the conductive layer 126G, and the conductive layer 126B can be entirely used as the light-emitting regions of the light-emitting device 130R, the light-emitting device 130G, and the light-emitting device 130B, increasing the aperture ratio of the pixels.

End portions of the pixel electrode 111R, the pixel electrode 111G, and the pixel electrode 111B each preferably have a tapered shape. Specifically, each of the end portions of the pixel electrode 111R, the pixel electrode 111G, and the pixel electrode 111B preferably has a tapered shape with a taper angle less than 90°. When the pixel electrode 111R, the pixel electrode 111G, and the pixel electrode 111B have tapered side surfaces, the coverage with the EL layer provided along the top surfaces and side surfaces of the pixel electrode 111R, the pixel electrode 111G, and the pixel electrode 111B can be improved.

In some cases, the insulating layer 235 is partly removed when the pixel electrode 111R, the pixel electrode 111G, and the pixel electrode 111B are formed. The insulating layer 235 may have a concave portion in a region overlapping with none of the pixel electrode 111R, the pixel electrode 111G, and the pixel electrode 111B.

Part of the insulating layer 235 is sometimes removed at the time of forming the layer 113R, the layer 113G, and the layer 113B. FIG. 2 illustrates an example in which the insulating layer 235 has a depressed portion in a region overlapping with neither the layer 113R, the layer 113G, nor the layer 113B.

In FIG. 2, an insulating layer (also referred to as a bank or a spacer) covering an end portion of the top surface of the pixel electrode 111R is not provided between the pixel electrode 111R and the layer 113R. An insulating layer covering an end portion of the top surface of the pixel electrode 111G is not provided between the pixel electrode 111G and the layer 113G. Thus, the distance between adjacent light-emitting devices can be short. Accordingly, the display apparatus can have a high resolution or a high definition. In addition, a mask for forming the insulating layer is not needed, which leads to a reduction in manufacturing cost of the display apparatus.

Light emitted from the EL layer can be extracted efficiently with a structure in which an insulating layer covering the end portion of the pixel electrode is not provided between the pixel electrode and the EL layer, i.e., a structure in which an insulating layer is not provided between the pixel electrode and the EL layer. Therefore, the display apparatus of one embodiment of the present invention can significantly reduce the viewing angle dependence. A reduction in the viewing angle dependence leads to an increase in visibility of an image on the display apparatus. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction.

The light-emitting device of this embodiment may have either a single structure (a structure including only one light-emitting unit) or a tandem structure (a structure including a plurality of light-emitting units). The light-emitting unit includes at least one light-emitting layer.

The light-emitting device 130R emits red (R) light, the light-emitting device 130G emits green (G) light, and the light-emitting device 130B emits blue (B) light. The layer 113R, the layer 113G, and the layer 113B each include at least a light-emitting layer. The EL layer 113R includes a light-emitting layer emitting red light, the layer 113G includes a light-emitting layer emitting green light, and the layer 113B includes a light-emitting layer emitting blue light. In other words, the layer 113R contains a light-emitting material emitting red light, the layer 113G contains a light-emitting material emitting green light, and the layer 113B contains a light-emitting material emitting blue light.

In the case of using a light-emitting device having a tandem structure, the layer 113R is preferably configured to include a plurality of light-emitting units emitting red light, the layer 113G is preferably configured to include a plurality of light-emitting units emitting green light, and the layer 113B is preferably configured to include a plurality of light-emitting units emitting blue light. A charge-generation layer is preferably provided between the light-emitting units.

The layer 113R, the layer 113G, and the layer 113B may each include one or more of a hole-injection layer, a hole-transport layer, a hole-blocking layer, a charge-generation layer, an electron-blocking layer, an electron-transport layer, and an electron-injection layer.

For example, the layer 113R, the layer 113G, and the layer 113B may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

For another example, the layer 113R, the layer 113G, and the layer 113B may each include an electron-injection layer, an electron-transport layer, a light-emitting layer, and a hole-transport layer in this order. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Thus, the layer 113R, the layer 113G, and the layer 113B each preferably include a light-emitting layer and a carrier-transport layer (an electron-transport layer or a hole-transport layer) over the light-emitting layer. Alternatively, the layer 113R, the layer 113G, and the layer 113B each preferably include a light-emitting layer and a carrier-blocking layer (a hole-blocking layer or an electron-blocking layer) over the light-emitting layer. Alternatively, the layer 113R, the layer 113G, and the layer 113B each preferably include a light-emitting layer, a carrier-blocking layer over the light-emitting layer, and a carrier-transport layer over the carrier-blocking layer. Since the surfaces of the layer 113R, the layer 113G, and the layer 113B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved.

The upper temperature limits of the compounds contained in the layer 113R, the layer 113G, and the layer 113B are each preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition point (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C.

In particular, the upper temperature limits of the functional layers provided over the light-emitting layer are preferably high. It is further preferable that the upper temperature limit of the functional layer provided over and in contact with the light-emitting layer be high. When the functional layer has high heat resistance, the light-emitting layer can be effectively protected and damage to the light-emitting layer can be reduced.

The upper temperature limit of the light-emitting layer is preferably high. In this case, the light-emitting layer can be inhibited from being damaged by heating and being decreased in emission efficiency and lifetime.

The light-emitting layer contains a light-emitting substance (also referred to as a light-emitting material, a light-emitting organic compound, or a guest material) and an organic compound (also referred to as a host material). Since the light-emitting layer is configured to contain more organic compound than light-emitting substance, Tg of the organic compound can be used as an indicator of the upper temperature limit of the light-emitting layer.

The layer 113R, the layer 113G, and the layer 113B may each include a first light-emitting unit, a charge-generation layer over the first light-emitting unit, and a second light-emitting unit over the charge-generation layer, for example.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved. Note that in the case where three or more light-emitting units are provided, the uppermost light-emitting unit preferably includes a light-emitting layer and one or both of a carrier-transport layer and a carrier-blocking layer over the light-emitting layer.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

In a region between the adjacent light-emitting devices 130, an insulating layer 125 and an insulating layer 127 over the insulating layer 125 are provided. Although FIG. 2 and the like illustrate a plurality of cross sections of the insulating layer 125 and the insulating layer 127, the insulating layer 125 and the insulating layer 127 are each one continuous layer when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other, and may include a plurality of insulating layers 127 that are separated from each other.

FIG. 2 and the like illustrate an example in which the end portion of the layer 113R is positioned outward from the end portion of the pixel electrode 111R. Note that although description is made using the pixel electrode 111R and the layer 113R as an example, the same applies to the pixel electrode 111G and the layer 113G, and the pixel electrode 111B and the layer 113B.

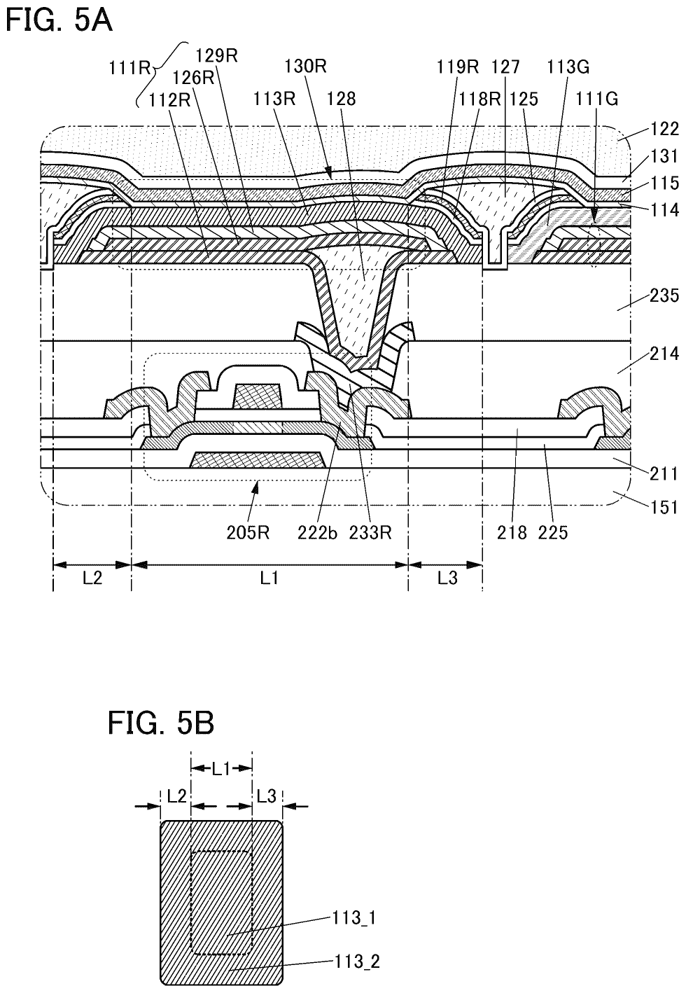

FIG. 5A is an enlarged view of the light-emitting device 130R, the transistor 205R, and the vicinity thereof illustrated in FIG. 2. FIG. 5B is a top view of the layer 113R. The layer 113R is formed to cover the end portion of the pixel electrode 111R. Such a structure enables the entire top surface of the pixel electrode to be a light-emitting region, and the aperture ratio can be easily increased as compared with the structure in which the end portion of the island-shaped EL layer is positioned inward from the end portion of the pixel electrode.

Covering the side surface of the pixel electrode 111 with the EL layer inhibits contact between the pixel electrode 111 and the common electrode 115, thereby inhibiting a short circuit of the light-emitting device 130. Furthermore, the distance between the light-emitting region (i.e., the region overlapping with the pixel electrode 111) in the EL layer and the end portion of the EL layer can be increased. Since the end portion of the EL layer might be damaged by processing, the use of a region away from the end portion of the EL layer as a light-emitting region can improve the reliability of the light-emitting device 130 in some cases.

The layer 113R, the layer 113G, and the layer 113B each preferably include a first region 113_1 that is a light-emitting region and a second region 113_2 on the outer side of the first region 113_1, as illustrated in FIG. 5B. The first region 113_1 is positioned between the pixel electrode 111R and the common electrode 115 in FIG. 5A. In the layer 113R, the first region 113_1 is a portion being in contact with the pixel electrode 111R and overlapping with the common electrode 115 with the common layer 114 therebetween. The first region 113_1 is covered with the mask layer during the manufacturing process of the display apparatus and thus subjected to reduced damage. Accordingly, a light-emitting device with high emission efficiency and a long lifetime can be achieved. Meanwhile, the second region 113_2 includes an end portion of the EL layer and the vicinity thereof, which might be damaged due to exposure to plasma in the manufacturing process of the display apparatus. By not using the second region as a light-emitting region, variation in characteristics of the light-emitting devices can be reduced. The second region can be referred to as a dummy region.

In FIG. 5A and FIG. 5B, a width L1 of the first region 113_1 which is a light-emitting region in the layer 113R is indicated by arrows. A width L2 and a width L3 of the second region 113_2 which is a dummy region in the layer 113R are indicated by arrows. As illustrated in FIG. 5B, the second region 113_2 is provided to surround the first region 113_1; thus, in the cross-sectional view of FIG. 5A and the like, the second region 113_2 can be observed in two portions between which the first region 113_1 is sandwiched. The width L1 to the width L3 can be observed in a cross-sectional observation image or the like.

The second region 113_2 is a portion where the layer 113R overlaps with at least one of a mask layer 118R, a mask layer 119R, the insulating layer 125, and the insulating layer 127.

Each of the width L2 and the width L3 of the second region 113_2 is preferably greater than or equal to 1 nm, further preferably greater than or equal to 5 nm, still further preferably greater than or equal to 50 nm, yet still further preferably greater than or equal to 100 nm. The width of the second region 113_2 that is a dummy region is preferably wider, in which case the quality of the light-emitting region can be more uniform and the light-emitting devices can have less variation in characteristics.

By contrast, a narrower width of the second region 113_2 can widen the light-emitting region and increase the aperture ratio of the pixel. Thus, each of the width L2 and the width L3 of the second region 113_2 is preferably less than or equal to 50%, further preferably less than or equal to 40%, still further preferably less than or equal to 30%, yet still further preferably less than or equal to 20%, yet still further preferably less than or equal to 10% of the width L1 of the first region 113_1. For example, each of the width L2 and the width L3 of the second region 113_2 in a small and high-resolution display apparatus, such as a display apparatus for a wearable device, is preferably less than or equal to 500 nm, further preferably less than or equal to 300 nm, still further preferably less than or equal to 200 nm, yet still further preferably less than or equal to 150 nm.

Note that in the island-shaped EL layer, the first region (light-emitting region) is a region from which EL (Electroluminescence) emission is obtained. Furthermore, in the island-shaped EL layer, the first region (light-emitting region) and the second region (dummy region) are each a region from which PL (Photoluminescence) emission is obtained. Thus, the first region and the second region can be distinguished from each other by observing EL emission and PL emission.

The common electrode 115 is shared by the light-emitting device 130R, the light-emitting device 130G, and the light-emitting device 130B. The common electrode 115 shared by the plurality of light-emitting devices is electrically connected to a conductive layer 123 provided in the connection portion 140 (see FIG. 2). The conductive layer 123 is preferably formed using a conductive layer formed using the same material and in the same step as the pixel electrode 111R, the pixel electrode 111G, and the pixel electrode 111B. For example, the conductive layer 123 can have a stacked-layer structure of a conductive layer 112p, a conductive layer 126p over the conductive layer 112p, and a conductive layer 129p over the conductive layer 126p. The conductive layer 112p can be formed in the same step as the conductive layer 112R, the conductive layer 112G, and the conductive layer 112B. The conductive layer 126p can be formed in the same step as the conductive layer 126R, the conductive layer 126G, and the conductive layer 126B. The conductive layer 129p can be formed in the same step as the conductive layer 129R, the conductive layer 129G, and the conductive layer 129B.

Note that FIG. 2 illustrates a structure in which the thickness of the conductive layer 129p is different from the thicknesses of the conductive layer 129R, the conductive layer 129G, and the conductive layer 129B. These thicknesses of the conductive layer 129p, the conductive layer 129R, the conductive layer 129G, and the conductive layer 129B may be different depending on the resistivities of materials used for these layers. In the case of making the thicknesses different, the conductive layer 129p may be formed in a step different from a step of forming the conductive layer 129R, the conductive layer 129G, and the conductive layer 129B. Alternatively, some formation steps may be common between the conductive layer 129p and the conductive layer 129R, the conductive layer 129G, and the conductive layer 129B.

The common layer 114 is not necessarily provided in the connection portion 140. FIG. 2 illustrates a structure in which the common electrode 115 is provided over the conductive layer 123. Note that an example in which the common layer 114 is provided over the conductive layer 123 and the conductive layer 123 and the common electrode 115 are electrically connected to each other through the common layer 114 may be employed. For example, by using a mask for specifying a film formation area (also referred to as an area mask or a rough metal mask to be distinguished from a fine metal mask), the common layer 114 and the common electrode 115 can be formed in different regions.

As illustrated in FIG. 2, the mask layer 118R and the mask layer 119R are positioned over the layer 113R included in the light-emitting device 130R, the mask layer 118G and the mask layer 119G are positioned over the layer 113G included in the light-emitting device 130G, and the mask layer 118B and the mask layer 119B are positioned over the layer 113B included in the light-emitting device 130B. The mask layer 118 and the mask layer 119 are provided to surround the first region 113_1 (light-emitting region). In other words, the mask layers have an opening in a portion overlapping with the light-emitting region. The top surface shape of the mask layer is the same or substantially the same as, or similar to that of the second region 113_2. The mask layer 118R and the mask layer 119R are remaining parts of the mask layers provided over the layer 113R at the time of forming the layer 113R. In a similar manner, the mask layer 118G and the mask layer 119G are remaining parts of the mask layers provided at the time of forming the layer 113G, and the mask layer 118B and the mask layer 119B are remaining parts of the mask layers provided at the time of forming the layer 113B. Thus, the mask layer used to protect the EL layer in manufacture of the display apparatus may partly remain in the display apparatus of one embodiment of the present invention.

For any two or all of the mask layer 118R, the mask layer 118G, and the mask layer 118B, the same material may be used or different materials may be used. Similarly, for any two or all of the mask layer 119R, the mask layer 119G, and the mask layer 119B, the same material may be used or different materials may be used. Note that the mask layer 118R, the mask layer 118G, and the mask layer 118B are sometimes collectively referred to as a mask layer 118. The mask layer 119R, the mask layer 119G, and the mask layer 119B may be collectively referred to as a mask layer 119.

As illustrated in FIG. 2, one end portion of the mask layer 118R and one end portion of the mask layer 119R (outer end portions which are opposite to the light-emitting region side) are aligned or substantially aligned with the end portion of the layer 113R, and the other end portion of the mask layer 118R and the other end portion of the mask layer 119R (inner end portions which are on the light-emitting region side) are positioned over the layer 113R. Here, the other end portion of the mask layer 118R and the other end portion of the mask layer 119R preferably overlap with the layer 113R and the pixel electrode 111R. In this case, the other end portion of the mask layer 118R and the other end portion of the mask layer 119R are easily formed over a flat or substantially flat surface of the layer 113R. Note that the same applies to the mask layer 118G, the mask layer 119G, the mask layer 118B, and the mask layer 119B. The mask layer 118 and the mask layer 119 remain between the top surface of the EL layer processed into an island shape (the layer 113R, the layer 113G, or the layer 113B) and the insulating layer 125.

In the case where end portions are aligned or substantially aligned with each other and the case where top surface shapes are the same or substantially the same, it can be said that outlines of stacked layers at least partly overlap with each other in a top view. For example, the case of processing the upper layer and the lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions are substantially aligned with each other” or the expression “top surface shapes are substantially the same”.

The side surfaces of the layer 113R, the layer 113G, and the layer 113B are each covered with the insulating layer 125. The insulating layer 127 overlaps with the side surfaces of the layer 113R, the layer 113G, and the layer 113B with the insulating layer 125 therebetween.

The top surfaces of the layer 113R, the layer 113G, and the layer 113B are each partly covered with the mask layer 118. The mask layer 119 is provided over the mask layer 118. The insulating layer 125 and the insulating layer 127 overlap with parts of the top surfaces of the layer 113R, the layer 113G, and the layer 113B with the mask layer 118 and the mask layer 119 therebetween.

The side surface and part of the top surface of each of the layer 113R, the layer 113G, and the layer 113B are covered with at least one of the insulating layer 125, the insulating layer 127, the mask layer 118, and the mask layer 119, so that the common layer 114 (or the common electrode 115) can be inhibited from being in contact with the side surfaces of the pixel electrode 111R, the pixel electrode 111G, the pixel electrode 111B, the layer 113R, the layer 113G, and the layer 113B, leading to inhibition of a short circuit of the light-emitting device. Accordingly, the reliability of the light-emitting device can be improved.

Although FIG. 2 illustrates the layer 113R, the layer 113G, and the layer 113B that have the same thickness, the present invention is not limited thereto. The layers 113R, 113G, and 113B may have different thicknesses. For example, the thickness is preferably set to match an optical path length that intensifies light emitted from the layer 113R, the layer 113G, and the layer 113B. A microcavity structure can be achieved in this manner, and the color purity of light emitted from each light-emitting device 130 can be increased.

The insulating layer 125 is preferably in contact with the side surfaces of the layer 113R, the layer 113G, and the layer 113B. The insulating layer 125 is configured to be in contact with the layer 113R, the layer 113G, and the layer 113B, whereby film separation of the layer 113R, the layer 113G, and the layer 113B can be prevented. When the insulating layer 125 is in close contact with the layer 113B, the layer 113G, or the layer 113R, the layer 113B and the like that are adjacent each other can be fixed or bonded to each other by the insulating layer 125. Accordingly, the reliability of the light-emitting device can be improved. The manufacturing yield of the light-emitting device can also be improved.

As illustrated in FIG. 2, the insulating layer 125 and the insulating layer 127 cover the side surface and part of the top surface of each of the layer 113R, the layer 113G, and the layer 113B, whereby film separation of the EL layers can further be prevented and the reliability of the light-emitting device can be improved. The manufacturing yield of the light-emitting device can also be improved.

In the example illustrated in FIG. 2, a stacked-layer structure of the layer 113R, the mask layer 118R, the mask layer 119R, the insulating layer 125, and the insulating layer 127 is provided over the end portion of the pixel electrode 111R. Similarly, a stacked-layer structure of the layer 113G, the mask layer 118G, the mask layer 119G, the insulating layer 125, and the insulating layer 127 is provided over the end portion of the pixel electrode 111G; and a stacked-layer structure of the layer 113B, the mask layer 118B, the mask layer 119B, the insulating layer 125, and the insulating layer 127 is provided over the end portion of the pixel electrode 111B.

In FIG. 2, the end portion of the pixel electrode 111R is covered with the layer 113R and the insulating layer 125 is in contact with the side surface of the layer 113R. Similarly, the end portion of the pixel electrode 111G is covered with the layer 113G, the end portion of the pixel electrode 111B is covered with the layer 113B, and the insulating layer 125 is in contact with the side surface of the layer 113G and the side surface of the layer 113B.

The insulating layer 127 is provided over the insulating layer 125 to fill a depressed portion formed in the insulating layer 125. The insulating layer 127 can be configured to overlap with the side surface and part of the top surface of each of the layer 113R, the layer 113G, and the layer 113B with the insulating layer 125 therebetween. The insulating layer 127 preferably covers at least part of the side surface of the insulating layer 125.

The insulating layer 125 and the insulating layer 127 can fill a space between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 113R, the layer 113G, the layer 113B, the mask layer 118, the mask layer 119, the insulating layer 125, and the insulating layer 127. Before the insulating layer 125 and the insulating layer 127 are provided, a step is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection can be inhibited. In addition, an increase in electric resistance, which is caused by local thinning of the common electrode 115 due to the step, can be inhibited.

The top surface of the insulating layer 127 preferably has a shape with higher flatness, but may include a projection portion, a convex surface, a concave surface, or a depressed portion. For example, the top surface of the insulating layer 127 preferably has a convex shape with high flatness.

Next, an example of materials that can be used for the insulating layer 125 and the insulating layer 127 is described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an atomic layer deposition (ALD) method is used as the insulating layer 125, the insulating layer 125 having few pin holes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as having low permeability). Alternatively, a barrier property refers to a function of capturing or fixing (also referred to as gettering) a particular substance.

When the insulating layer 125 has a function of a barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, it is desirable that one or both of the hydrogen concentration and the carbon concentration in the insulating layer 125 be sufficiently low.

Note that for the insulating layer 125 and the mask layer 118B, the mask layer 118G, and the mask layer 118R, the same material can be used. In this case, the boundary between the insulating layer 125 and any of the mask layer 118B, the mask layer 118G, and the mask layer 118R is unclear and thus the layers cannot be distinguished from each other in some cases.

The insulating layer 127 provided over the insulating layer 125 has a function of filling large unevenness of the insulating layer 125, which is formed between the adjacent light-emitting devices. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

Alternatively, for the insulating layer 127, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the insulating layer 127, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

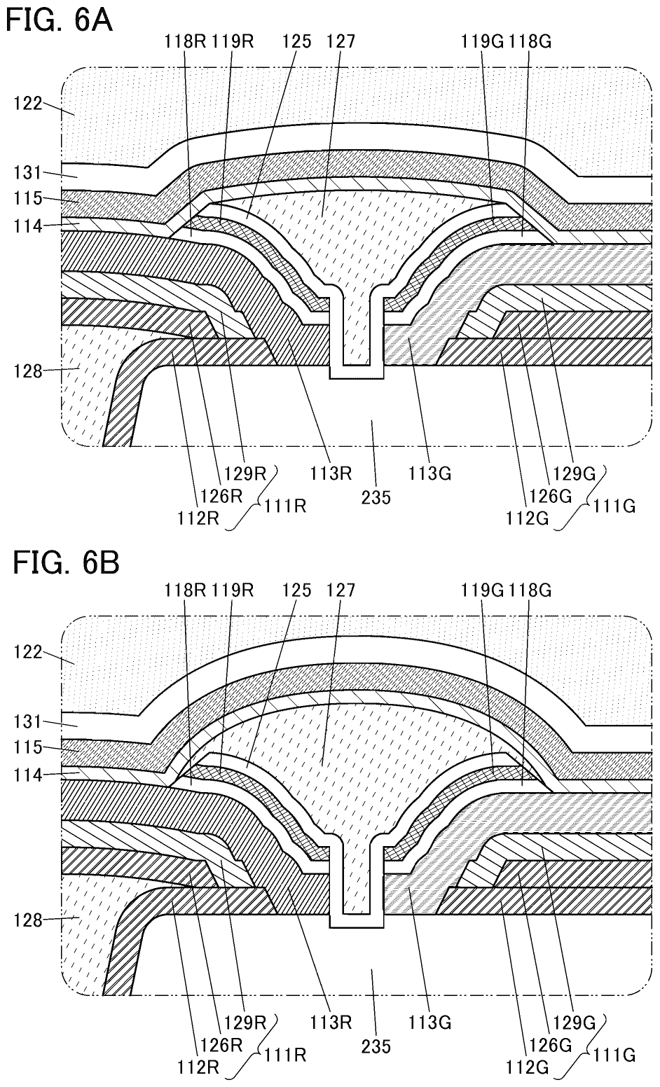

Next, structures of the insulating layer 127 and the vicinity thereof are described. FIG. 6A is an enlarged cross-sectional view of a region including the insulating layer 127 between the light-emitting device 130R and the light-emitting device 130G, and the vicinity of the insulating layer 127. Although the insulating layer 127 between the light-emitting device 130R and the light-emitting device 130G is described below as an example, the same applies to the insulating layer 127 between the light-emitting device 130G and the light-emitting device 130B, the insulating layer 127 between the light-emitting device 130B and the light-emitting device 130R, and the like.

As illustrated in FIG. 6A, the layer 113R is provided to cover the pixel electrode 111R and the layer 113G is provided to cover the pixel electrode 111G. The mask layer 118R is provided in contact with part of the top surface of the layer 113R, and the mask layer 118G is provided in contact with part of the top surface of the layer 113G. The insulating layer 125 is provided in contact with the top surface and the side surface of the mask layer 118R, the side surface of the layer 113R, the top surface of the insulating layer 235, the top surface and the side surface of the mask layer 118G, and the side surface of the layer 113G. The insulating layer 125 covers part of the top surface of the layer 113R and part of the top surface of the layer 113G. The insulating layer 127 is provided in contact with the top surface of the insulating layer 125. The insulating layer 127 overlaps with the side surface and part of the top surface of the layer 113R and the side surface and part of the top surface of the layer 113G with the insulating layer 125 therebetween, and is in contact with at least part of the side surface of the insulating layer 125. The common layer 114 is provided to cover the layer 113R, the mask layer 118R, the layer 113G, the mask layer 118G, the insulating layer 125, and the insulating layer 127, and the common electrode 115 is provided over the common layer 114.

The insulating layer 127 is formed in a region between two island-shaped EL layers (e.g., a region between the layer 113R and the layer 113G in FIG. 6A). At this time, at least part of the insulating layer 127 is placed at a position interposed between an end portion of the side surface of one of the EL layers (e.g., the layer 113R in FIG. 6A) and an end portion of the side surface of the other of the EL layers (e.g., the layer 113G in FIG. 6A). Providing the insulating layer 127 in such a manner can prevent formation of a disconnected portion and a locally thinned portion in the common layer 114 and the common electrode 115 that are formed over the island-shaped EL layers and the insulating layer 127.

The end portion of the insulating layer 127 preferably has a tapered shape in the cross-sectional view of the display apparatus. The angle formed by the side surface of the insulating layer 127 and the formation surface of the insulating layer 127 is preferably less than 90°, further preferably less than or equal to 60°, still further preferably less than or equal to 45°, yet still further preferably less than or equal to 20°. When the end portion of the insulating layer 127 has such a tapered shape, the common layer 114 and the common electrode 115 that are provided over the insulating layer 127 can be formed with favorable coverage, thereby inhibiting step disconnection, local thinning, or the like. Accordingly, the in-place uniformity of the common layer 114 and the common electrode 115 can be improved, leading to higher display quality of the display apparatus.

As illustrated in FIG. 6A, in a cross-sectional view of the display apparatus, the top surface of the insulating layer 127 preferably has a convex shape. The convex shape of the top surface of the insulating layer 127 is preferably a shape gently bulged toward the center. It is also preferable that the convex portion in the center portion of the top surface of the insulating layer 127 have a shape gently connected to a tapered portion in the end portion. When the insulating layer 127 has such a shape, the common layer 114 and the common electrode 115 can be formed with good coverage over the entire insulating layer 127.

The end portion of the insulating layer 125 preferably has a tapered shape in the cross-sectional view of the display apparatus. The angle formed by the side surface of the insulating layer 125 and the formation surface of the insulating layer 125 is preferably less than 90°, further preferably less than or equal to 60°, still further preferably less than or equal to 45°, yet still further preferably less than or equal to 20°.

The end portion of the mask layer 118R preferably has a tapered shape in the cross-sectional view of the display apparatus. The angle formed by the side surface of the mask layer 118R and the formation surface of the mask layer 118R is preferably less than 90°, further preferably less than or equal to 60°, still further preferably less than or equal to 45°, yet still further preferably less than or equal to 20°. Similarly, the end portions of the mask layer 118G and the mask layer 118B preferably have tapered shapes, and the angles formed between these side surfaces and the formation surface are preferably within the above range.

The end portion of the mask layer 119R preferably has a tapered shape in the cross-sectional view of the display apparatus. The angle formed by the side surface of the mask layer 119R and the formation surface of the mask layer 119R is preferably less than 90°, further preferably less than or equal to 60°, still further preferably less than or equal to 45°, yet still further preferably less than or equal to 20°. Similarly, the end portions of the mask layer 119G and the mask layer 119B preferably have tapered shapes, and the angles formed between these side surfaces and the formation surface are preferably within the above range.

Such tapered shapes of the end portions of the mask layer 118R and the mask layer 119R can improve the coverage with the common layer 114 and the common electrode 115 provided over the mask layer 118G and the mask layer 119R.

The end portion of the mask layer 118R and the end portion of the mask layer 119R are each preferably positioned outward from the end portion of the insulating layer 125. In this case, unevenness of the formation surface of the common layer 114 and the common electrode 115 can be reduced and coverage with the common layer 114 and the common electrode 115 can be improved.

The insulating layer 127 covers at least part of the side surface of the insulating layer 125, the side surface of the mask layer 118R, the mask layer 119R, the side surface of the mask layer 118G, and a side surface of the mask layer 119G in some cases. FIG. 6B illustrates a structure in which the insulating layer 127 covers the side surface of the insulating layer 125, part of the side surface of the mask layer 118R, the mask layer 119R, part of the side surface of the mask layer 118G, and the side surface of the mask layer 119G. The end portion of the insulating layer 127 is preferably positioned outward from the end portion of the insulating layer 125. In this case, unevenness of the formation surface of the common layer 114 and the common electrode 115 can be reduced and coverage with the common layer 114 and the common electrode 115 can be improved.

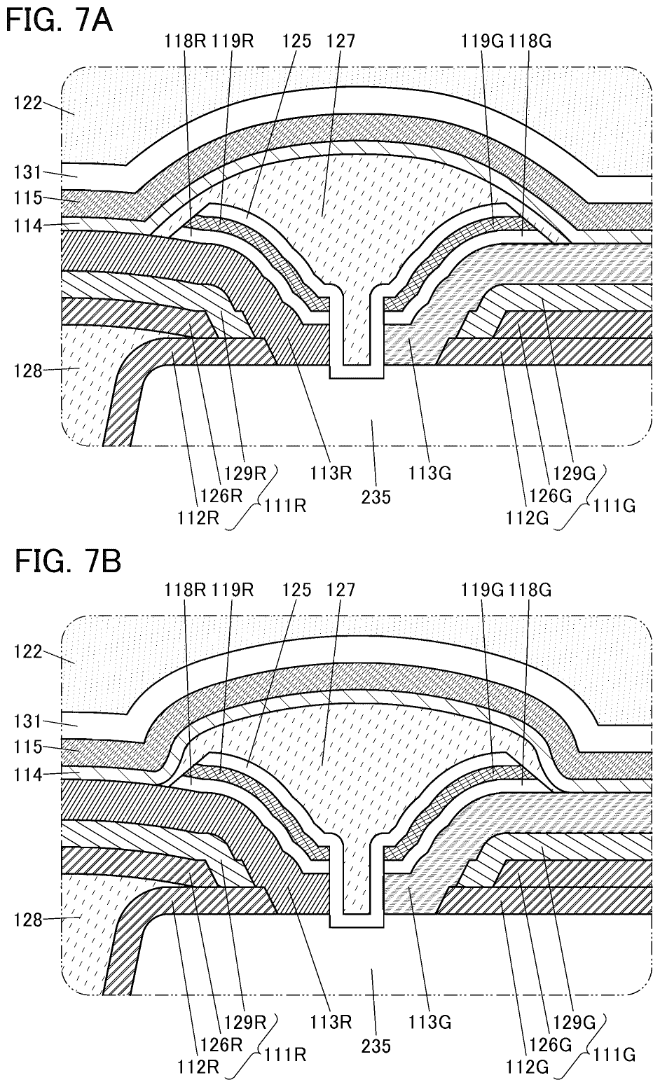

FIG. 7A illustrates an example in which the insulating layer 127 covers the entire side surface of the insulating layer 125, the entire side surface of the mask layer 118R, the entire side surface of the mask layer 119R, and the entire side surface of the mask layer 118G and the mask layer 119G. This is preferable because unevenness on the formation surface of the common layer 114 and the common electrode 115 can be further reduced. As illustrated in FIG. 7A, the insulating layer 127 may be in contact with the layer 113R and the layer 113G.

FIG. 7B illustrates examples in which the side surface of the insulating layer 127 has a concave shape (also referred to as a narrowed portion, a depressed portion, a dent, or a hollow). Depending on the materials and the formation conditions (e.g., heating temperature, heating time, and heating atmosphere) of the insulating layer 127, the side surface of the insulating layer 127 has a concave shape in some cases.

One end portion of the insulating layer 127 preferably overlaps with the top surface of the pixel electrode 111R and the other end portion of the insulating layer 127 preferably overlaps with the top surface of the pixel electrode 111G. Such a structure enables the end portion of the insulating layer 127 to be formed over flat or substantially flat regions of the layer 113R and the layer 113G.

Note that the insulating layer 127 does not necessarily overlap with the top surface of the pixel electrode 111. Meanwhile, a portion where the top surface of the pixel electrode 111 and the insulating layer 127 overlap with each other is preferably smaller because the light-emitting region of the light-emitting device can be wider and the aperture ratio can be higher.

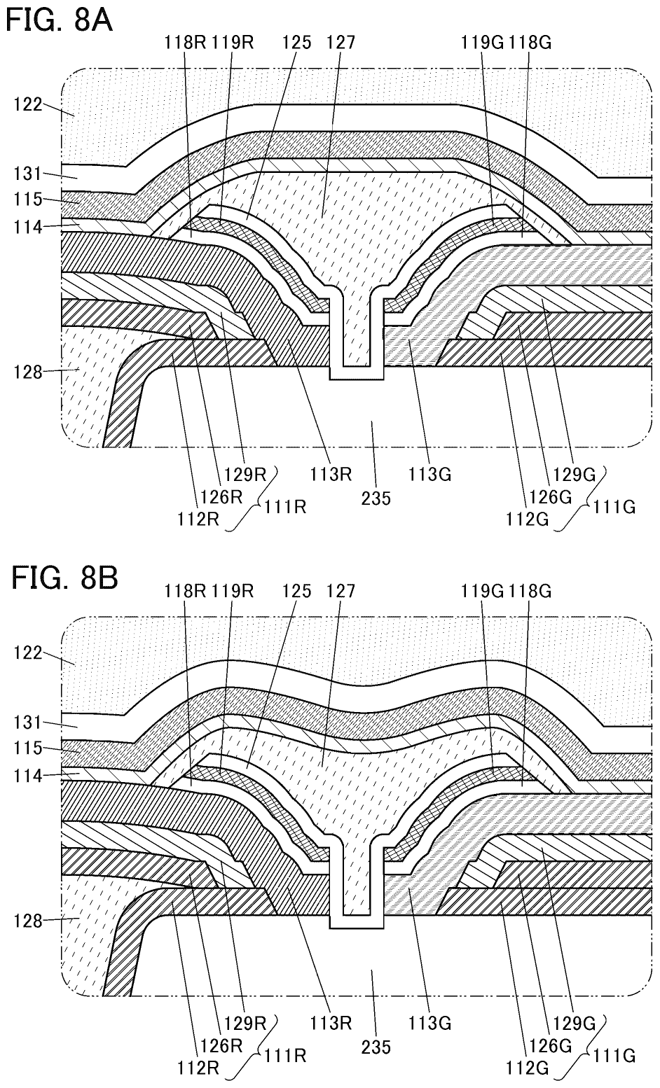

As illustrated in FIG. 8A, the top surface of the insulating layer 127 may have a flat portion in a cross-sectional view of the display apparatus.

As illustrated in FIG. 8B, the top surface of the insulating layer 127 may have a concave shape in a cross-sectional view of the display apparatus. In FIG. 8B, the top surface of the insulating layer 127 has a shape that is gently bulged toward the center, i.e., includes a convex surface, and has a shape that is recessed in the center and its vicinity, i.e., includes a concave surface. In FIG. 8B, the convex portion of the top surface of the insulating layer 127 has a shape gently connected to the tapered portion in the end portion. Even when the insulating layer 127 has such a shape, the common layer 114 and the common electrode 115 can be formed with good coverage over the entire insulating layer 127.

To form a structure in which the insulating layer 127 includes a concave surface in its center portion as illustrated in FIG. 8B, a light exposure method using a multi-tone mask (typically, a half-tone mask or a gray-tone mask) can be employed. A multi-tone mask is a mask capable of light exposure of three light-exposure levels to provide an exposed portion, a half-exposed portion, and an unexposed portion, and is a light-exposure mask through which light is transmitted to have a plurality of intensities. The insulating layer 127 including regions with a plurality of (typically two kinds of) thicknesses can be formed with one photomask (one light exposure and development process).

Note that a method of forming a concave surface in the center portion of the insulating layer 127 is not limited to the above method. For example, an exposed portion and a half-exposed portion may be formed separately with the use of two photomasks. Alternatively, the viscosity of the resin material used for the insulating layer 127 may be adjusted; specifically, the viscosity of the material used for the insulating layer 127 may be less than or equal to 10 cP, preferably greater than or equal to 1 cP and less than or equal to 5 cP.

Although not illustrated, the concave surface in the center portion of the insulating layer 127 is not necessarily continuous, and may be disconnected between adjacent light-emitting devices. In this case, part of the insulating layer 127 in the center portion of the insulating layer 127 illustrated in FIG. 8B is eliminated, so that the surface of the insulating layer 125 is exposed. In the case of such a structure, the common layer 114 and the common electrode 115 are formed to have shapes covering the insulating layer 125.

As described above, providing the insulating layer 127, the insulating layer 125, the mask layer 118R, the mask layer 118G, the mask layer 119R, and the mask layer 119G enables the common layer 114 and the common electrode 115 to be formed with favorable coverage from the flat or substantially flat region of the layer 113R to the flat or substantially flat region of the layer 113G. It is also possible to prevent formation of a disconnected portion and a locally thinned portion in the common layer 114 and the common electrode 115. This can inhibit the common layer 114 and the common electrode 115 between light-emitting devices from having connection defects due to the disconnected portion and an increased electric resistance due to the locally thinned portion. Thus, the display quality of the display apparatus of one embodiment of the present invention can be improved.

The protective layer 131 is preferably provided over the light-emitting device 130R, the light-emitting device 130G, and the light-emitting device 130B. Providing the protective layer 131 can improve the reliability of the light-emitting device 130. The protective layer 131 may have a single-layer structure or a stacked-layer structure, and may have a stacked-layer structure including two or more layers.

There is no limitation on the conductivity of the protective layer 131. As the protective layer 131, at least one type of insulating films, semiconductor films, and conductive films can be used.

The protective layer 131 including an inorganic film can inhibit oxidation of the common electrode 115 and entry of impurities (e.g., moisture and oxygen) into the light-emitting device; thus, the deterioration of the light-emitting device can be inhibited and the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked structure of two layers which are formed by different film formation methods. Specifically, the first layer of the protective layer 131 may be formed by an ALD method, and the second layer of the protective layer 131 may be formed by a sputtering method.

A light-blocking layer 117 may be provided on the surface of the substrate 120 on the resin layer 122 side. The light-blocking layer 117 can be provided between adjacent light-emitting devices 130 and in the connection portion 140. The light-blocking layer 117 can prevent color mixture by blocking light emitted from adjacent subpixels. Furthermore, external light can be inhibited from reaching the transistor 205, and deterioration of the transistor 205 can be inhibited. Note that a structure in which the light-blocking layer 117 is not provided may be employed.

A variety of optical members can be provided on the outer surface of the substrate 120. Examples of optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. For the surface protective layer, a material having a high visible-light-transmitting property is preferably used. For the surface protective layer, a material with high hardness is preferably used.

For the substrate 120, glass, quartz, ceramic, sapphire, a resin, a metal, an alloy, a semiconductor, or the like can be used. For the substrate through which light from the light-emitting device is extracted, a material that transmits the light is used. When a flexible material is used for the substrate 120, the flexibility of the display apparatus can be increased. Furthermore, a polarizing plate may be used as the substrate 120.

For the substrate 120, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

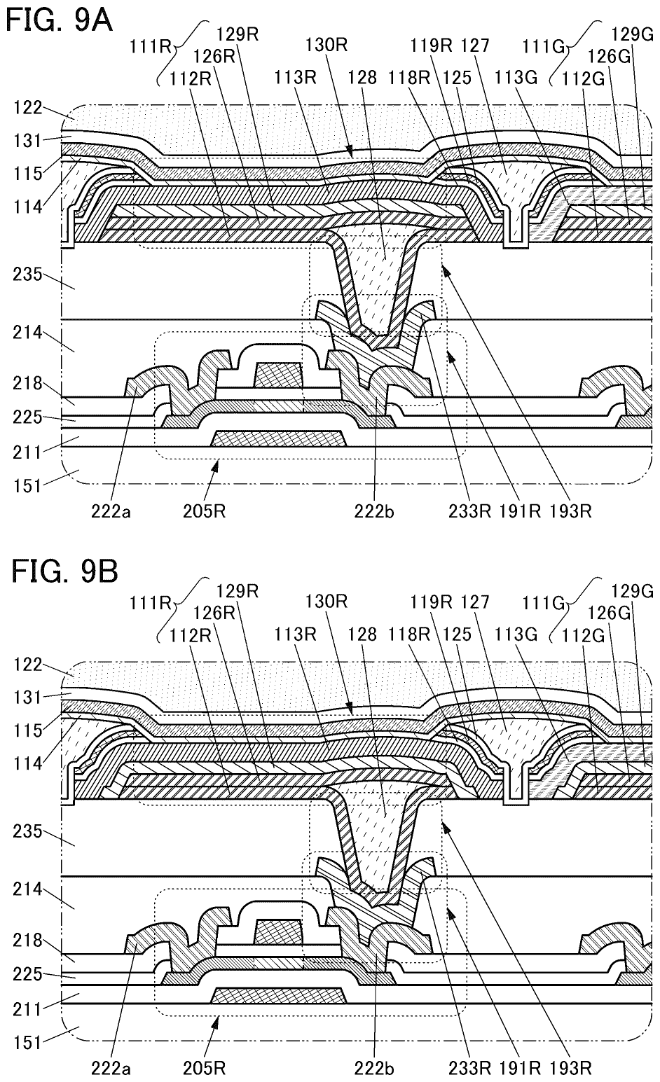

FIG. 9A and FIG. 9B illustrate structure examples of the pixel electrode 111R different from that of the pixel electrode 111R illustrated in FIG. 2 and the like.

In the pixel electrode 111R illustrated in FIG. 9A, the end portions of the conductive layer 129R, the conductive layer 126R, and the conductive layer 112R are aligned or substantially aligned with one another. The layer 113R is in contact with the side surface of the conductive layer 129R, the side surface of the conductive layer 126R, and the side surface of the conductive layer 112R.

For example, a first conductive film to be the conductive layer 129R, the layer 128, a second conductive film to be the conductive layer 126R, and a third conductive film to be the conductive layer 112R are formed; after that, a resist mask is formed over the third conductive film, and the first conductive film, the second conductive film, and the third conductive film are processed using the resist mask, whereby the conductive layer 129R, the conductive layer 126R, and the conductive layer 112R can be formed. The first conductive film, the second conductive film, and the third conductive film are processed in the same step to form the conductive layer 129R, the conductive layer 126R, and the conductive layer 112R, whereby the process can be simplified.

In the pixel electrode 111R illustrated in FIG. 9B, the conductive layer 129R and the conductive layer 126R are covered with the conductive layer 112R. The end portion of the conductive layer 129R and the end portion of the conductive layer 126R are aligned or substantially aligned with each other. The conductive layer 112R is in contact with the side surface of the conductive layer 129R and a top surface and the side surface of the conductive layer 126R. The layer 113R is in contact with the side surface of the conductive layer 129R and the top surface and the side surface of the conductive layer 112R.

For example, the first conductive film to be the conductive layer 129R, the layer 128, and the second conductive film to be the conductive layer 126R are formed; after that, a resist mask is formed over the second conductive film, and the first conductive film and the second conductive film are processed using the resist mask, whereby the conductive layer 129R and the conductive layer 126R are formed. After that, the third conductive film to be the conductive layer 112R is formed to cover the conductive layer 129R and the conductive layer 126R, and the third conductive film is processed, whereby the conductive layer 112R can be formed. The first conductive film and the second conductive film are processed in the same step to form the conductive layer 129R and the conductive layer 126R, whereby the process can be simplified. Even when a material that is easily diffused, such as silver, is used for the conductive layer 112R or the conductive layer 126R, diffusion can be inhibited by covering the top surfaces and the side surfaces of the conductive layer 112R and the conductive layer 126R with the conductive layer 129R.

Although FIG. 9A and the like illustrate a structure in which the top surface of the layer 128 has a shape in which the center and the vicinity thereof are bulged, i.e., a shape including a convex surface, in a cross-sectional view, the shape of the layer 128 is not particularly limited. The top surface of the layer 128 can have a shape in which its center and the vicinity thereof are depressed, i.e., a shape including a concave surface, in a cross-sectional view. The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112R may be equal to or substantially equal to each other, or may be different from each other. For example, the level of the top surface of the layer 128 may be either lower or higher than the level of the top surface of the conductive layer 112R.

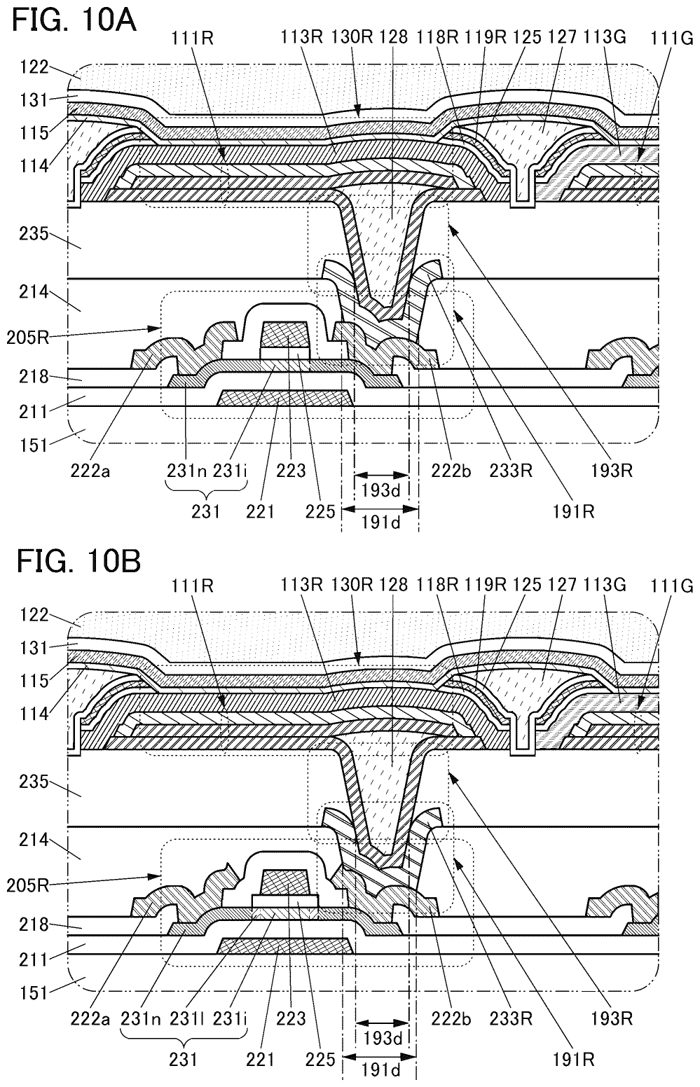

There is no particular limitation on the structure of the transistor that can be used in the display apparatus of one embodiment of the present invention. FIG. 10A to FIG. 13 illustrate examples different from that of the transistor 205 illustrated in FIG. 2 and the like.

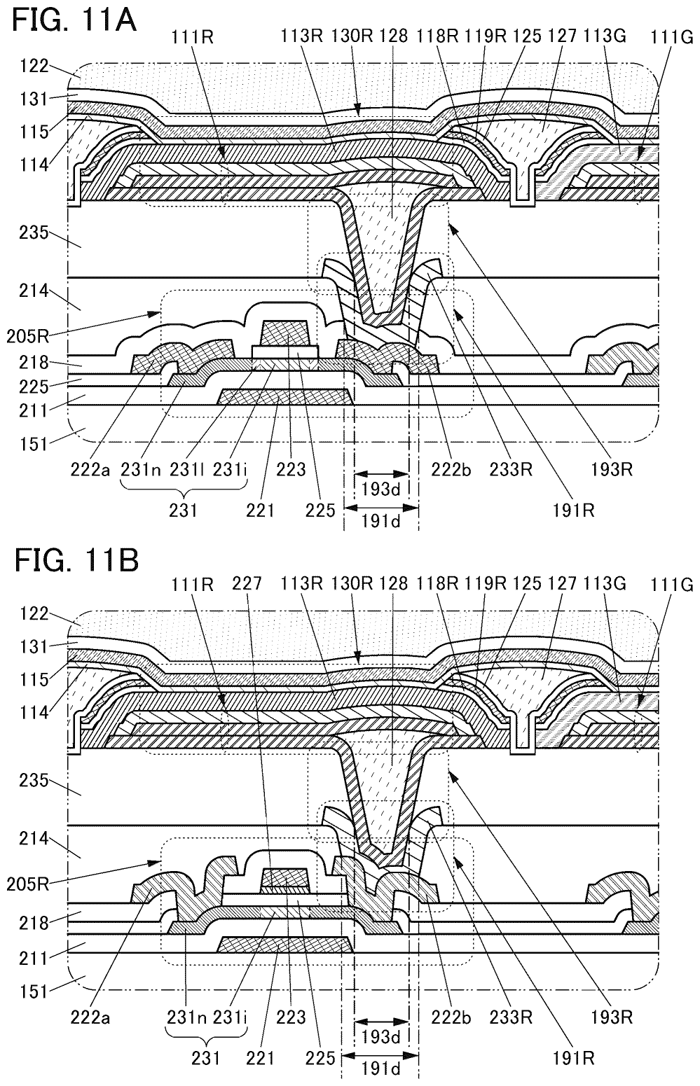

Each of the transistors 205R illustrated in FIG. 10A to FIG. 11A is different from the transistor 205 illustrated in FIG. 2 and the like mainly in the structure of the insulating layer 225.

In FIG. 10A, an end portion of the insulating layer 225 is aligned or substantially aligned with an end portion of the conductive layer 223. It can be said that the top surface shape of the insulating layer 225 is aligned or substantially aligned with that of the conductive layer 223. The insulating layer 225 overlaps with the channel formation region 231i of the semiconductor layer 231 and does not overlap with the low-resistance regions 231n. The insulating layer 225 can be formed with use of a resist mask for processing the conductive layer 223, for example.

The insulating layer 218 is in contact with the top surface and the side surface of the semiconductor layer 231, the side surface of the insulating layer 225, and the top surface and the side surface of the conductive layer 223. The conductive layer 222a and the conductive layer 222b are each electrically connected to the low-resistance region 231n through an opening of the insulating layer 218.

In FIG. 10B, the end portion of the insulating layer 225 is positioned over the semiconductor layer 231. The end portion of the insulating layer 225 is positioned outward from the end portion of the conductive layer 223. In other words, the insulating layer 225 includes a portion protruding beyond the end portion of the conductive layer 223 over the semiconductor layer 231.

The semiconductor layer 231 includes a pair of regions 231l between which the channel formation region 231i is sandwiched and the pair of low-resistance regions 231n on outer sides of the regions 231l. The regions 231l are each a region of the semiconductor layer 231 that overlaps with the insulating layer 225 and does not overlap with the conductive layer 223.

The region 231l has a function of a buffer region for relieving a drain electric field. The region 231l is a region not overlapping with the conductive layer 223 and thus is a region where a channel is hardly formed by application of gate voltage to the conductive layer 223. The region 231l preferably has a higher carrier concentration than the channel formation region 231i. Thus, the region 231l can function as an LDD (Lightly Doped Drain) region.

The region 231l can be referred to as a region whose resistance is substantially equal to or lower than that of the channel formation region 231i, a region whose carrier concentration is substantially equal to or higher than that of the channel formation region 231i, a region whose oxygen vacancy density is substantially equal to or higher than that of the channel formation region 231i, or a region whose impurity concentration is substantially equal to or higher than that of the channel formation region 231i.

The region 231l can be referred to as a region whose resistance is substantially equal to or higher than that of the low-resistance region 231n, a region whose carrier concentration is substantially equal to or lower than that of the low-resistance region 231n, a region whose oxygen vacancy density is substantially equal to or lower than that of the low-resistance region 231n, or a region whose impurity concentration is substantially equal to or lower than that of the low-resistance region 231n.

The insulating layer 218 is in contact with the top surface and the side surface of the semiconductor layer 231, the top surface and the side surface of the insulating layer 225, and the top surface and the side surface of the conductive layer 223.

FIG. 11A illustrates a structure in which the conductive layer 222a and the conductive layer 222b are formed in the same step as the conductive layer 223. That is, the conductive layer 222a and the conductive layer 222b contain the same material as the conductive layer 223. Forming the conductive layer 222a and the conductive layer 222b in the same step as the conductive layer 223 can simplify the process.

The insulating layer 218 may be provided over the transistor 205R. The insulating layer 214 is provided over the insulating layer 218. The conductive layer 233R is provided to cover the opening 191R provided in the insulating layer 218 and the insulating layer 214. The conductive layer 222b of the transistor 205R is electrically connected to the pixel electrode 111R through the conductive layer 233R. The width 191d can be referred to as a distance between the end portions of the insulating layer 214 that face each other over the insulating layer 218. Note that a structure in which the insulating layer 218 is not provided may be employed.

The transistor 205R illustrated in FIG. 11B includes a metal oxide layer 227 between the insulating layer 225 and the conductive layer 223. The conductive layer 223 and the metal oxide layer 227 are processed to have substantially aligned top surface shapes. The metal oxide layer 227 can be formed with use of a resist mask for processing the conductive layer 223, for example.

The metal oxide layer 227 has a function of supplying oxygen into the insulating layer 225. In the case where a conductive film containing a metal or an alloy that is easily oxidized is used for the conductive layer 223, the metal oxide layer 227 can also function as a barrier layer that prevents the conductive layer 223 from being oxidized by oxygen in the insulating layer 225. Note that the metal oxide layer 227 may be removed before formation of the conductive layer 223 so that the conductive layer 223 and the insulating layer 225 are in contact with each other. The metal oxide layer 227 is not necessarily provided when not needed.

The metal oxide layer 227 positioned between the insulating layer 225 and the conductive layer 223 functions as a barrier film that prevents diffusion of oxygen contained in the insulating layer 225 to the conductive layer 223 side. The metal oxide layer 227 also functions as a barrier film that prevents diffusion of impurities containing hydrogen elements contained in the conductive layer 223 to the insulating layer 225 side. Examples of impurities containing hydrogen elements include hydrogen and water. The metal oxide layer 227 is preferably formed using, for example, a material that is less likely to transmit oxygen and hydrogen than at least the insulating layer 225.

Even in the case where a metal material that is likely to absorb oxygen is used for the conductive layer 223, the metal oxide layer 227 can prevent diffusion of oxygen from the insulating layer 225 into the conductive layer 223. Furthermore, even in the case where the conductive layer 223 contains hydrogen, diffusion of hydrogen from the conductive layer 223 into the semiconductor layer 231 through the insulating layer 225 can be prevented. Consequently, the carrier concentration in the channel formation region of the semiconductor layer 231 can be extremely low. Note that examples of the metal material that is likely to absorb oxygen include aluminum and copper.

For the metal oxide layer 227, an insulating material or a conductive material can be used. When the metal oxide layer 227 has an insulating property, the metal oxide layer 227 functions as part of the gate insulating layer. Meanwhile, when the metal oxide layer 227 has conductivity, the metal oxide layer 227 functions as part of the gate electrode.

The metal oxide layer 227 is preferably formed using an insulating material with a higher permittivity than silicon oxide. It is particularly preferable to use an aluminum oxide film, a hafnium oxide film, a hafnium aluminate film, or the like because driving voltage can be lowered.

For the metal oxide layer 227, a conductive oxide such as indium oxide, indium tin oxide (ITO), or indium tin oxide containing silicon (ITSO) can also be used, for example. A conductive oxide containing indium is particularly preferable because of its high conductivity.

For the metal oxide layer 227, an oxide material containing one or more elements that are the same as those of the semiconductor layer 231 is preferably used. It is particularly preferable to use an oxide semiconductor material that can be used for the semiconductor layer 231. In that case, a metal oxide film formed using the same sputtering target as that for the semiconductor layer 231 is preferably used as the metal oxide layer 227 because an apparatus can be shared.

The metal oxide layer 227 is preferably formed using a sputtering apparatus. For example, in the case where an oxide film is formed using a sputtering apparatus, forming the oxide film in an atmosphere containing an oxygen gas can suitably add oxygen to one or both of the insulating layer 225 and the semiconductor layer 231.

Note that after the metal oxide film that can be used for the metal oxide layer 227 is deposited and oxygen is supplied to the insulating layer 225, the metal oxide film may be removed. The metal oxide layer 227 or the metal oxide film that can be used for the metal oxide layer 227 is not necessarily provided.

Note that the metal oxide layer 227 can also be applied to another structure example.

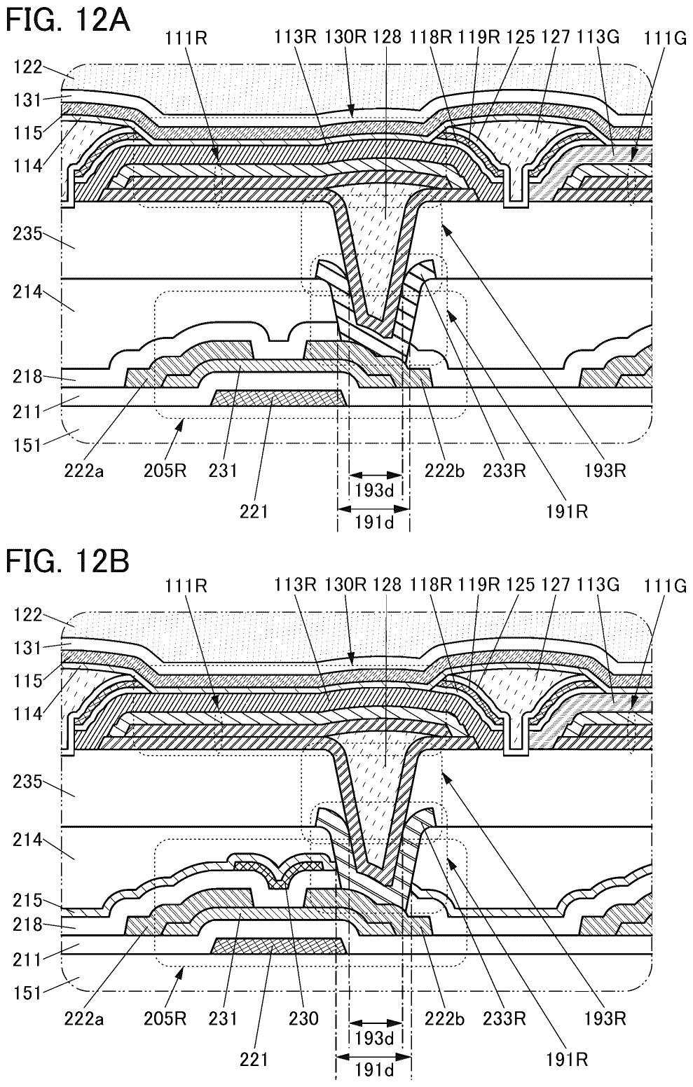

In the transistor 205R illustrated in FIG. 12A, the conductive layer 221, the insulating layer 211, and the semiconductor layer 231 are stacked in this order. The transistor 205R is what is called a bottom-gate transistor, in which the gate electrode is provided below the semiconductor layer 231. Part of the insulating layer 211 functions as a gate insulating layer of the transistor 205R. The conductive layer 221 functions as a gate electrode of the transistor 205R.

The conductive layer 222a and the conductive layer 222b functioning as a source and a drain are provided over the semiconductor layer 231. The transistor 205R can be referred to as a BGTC (Bottom Gate Top Contact) transistor.

The insulating layer 218 may be provided over the transistor 205R. The insulating layer 214 is provided over the insulating layer 218. The conductive layer 233R is provided to cover the opening 191R provided in the insulating layer 218 and the insulating layer 214. The conductive layer 222b of the transistor 205R is electrically connected to the pixel electrode 111R through the conductive layer 233R. Note that a structure in which the insulating layer 218 is not provided may be employed.

The transistor 205R illustrated in FIG. 12B includes a conductive layer 230 functioning as a back gate. The conductive layer 230 includes a region overlapping with the semiconductor layer 231 with the insulating layer 218 therebetween. The conductive layer 230 includes a region overlapping with the conductive layer 221 functioning as a gate with the semiconductor layer 231 therebetween. The insulating layer 215 may be provided to cover the conductive layer 230 and the insulating layer 218. The insulating layer 214 is provided over the insulating layer 215. The conductive layer 233R is provided to cover the opening 191R provided in the insulating layer 218, the insulating layer 215, and the insulating layer 214. The conductive layer 222b of the transistor 205R is electrically connected to the pixel electrode 111R through the conductive layer 233R. Note that a structure in which the insulating layer 215 is not provided may be employed.

The insulating layer 215 has a function of a protective layer of the transistor 205R. It is further preferable to use a material that does not easily allow diffusion of impurities for the insulating layer 215. Providing the insulating layer 215 can effectively inhibit diffusion of impurities into the transistors from the outside and increase the reliability of the display apparatus. For the insulating layer 215, a material that can be used for the insulating layer 218 can be used. The width 191d can be referred to as a distance between the end portions of the insulating layer 214 that face each other over the insulating layer 215.

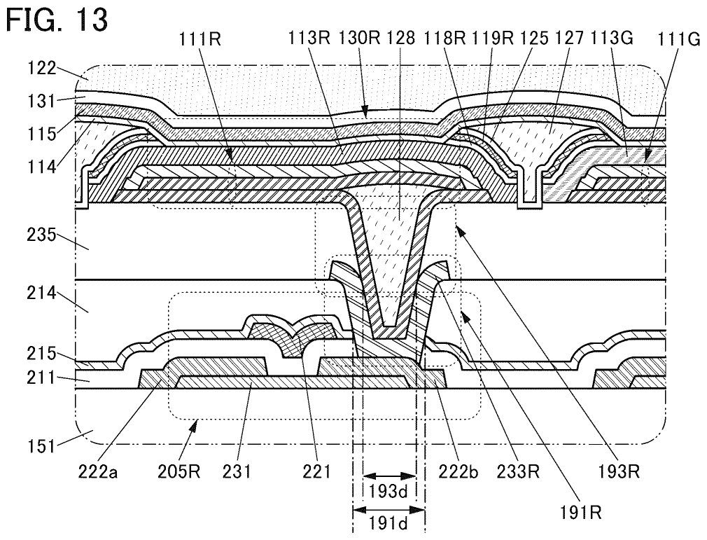

In the transistor 205R illustrated in FIG. 13, the semiconductor layer 231, the insulating layer 211, and the conductive layer 221 are stacked in this order. The transistor 205R is what is called a top-gate transistor, in which the gate electrode is provided over the semiconductor layer 231. Part of the insulating layer 211 functions as a gate insulating layer of the transistor 205R. The conductive layer 221 functions as a gate electrode of the transistor 205R.

The conductive layer 222a and the conductive layer 222b functioning as a source and a drain are provided over the semiconductor layer 231. The transistor 205R can be referred to as a TGTC (Top Gate Top Contact) transistor.

The insulating layer 215 may be provided over the transistor 205R. The insulating layer 214 is provided over the insulating layer 215. The conductive layer 233R is provided to cover the opening 191R provided in the insulating layer 211, the insulating layer 215, and the insulating layer 214. The conductive layer 222b of the transistor 205R is electrically connected to the pixel electrode 111R through the conductive layer 233R. Note that a structure in which the insulating layer 215 is not provided may be employed.

A structure example different from that of the above-described display apparatus will be described below. Note that description of the same portions as those in the above-described display apparatus is omitted in some cases. Furthermore, in drawings that are referred to later, the same hatching pattern is applied to portions having functions similar to those in the display apparatus described above, and the portions are not denoted by reference numerals in some cases.

### Structure Example 2 of Display Apparatus

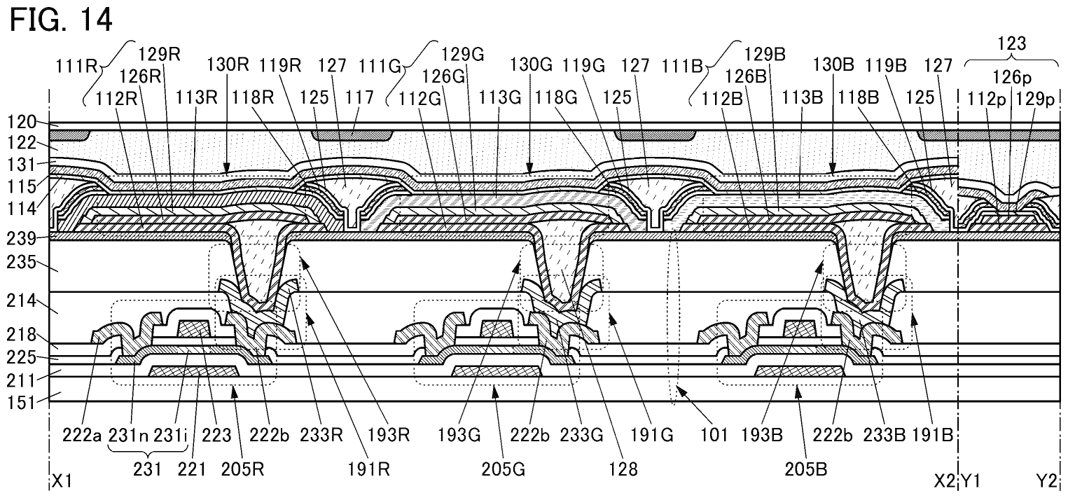

FIG. 14 is cross-sectional view of a display apparatus of one embodiment of the present invention. FIG. 14 is a cross-sectional view taken along the dashed-dotted line X1-X2 and the dashed-dotted line Y1-Y2 in FIG. 1A.

The display apparatus illustrated in FIG. 14 is different from the display apparatus illustrated in FIG. 2 mainly in including an insulating layer 239 between the insulating layer 235 and each of the light-emitting device 130R, the light-emitting device 130G, and the light-emitting device 130B.

The insulating layer 239 is provided over the insulating layer 235 and includes an opening in a region overlapping with the opening 193 in the insulating layer 235. The pixel electrode 111 is provided over the insulating layer 235. The pixel electrode 111 is provided to cover the opening in the insulating layer 235 and the opening 193R in the insulating layer 235. The pixel electrode 111 is electrically connected to the conductive layer 233 through the opening in the insulating layer 235 and the opening 193R in the insulating layer 235.

The insulating layer 239 can function as an etching protective film when the layer 113, the mask layer 118, and the mask layer 119 are formed. Providing the insulating layer 239 can prevent generation of unevenness in the insulating layer 235 caused by etching of part of the insulating layer 235 at the time when the layer 113, the mask layer 118, and the mask layer 119 are formed. Thus, steps in the formation surface of the insulating layer 125 become small, whereby the coverage with the insulating layer 125 can be increased. Consequently, the side surface of the layer 113 is covered with the insulating layer 125, which inhibits film separation of the layer 113.

The insulating layer 239 can be an insulating layer containing an inorganic material. As the insulating layer 239, an inorganic insulating film such as an oxide insulating film, a nitride insulating film, an oxynitride insulating film, or a nitride oxide insulating film can be used, for example. The insulating layer 239 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. A silicon oxide film or a silicon oxynitride film can be suitably used as the insulating layer 239, for example.

For the insulating layer 239, it is preferable to select a material having a high etching rate (also referred to as high selectivity) with respect to films to be the layer 113, the mask layer 118, and the mask layer 119 in etching of the films.

In the region that does not overlap with any of the layer 113R, the layer 113G, and the layer 113B, part of the insulating layer 239 may be removed. The thickness of the insulating layer 239 in the region that does not overlap with any of the layer 113R, the layer 113G, and the layer 113B may be smaller than the thickness of the insulating layer 239 in the region that overlaps with the layer 113R, the layer 113G, or the layer 113B.

Note that the insulating layer 239 can be applied to other structure examples.

### Structure Example 3 of Display Apparatus

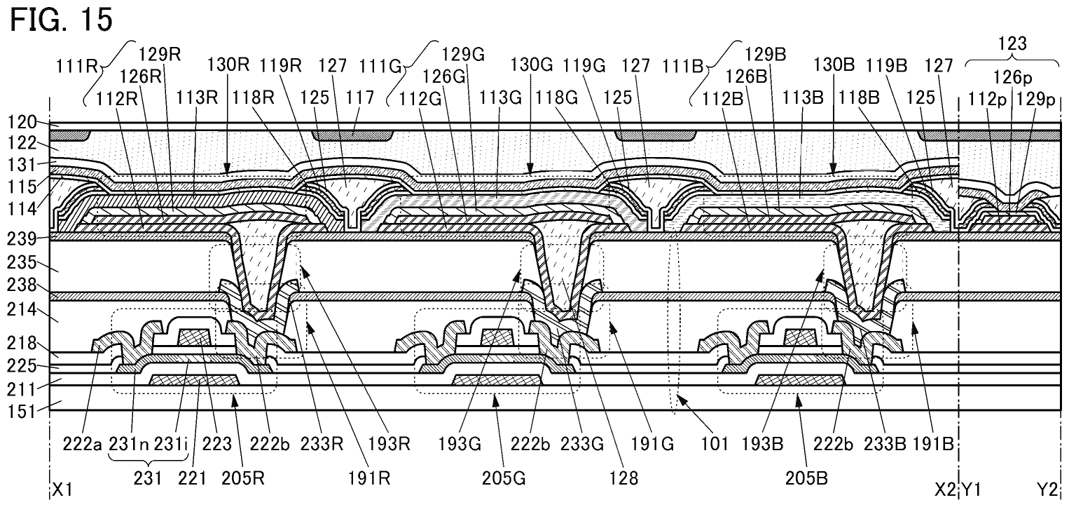

FIG. 15 is cross-sectional view of a display apparatus of one embodiment of the present invention. FIG. 15 is a cross-sectional view taken along the dashed-dotted line X1-X2 and the dashed-dotted line Y1-Y2 in FIG. 1A.

The display apparatus illustrated in FIG. 15 is different from the display apparatus illustrated in FIG. 2 mainly in including an insulating layer 239 between the insulating layer 235 and each of the light-emitting device 130R, the light-emitting device 130G, and the light-emitting device 130B and including the insulating layer 238 between the insulating layer 235 and the insulating layer 214.

For the insulating layer 239, the above description can be referred to; thus, the detailed description is omitted.

The insulating layer 238 is provided over the insulating layer 214 and includes an opening in a region overlapping with the opening 191 in the insulating layer 214. The conductive layer 233 is provided over the insulating layer 238. The conductive layer 233 is provided to cover the opening in the insulating layer 238 and the opening 191R in the insulating layer 214. The conductive layer 233 is electrically connected to the conductive layer 222b of the transistor 205 through the opening in the insulating layer 238 and the opening 191R in the insulating layer 214.

The insulating layer 238 can function as an etching protective film when the conductive layer 233 is formed. Providing the insulating layer 238 can prevent part of the insulating layer 214 from being etched at the time of forming the conductive layer 233 and thus can prevent generation of unevenness in the insulating layer 214. Thus, the step of the formation surface of the insulating layer 235 can be reduced, so that the planarity of the insulating layer 235 can be increased. Therefore, the planarity of the formation surface of the light-emitting device 130 is improved, a connection defect due to disconnection of the common electrode and an increase in electric resistance due to the locally thinned regions of the common electrode 115 can be prevented, and the display apparatus can have high display quality.

The insulating layer 238 can be formed using a material that can be used for the insulating layer 239. A silicon oxide film or a silicon oxynitride film can be suitably used as the insulating layer 238, for example.

For the insulating layer 238, it is preferable to select a material having a high etching rate (also referred to as high selectivity) with respect to a film to be the conductive layer 233 in etching of the film.

In the region that does not overlap with any of the conductive layer 233R, the conductive layer 233G, and the conductive layer 233B may be removed. The thickness of the insulating layer 235 in the region that does not overlap with any of the conductive layer 233R, the conductive layer 233G, and the conductive layer 233B may be smaller than the thickness of the insulating layer 235 in the region that overlaps with the conductive layer 233R, the conductive layer 233G, and the conductive layer 233B.

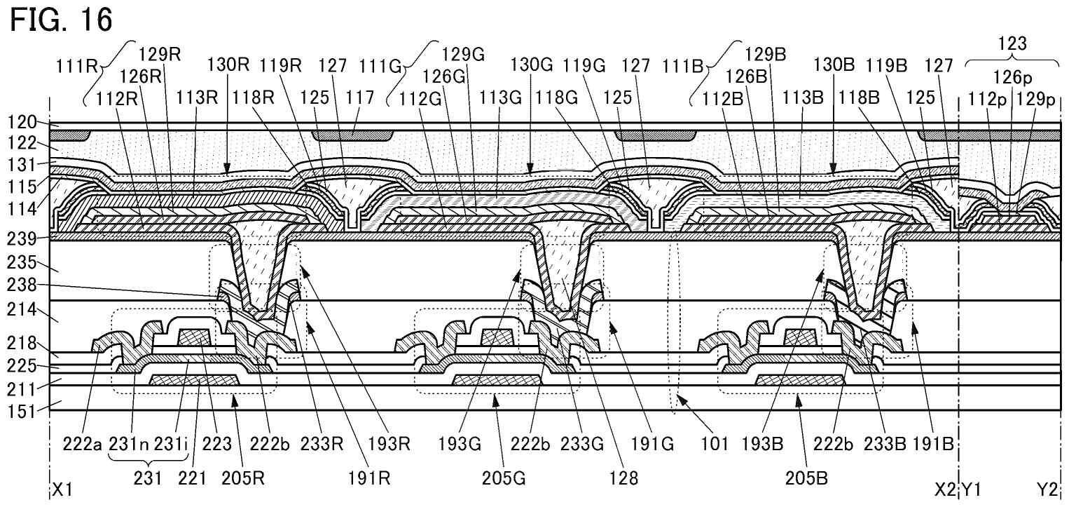

Although FIG. 15 illustrates the structure in which the insulating layer 238 is provided between the insulating layer 214 and the insulating layer 235, one embodiment of the present invention is not limited thereto. As illustrated in FIG. 16, a structure may be employed in which the insulating layer 238 is provided in a region overlapping with any of the conductive layer 233R, the conductive layer 233G, and the conductive layer 233B and the insulating layer 238 is not provided in a region overlapping with none of the conductive layer 233R, the conductive layer 233G, and the conductive layer 233B. The insulating layer 238 is provided in a region between the conductive layer 233R and the insulating layer 214, a region between the conductive layer 233G and the insulating layer 214, and a region between the conductive layer 233B and the insulating layer 214. For example, the insulating layer 238 in the region overlapping with none of the conductive layer 233R, the conductive layer 233G, and the conductive layer 233B may be removed at the time of forming the conductive layer 233R, the conductive layer 233G, and the conductive layer 233B. Alternatively, the insulating layer 238 with an island shape may remain in the region overlapping with none of the conductive layer 233R, the conductive layer 233G, and the conductive layer 233B. Thus, the insulating layer 235 is provided in contact with part of the top surface of the insulating layer 214.

Note that the insulating layer 238 can be applied to other structure examples.

### Structure Example 4 of Display Apparatus

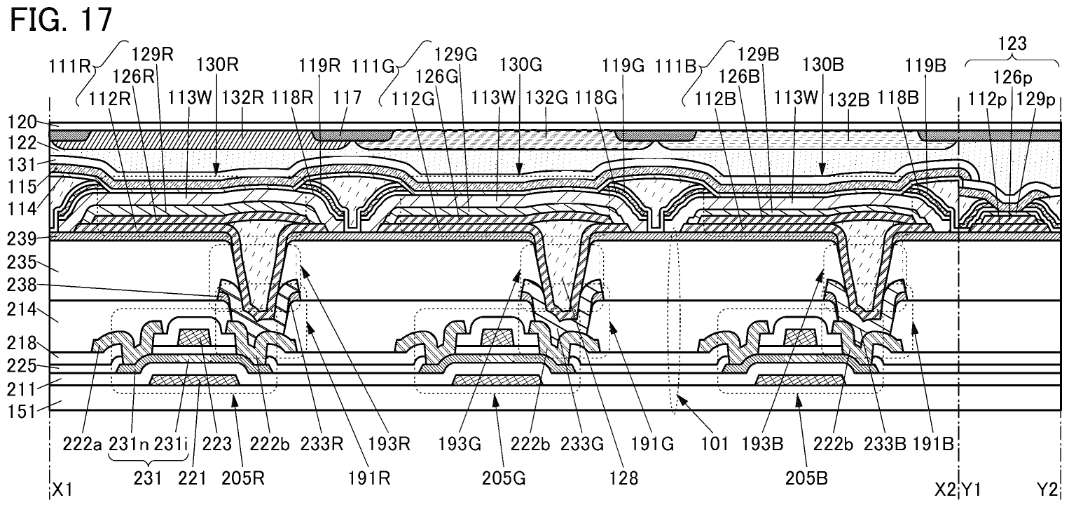

FIG. 17 is cross-sectional view of a display apparatus of one embodiment of the present invention. FIG. 17 is a cross-sectional view taken along the dashed-dotted line X1-X2 and the dashed-dotted line Y1-Y2 in FIG. 1A.

The display apparatus illustrated in FIG. 17 is different from the display apparatus illustrated in FIG. 2 mainly in the structures of the light-emitting device 130R, the light-emitting device 130G, and the light-emitting device 130B.

The light-emitting device 130R includes a layer 113W instead of the layer 113R. The light-emitting device 130G includes the layer 113W instead of the layer 113G. The light-emitting device 130B includes the layer 113W instead of the layer 113B. The layer 113W can be configured to emit white light, for example.

A conductive layer having a property of transmitting visible light may be used for the conductive layer 129R, the conductive layer 129G, and the conductive layer 129B and their thicknesses may be different from one another. The conductive layer 129R, the conductive layer 129G, and the conductive layer 129B can function as optical adjustment layers. When the thicknesses of the conductive layer 129R, the conductive layer 129G, and the conductive layer 129B are adjusted to obtain optimum path lengths, light with a desired wavelength intensified can be obtained from the light-emitting devices 130 even in the case where the layer 113W emitting white light is used.

A coloring layer 132R transmitting red light, a coloring layer 132G transmitting green light, and a coloring layer 132B transmitting blue light may be provided on the side of the substrate 120 that faces the resin layer 122. The coloring layer 132R is provided in a region overlapping with the light-emitting device 130R. The coloring layer 132G is provided in a region overlapping with the light-emitting device 130G. The coloring layer 132B is provided in a region overlapping with the light-emitting device 130B. For example, light with unnecessary wavelengths emitted from the red-light-emitting device 130R can be blocked by the coloring layer 132R. Such a structure can increase the color purity of light emitted from each light-emitting device. Note that a similar effect can be obtained in a combination of the light-emitting device 130G and the coloring layer 132G or a combination of the light-emitting device 130B and the coloring layer 132B.

Note that the coloring layer 132R, the coloring layer 132G, and the coloring layer 132B can be applied to other structure examples.

### Structure Example 5 of Display Apparatus

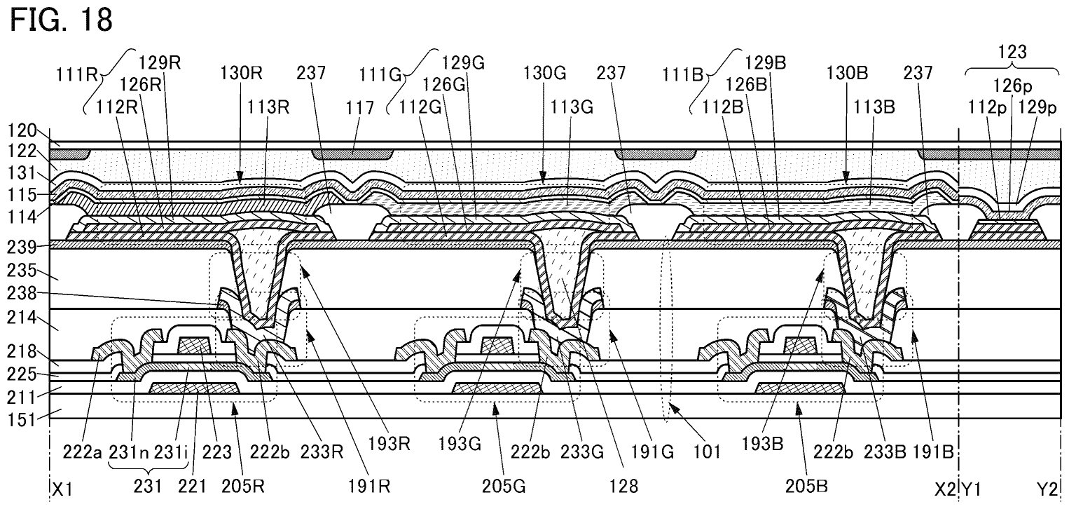

FIG. 18 is cross-sectional view of a display apparatus of one embodiment of the present invention. FIG. 18 is a cross-sectional view taken along the dashed-dotted line X1-X2 and the dashed-dotted line Y1-Y2 in FIG. 1A.

The display apparatus illustrated in FIG. 18 is different from the display apparatus illustrated in FIG. 16 mainly in including an insulating layer 237 instead of the mask layer 118, the mask layer 119, the insulating layer 125, and the insulating layer 127.

The insulating layer 237 covers end portions of the top surfaces of the pixel electrode 111R, the pixel electrode 111G, and the pixel electrode 111B. The insulating layer 237 functions as a partition (also referred to as a bank or a spacer).

Providing the insulating layer 237 prevents contact between the pixel electrode 111 and the common layer 114 and the common electrode 115 to inhibit a short-circuit in the light-emitting device 130.

For example, the insulating layer 237 covering the end portion of the top surface of the pixel electrode 111 is formed, and then the layer 113R, the layer 113G, and the layer 113B can be formed with a fine metal mask (FMM). The formation of the island-shaped layers 113R, 113G, and 113B using the fine metal mask (FMM) can simplify the process.

The layer 113R, the layer 113G, and the layer 113B may be provided over the insulating layer 237. Note that although FIG. 18 illustrate a structure in which adjacent layers 113 are not in contact with each other, one embodiment of the present invention is not limited thereto. Adjacent layers 113 may be in contact with each other over the insulating layer 237. Adjacent layers 113 may overlap with each other over the insulating layer 237. For example, over the insulating layer 237, the layer 113R may be in contact with the layer 113G, and the layer 113R and the layer 113G may overlap with each other.

Note that the insulating layer 237 can be applied to other structure examples.

### Structure Example 6 of Display Apparatus

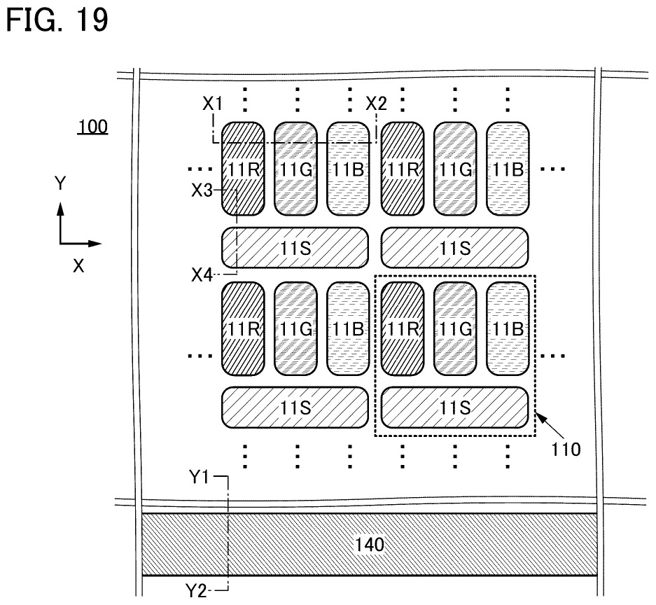

FIG. 19 illustrates a top view of the display apparatus 100 different from that in FIG. 1A. The pixel 110 illustrated in FIG. 19 is composed of four subpixels: a subpixel 11R, a subpixel 11G, a subpixel 11B, and a subpixel 11S.

The subpixels 11R, 11G, 11B, and 11S can be configured to include light-emitting devices whose emission colors are different. The subpixel 11R, the subpixel 11G, the subpixel 11B, and the subpixel 11S are subpixels of four colors of R, G, B, and W, subpixels of four colors of R, G, B, and Y, or subpixels of four types of R, G, B, and IR, for example.

The display apparatus of one embodiment of the present invention may include a light-receiving device in the pixel.

Three of the four subpixels included in the pixel 110 illustrated in FIG. 19 may each be configured to include a light-emitting device and the other one may be configured to include a light-receiving device.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

The light-receiving device can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected because an object can be detected even in a dark environment.

It is particularly preferable to use an organic photodiode including a layer containing an organic compound as the light-receiving device. An organic photodiode, which is easily made thin, lightweight, and large in area and has a high degree of freedom for shape and design, can be used for a variety of display apparatuses.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

The light-receiving device is driven by application of reverse bias between the pixel electrode and the common electrode, whereby light entering the light-receiving device can be detected and electric charge can be generated and extracted as a current.

A manufacturing method similar to that for the light-emitting device can be employed for the light-receiving device. An island-shaped active layer (also referred to as a photoelectric conversion layer) included in the light-receiving device is formed not by using a fine metal mask but by processing a film to be the active layer formed on the entire surface; thus, the island-shaped active layer can be formed to have a uniform thickness. Moreover, providing the mask layer over the active layer can reduce damage to the active layer in the manufacturing process of the display apparatus, resulting in an improvement in reliability of the light-receiving device.

Embodiment 6 can be referred to for the structure and the materials of the light-receiving device.

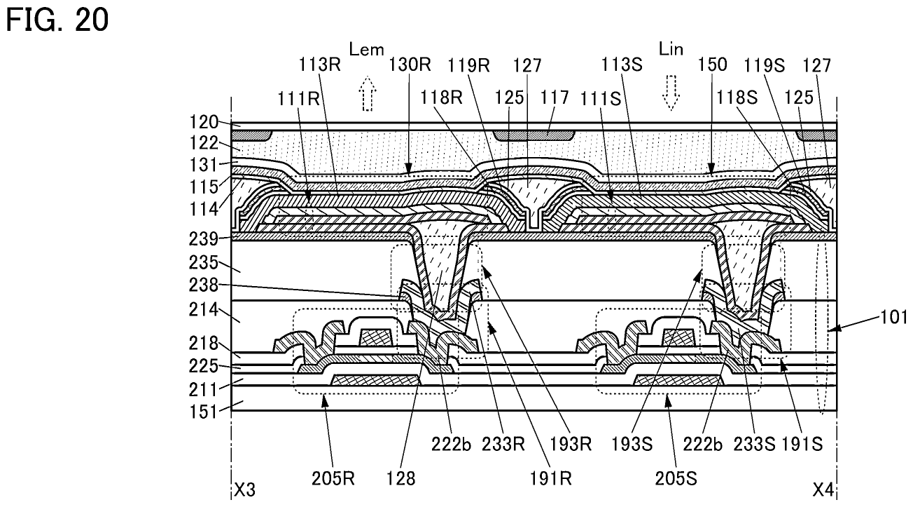

FIG. 20 is a cross-sectional view taken along the dashed-dotted line X3-X4 in FIG. 19. Note that for the cross-sectional view taken along the dashed-dotted line X1-X2 and the cross-sectional view taken along the dashed-dotted line Y1-Y2 in FIG. 19, FIG. 2 can be referred to.

As illustrated in FIG. 20, in the display apparatus 100, an insulating layer is provided over the layer 101 including transistors, the light-emitting device 130R and a light-receiving device 150 are provided over the insulating layer, the protective layer 131 is provided to cover the light-emitting device and the light-receiving device, and the substrate 120 is bonded with the resin layer 122. In a region between the light-emitting device and the light-receiving device adjacent to each other, the insulating layer 125 and the insulating layer 127 over the insulating layer 125 are provided.

FIG. 20 illustrates an example in which light is emitted from the light-emitting device 130R to the substrate 120 side and light enters the light-receiving device 150 from the substrate 120 side (see light Lem and light Lin).

The structure of the light-emitting device 130R is as described above.

The light-receiving device 150 includes a pixel electrode 111S over the insulating layer 235, a layer 113S over the pixel electrode 111S, the common layer 114 over the layer 113S, and the common electrode 115 over the common layer 114. The layer 113S includes at least an active layer.

Here, the layer 113S includes at least an active layer, preferably includes a plurality of functional layers. Examples of the functional layer include carrier-transport layers (a hole-transport layer and an electron-transport layer) and carrier-blocking layers (a hole-blocking layer and an electron-blocking layer). In addition, one or more layers are preferably provided over the active layer. A layer between the active layer and the mask layer can inhibit the active layer from being exposed on the outermost surface during the manufacturing process of the display apparatus and can reduce damage to the active layer. Accordingly, the reliability of the light-receiving device 150 can be improved. Thus, the layer 113S preferably includes an active layer and a carrier-blocking layer (a hole-blocking layer or an electron-blocking layer) or a carrier-transport layer (an electron-transport layer or a hole-transport layer) over the active layer.

The layer 113S is a layer that is provided in the light-receiving device 150 and is not in the light-emitting devices. Note that the functional layer other than the active layer included in the layer 113S may include the same material as the functional layer other than the light-emitting layer included in each of the layer 113B to the layer 113R. Meanwhile, the common layer 114 is a continuous layer shared by the light-emitting device and the light-receiving device.

Here, a layer shared by the light-receiving device and the light-emitting device may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

The mask layer 118R and the mask layer 119R are positioned between the layer 113R and the insulating layer 125, and a mask layer 118S and a mask layer 119S are positioned between the layer 113S and the insulating layer 125. The mask layer 118R and the mask layer 119R are each a remaining part of a mask layer provided over the layer 113R at the time of processing the layer 113R. The mask layer 118S and the mask layer 119S are each a remaining part of a mask layer provided in contact with the top surface of the layer 113S at the time of processing the layer 113S, which is a layer including the active layer. The mask layer 118R and the mask layer 118S may contain the same material or different materials. The mask layer 119R and the mask layer 119S may contain the same material or different materials.

The light-receiving device 150 is electrically connected to a transistor 205S through a conductive layer 233S. The conductive layer 233S can be formed in the same step as the conductive layer 233R, the conductive layer 233G, and the conductive layer 233B. The transistor 205S can be formed in the same step as the transistor 205R, the transistor 205G, and the transistor 205B. The conductive layer 222b functioning as a source or a drain of the transistor 205S includes a region overlapping with an opening 191S in the insulating layer 214. The opening 191S can be formed in the same step as the opening 191R, the opening 191G, and the opening 191B. The conductive layer 233S is provided to cover the opening 191S. The conductive layer 222b is electrically connected to the conductive layer 233S in the opening 191S. The conductive layer 233S includes a region overlapping with an opening 193S in the insulating layer 235. The opening 193S can be formed in the same step as the opening 193R, the opening 193G, and the opening 193B. The opening 193S is preferably positioned inside the opening 191S. The pixel electrode 111S of the light-receiving device 150 is provided to cover the opening 193S. The pixel electrode 111S can be formed in the same step as the pixel electrode 111R, the pixel electrode 111G, and the pixel electrode 111B.

Although FIG. 19 illustrates an example in which an aperture ratio (also referred to as size or size of the light-emitting region or the light-receiving region) of the subpixel 11S is higher than those of the subpixels 11R, 11G, and 11B, one embodiment of the present invention is not limited thereto. The aperture ratio of each of the subpixels 11R, 11G, 11B, and 11S can be determined as appropriate. The subpixels 11R, 11G, 11B, and 11S may have different aperture ratios, or two or more of them may have the same or substantially the same aperture ratio.

The subpixel 11S may have a higher aperture ratio than at least one of the subpixels 11R, 11G, and 11B. The wide light-receiving area of the subpixel 11S can make it easy to detect an object in some cases. For example, in some cases, the aperture ratio of the subpixel 11S is higher than the aperture ratio of each of the other subpixels depending on the resolution of the display apparatus and the circuit structure or the like of the subpixel.

The subpixel 11S may have a lower aperture ratio than at least one of the subpixels 11R, 11G, and 11B. A small light-receiving area of the subpixel 11S leads to a narrow image-capturing range, inhibits a blur in a capturing result, and improves the definition. This is preferable because high-resolution or high-definition image capturing can be performed.

As described above, the subpixel 11S can have a detection wavelength, a resolution, and an aperture ratio that are suitable for the intended use.

In the display apparatus of one embodiment of the present invention, an island-shaped EL layer is provided in each light-emitting device, which can inhibit generation of a leakage current between the subpixels. Thus, it is possible to prevent crosstalk due to unintended light emission, so that a display apparatus with high contrast can be achieved. An end portion of the island-shaped EL layer and the vicinity thereof, which might be damaged in the manufacturing process of the display apparatus, are set as a dummy region not to be used as the light-emitting region, whereby variations in the characteristics of the light-emitting devices can be inhibited. Providing the insulating layer having a tapered end portion between adjacent island-shaped EL layers can inhibit formation of step disconnection and prevent formation of a locally thinned portion in the common electrode at the time of forming the common electrode. This can inhibit the common layer and the common electrode from having connection defects due to the disconnected portion and an increased electric resistance due to the locally thinned portion. Thus, the display apparatus of one embodiment of the present invention can have both a higher resolution and higher display quality.

This embodiment can be combined with the other embodiments as appropriate. In this specification, in the case where a plurality of structure examples are described in one embodiment, the structure examples can be combined as appropriate.

### Embodiment 2

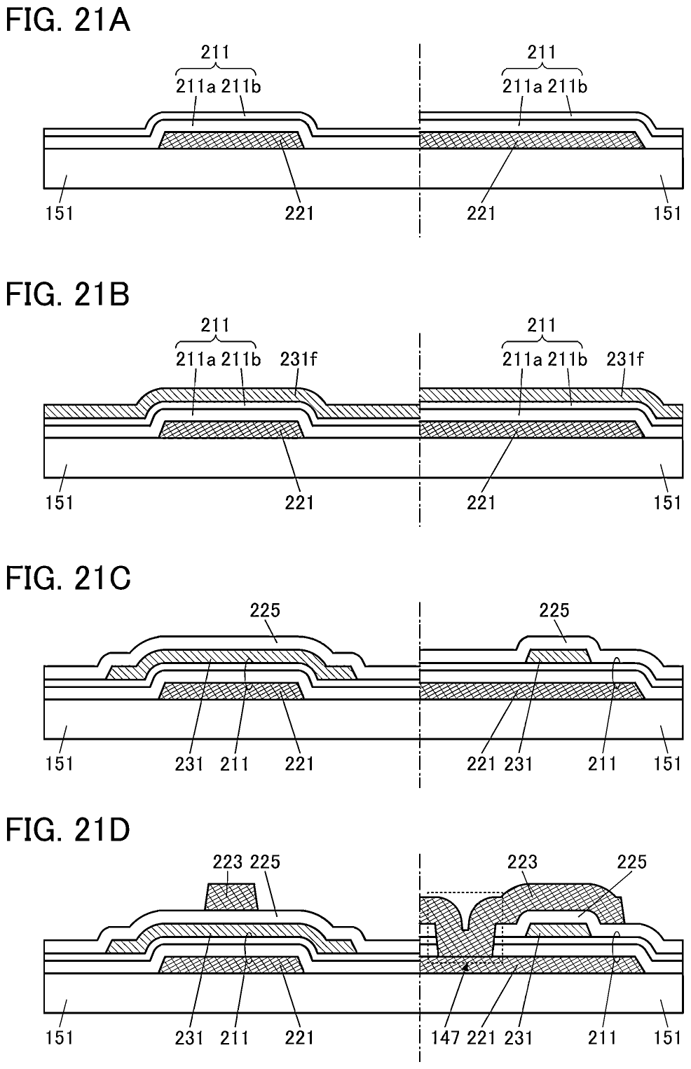

In this embodiment, examples of a manufacturing method of a display apparatus of one embodiment of the present invention will be described with reference to FIG. 21 to FIG. 42. Note that as for a material and a formation method of each component, portions similar to the portions described in Embodiment 1 are not described in some cases. The structure of the light-emitting device will be described in detail in Embodiment 5.

Thin films included in the display apparatus (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic chemical vapor deposition (MOCVD) method.

Alternatively, thin films included in the display apparatus (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

Thin films included in the display apparatus can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light used for light exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet rays, KrF laser light, ArF laser light, or the like can be used. Light exposure may be performed by liquid immersion light exposure technique. As the light used for light exposure, extreme ultraviolet (EUV) light or X-rays may also be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

### Manufacturing Method Example 1

Here, a method of manufacturing the display apparatus illustrated in FIG. 16 is described.

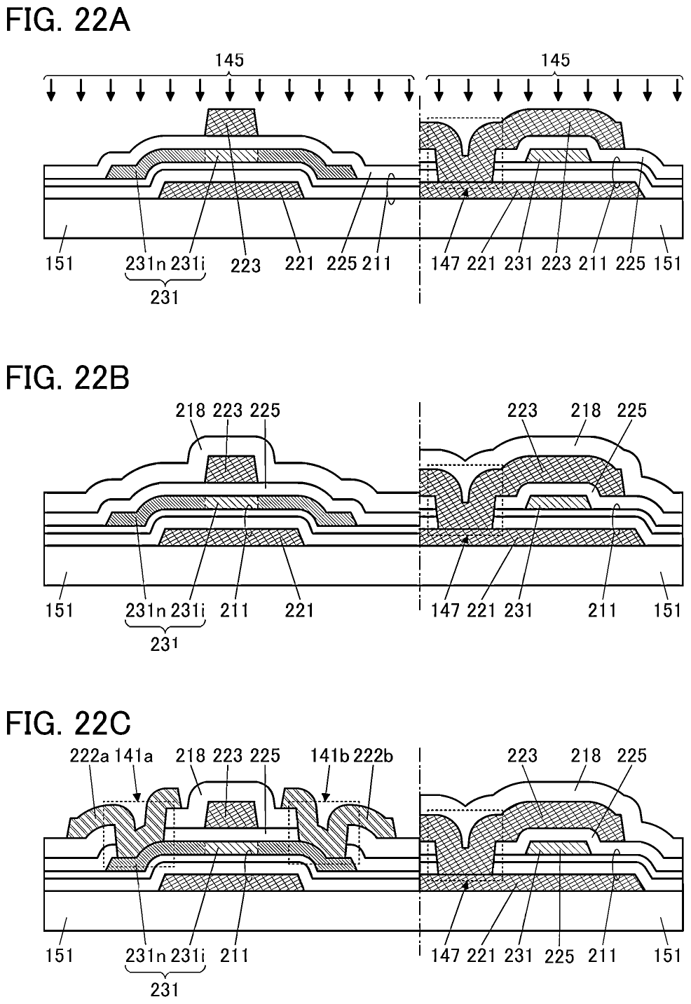

First, the transistor 205R, the transistor 205G, and the transistor 205B are formed over the substrate 151. Here, description is made with reference to FIG. 21A to FIG. 22C using the transistor 205R as an example. Note that cross sections of the transistor 205R in the channel length direction and the channel width direction at steps in the process of forming the transistor 205R are illustrated side by side in FIG. 21A to FIG. 22C.

The conductive film to be the conductive layer 221 is formed over the substrate 151, and is processed by etching to form the conductive layer 221. The conductive layer 221 is preferably processed to have an end portion with a tapered shape. This can improve step coverage with the insulating layer 211 to be formed next.

When a conductive film containing copper is used as the conductive film to be the conductive layer 221, wiring resistance can be reduced. For example, a conductive film containing copper is preferably used in the case of a large display apparatus or a display apparatus with a high resolution. Even in the case where a conductive film containing copper is used as the conductive layer 221, diffusion of copper to the semiconductor layer 231 side can be suppressed by the insulating layer 211, whereby a highly reliable transistor can be obtained.

Next, the insulating layer 211 is formed to cover the substrate 151 and the conductive layer 221 (FIG. 21A). The insulating layer 211 can be formed by a PECVD method, an ALD method, a sputtering method, or the like. Here, the insulating layer 211 is formed by stacking the insulating film 211a and the insulating film 211b. Specifically, each of the insulating films included in the insulating layer 211 is preferably formed by a PECVD method.

As the insulating film 211a, an insulating film containing nitrogen, such as a silicon nitride film, a silicon nitride oxide film, an aluminum nitride film, or a hafnium nitride film, can be used, for example. In particular, a dense silicon nitride film deposited with a PECVD apparatus is preferably used as the insulating film 211a. With the use of such an insulating film containing nitrogen, diffusion of impurities from the formation surface side can be suitably inhibited even when the thickness of the insulating film is small.

When an insulating film containing nitrogen is used as the insulating film 211a, a reduction in the amount of oxygen contained in the insulating film 211b and oxidation of the conductive layer 221 or the like due to diffusion of oxygen in the insulating film 211b to the conductive layer 221 or the like can be inhibited, for example.

The insulating film 211b in contact with the semiconductor layer 231 is preferably formed using an insulating film containing an oxide. It is particularly preferable that an oxide film be used as the insulating film 211b. As the insulating film 211b, it is preferable to use a dense insulating film in which impurities such as water are less likely to be adsorbed on the surface. In addition, as the insulating film 211b, it is preferable to use an insulating film which includes as few defects as possible and in which impurities containing hydrogen elements are reduced.

As the insulating film 211b, for example, an insulating film including one or more kinds of a silicon oxide film, a silicon oxynitride film, a silicon nitride oxide film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used. It is particularly preferable to use a silicon oxide film or a silicon oxynitride film as the insulating film 211b.

The insulating film 211b preferably includes a region containing oxygen in excess of that in the stoichiometric composition. In other words, the insulating film 211b is preferably an insulating film capable of releasing oxygen by heating. It is also possible to supply oxygen into the insulating film 211b by forming the insulating film 211b in an oxygen-containing atmosphere, performing heat treatment on the deposited insulating film 211b in an oxygen-containing atmosphere, performing plasma treatment or the like on the deposited insulating film 211b in an oxygen-containing atmosphere, or depositing an oxide film over the insulating film 211b in an oxygen-containing atmosphere, for example. Note that an oxidizing gas may be used instead of oxygen or in addition to oxygen in each of the above treatments for supplying oxygen. Alternatively, heat treatment may be performed after an insulating film capable of releasing oxygen by heating is deposited over the insulating film 211b, so that oxygen may be supplied from the insulating film into the insulating film 211b. Alternatively, oxygen may be supplied to the insulating film 211b by a plasma ion doping method or an ion implantation method.

Here, the insulating film 211b is preferably formed to be thicker than the insulating film 211a. This increases the amount of oxygen that can be released from the insulating film 211b by heating and reduces the amount of hydrogen released from the insulating film 211a. Accordingly, a large amount of oxygen can be supplied to the semiconductor layer 231 formed later while supply of hydrogen thereto is inhibited, so that the transistor can have high reliability. The thickness of the insulating film 211b is preferably greater than or equal to twice and less than or equal to 50 times, further preferably greater than or equal to three times and less than or equal to 30 times, still further preferably greater than or equal to five times and less than or equal to 20 times, yet still further preferably greater than or equal to seven times and less than or equal to 15 times, typically approximately 10 times the thickness of the insulating film 211a.

Oxygen can be supplied into the insulating film 211b during formation of a metal oxide film to be the semiconductor layer 231 by a sputtering method in an oxygen-containing atmosphere. The formation of the metal oxide film to be the semiconductor layer may be followed by heat treatment. The heat treatment enables oxygen in the insulating film 211b to be supplied to the metal oxide film more effectively and can reduce oxygen vacancies in the metal oxide film.

In the case where the insulating layer 211 is formed with a PECVD apparatus, static electricity accumulated on the substrate 151 may be eliminated by performing plasma treatment in a treatment chamber with power lower than that in the formation of the insulating layer 211 after the formation of the insulating layer 211. The plasma treatment can be referred to as a static eliminating process. For the static eliminating process, an atmosphere containing one or more of nitrogen, dinitrogen monoxide, nitrogen dioxide, hydrogen, ammonia, and a noble gas can be used. For example, an argon gas atmosphere can be suitably used for the static eliminating process. A mixed gas containing the plurality of gases may be used for the static eliminating process.

A surface of the insulating layer 211 may be removed after the formation of the insulating layer 211. The static eliminating process sometimes causes defects on the surface of the insulating layer 211. If defects exist in the insulating layer 211 functioning as the first gate insulating layer of the transistor 205, the defects become carrier trap sites and the reliability of the transistor 205 might be degraded. Thus, the surface of the insulating layer 211 including defects is removed, so that the reliability of the transistor 205 can be increased. For example, cleaning using a cleaning solution containing hydrofluoric acid can be used to remove the surface of the insulating layer 211.

Heat treatment may be performed after the formation of the insulating layer 211. Heat treatment can reduce the number of defects included in the insulating layer 211. Impurities containing hydrogen elements contained in the insulating layer 211 can be reduced. Examples of the impurities containing hydrogen elements include hydrogen and water.

The heat treatment temperature is preferably higher than or equal to 150° C. and lower than the strain point of the substrate, further preferably higher than or equal to 250° C. and lower than or equal to 450° C., still further preferably higher than or equal to 300° C. and lower than or equal to 450° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 211 can be inhibited. An oven, a rapid thermal annealing (RTA) apparatus, or the like can be used for the heat treatment. The use of the RTA apparatus can shorten the heat treatment time.

The heat treatment may be performed after the surface of the insulating layer 211 is removed.

Next, treatment for supplying oxygen to the insulating layer 211 may be performed. As the oxygen supply treatment, an oxygen radical, an oxygen atom, an oxygen atomic ion, an oxygen molecular ion, or the like is supplied to the insulating layer 211 by an ion doping method, an ion implantation method, plasma treatment, or the like. Alternatively, a film that inhibits oxygen release may be formed over the insulating layer 211, and then oxygen may be added to the insulating layer 211 through the film. It is preferable to remove the film after addition of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Next, a metal oxide film 231f is deposited over the insulating layer 211 (FIG. 21B). The metal oxide film 231f is preferably formed by a sputtering method using a metal oxide target.

The metal oxide film 231f is preferably a dense film with as few defects as possible. The metal oxide film 231f is preferably a highly purified film in which impurities containing hydrogen elements are reduced as much as possible. It is particularly preferable to use a metal oxide film having crystallinity as the metal oxide film 231f.

In forming the metal oxide film 231f, an oxygen gas is preferably used. In the case of using an oxygen gas at the time of forming the metal oxide film 231f, oxygen can be suitably supplied into the insulating layer 211. For example, in the case of using an oxide for the insulating film 211a, oxygen can be suitably supplied into the insulating film 211a. By the supply of oxygen to the insulating layer 211, oxygen is supplied to the semiconductor layer 231 in a later step, so that oxygen vacancies (Vo) and a state in which hydrogen enters the oxygen vacancy (Vo) (hereinafter referred to as VoH) in the semiconductor layer 231 can be reduced.

In depositing the metal oxide film, an inert gas (e.g., a helium gas, an argon gas, or a xenon gas) may be mixed in addition to the oxygen gas. Note that when the proportion of an oxygen gas in the whole deposition gas (hereinafter also referred to as an oxygen flow rate ratio) at the time of depositing the metal oxide film is higher, the crystallinity of the metal oxide film can be higher and a transistor with higher reliability can be obtained. By contrast, when the oxygen flow rate ratio is lower, the crystallinity of the metal oxide film is lower and a transistor with a high on-state current can be obtained.

In depositing the metal oxide film, as the substrate temperature becomes higher, a denser metal oxide film having higher crystallinity can be formed. On the other hand, as the substrate temperature becomes lower, a metal oxide film having lower crystallinity and higher electric conductivity can be formed.

The metal oxide film is formed under the deposition conditions where a substrate temperature is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the metal oxide film is deposited with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 211 and treatment for supplying oxygen into the insulating layer 211 before the deposition of the metal oxide film 231f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 211 by plasma treatment in an atmosphere containing an oxidizing gas such as dinitrogen monoxide (N₂O). Performing plasma treatment containing a dinitrogen monoxide gas can supply oxygen to the insulating layer 211 while suitably removing an organic substance on the surface of the insulating layer 211. It is preferable that the metal oxide film 231f be deposited successively after such treatment, without exposure of the surface of the insulating layer 211 to the air.

Note that in the case where the semiconductor layer 231 has a stacked-layer structure in which a plurality of semiconductor layers are stacked, an upper metal oxide film is preferably deposited successively after deposition of a lower metal oxide film without exposure of the surface of the lower metal oxide layer to the air.

Next, the metal oxide film 231f is partly etched to form the island-shaped semiconductor layer 231. For processing of the metal oxide film 231f, either one or both of a wet etching method and a dry etching method are used. At this time, part of the insulating layer 211 that does not overlap with the semiconductor layer 231 is etched and thinned in some cases. For example, in some cases, the insulating film 211b of the insulating layer 211 is removed by etching and a surface of the insulating film 211a is exposed.

Here, it is preferable that heat treatment be performed after the metal oxide film 231f is deposited or the metal oxide film 231f is processed into the semiconductor layer 231. By the heat treatment, hydrogen or water contained in the metal oxide film 231f or the semiconductor layer 231 or adsorbed on the surface of the metal oxide film 231f or the semiconductor layer 231 can be removed. Furthermore, the film quality of the metal oxide film 231f or the semiconductor layer 231 is improved (e.g., the number of defects is reduced or crystallinity is increased) by the heat treatment in some cases.

Furthermore, oxygen can be supplied from the insulating layer 211 to the metal oxide film 231f or the semiconductor layer 231 by heat treatment. At this time, it is further preferable that the heat treatment be performed before the semiconductor film 231 is processed into the semiconductor layer 231.

The temperature of the heat treatment can be typically higher than or equal to 150° C. and lower than the strain point of the substrate, higher than or equal to 200° C. and lower than or equal to 500° C., higher than or equal to 250° C. and lower than or equal to 450° C., or higher than or equal to 300° C. and lower than or equal to 450° C. The heat treatment can be performed in an atmosphere containing a noble gas or nitrogen. Alternatively, heating may be performed in the atmosphere, and then heating may be performed in an oxygen-containing atmosphere. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment. The use of the RTA apparatus can shorten the heat treatment time.

Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

Next, the insulating layer 225 is formed to cover the insulating layer 211 and the semiconductor layer 231 (FIG. 21C). The insulating layer 225 is preferably formed by a PECVD method. The insulating layer 225 may have a stacked-layer structure.

It is preferable to perform plasma treatment on a surface of the semiconductor layer 231 before deposition of the gate insulating layer 225. By the plasma treatment, an impurity adsorbed onto the surface of the semiconductor layer 231, such as water, can be reduced. Therefore, impurities at the interface between the semiconductor layer 231 and the insulating layer 225 can be reduced, achieving a highly reliable transistor. The plasma treatment is particularly suitable in the case where the surface of the semiconductor layer 231 is exposed to the air after the formation of the semiconductor layer 231 and before the deposition of the gate insulating layer 225. For example, plasma treatment can be performed in an atmosphere containing oxygen, ozone, nitrogen, dinitrogen monoxide, argon, or the like. The plasma treatment and the deposition of the insulating layer 225 are preferably performed successively without exposure to the air.

Here, the substrate temperature at the time of forming the insulating layer 225 is preferably high. The high substrate temperature at the time of forming the insulating layer 225 enables the insulating layer 225 to have few defects. In contrast, when the substrate temperature at the time of forming the insulating layer 225 is high, a metal atom contained in the semiconductor layer 231 is diffused into the insulating layer 225, and defects are generated in the insulating layer 225 in some cases. For example, in the case where an In—Ga—Zn oxide is used for the semiconductor layer 231 and an oxide containing silicon is used for the insulating layer 225, defects In_{Si}, Ga_{Si}, and Zn_{Si} in which the silicon atom contained in the insulating layer 225 is replaced with the metal atom contained in the semiconductor layer 231 might be generated, which might increase NBTIS degradation. The substrate temperature at the time of forming the insulating layer 225 is preferably higher than or equal to 180° C. and lower than or equal to 450° C., further preferably higher than or equal to 200° C. and lower than or equal to 450° C., still further preferably higher than or equal to 200° C. and lower than or equal to 400° C., yet still further preferably higher than or equal to 250° C. and lower than or equal to 400° C., yet still further preferably higher than or equal to 250° C. and lower than or equal to 350° C., yet still further preferably higher than or equal to 300° C. and lower than or equal to 350° C. When the substrate temperature at the time of forming the insulating layer 225 is within the above range, the transistor can have high reliability.

After the insulating layer 225 is deposited, heat treatment is preferably performed. By the heat treatment, hydrogen or water contained in the insulating layer 225 or adsorbed on its surface can be removed. At the same time, the number of defects in the insulating layer 225 can be reduced. For the conditions of the heat treatment, the above description can be referred to. Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

Next, the insulating layer 225 and the insulating layer 211 are partly etched to form the opening 147 that reaches the conductive layer 221. Accordingly, the conductive layer 223 to be formed later can be electrically connected to the conductive layer 221 through the opening 147.

Next, a conductive film to be the conductive layer 223 is formed over the insulating layer 225, and is processed by etching to form the conductive layer 223 (FIG. 21D).

For example, the conductive film to be the conductive layer 223 is preferably deposited by a sputtering method using a sputtering target containing a metal or an alloy. A low-resistance metal or alloy material is preferably used for the conductive film.

For the conductive film to be the conductive layer 223, a material which releases a small amount of hydrogen and in which hydrogen is less likely to be diffused is preferably used. A material that is less likely to be oxidized is preferably used for the conductive film. For example, the conductive film is preferably a stacked-layer film including a low-resistance conductive film and a conductive film which is less likely to be oxidized and in which hydrogen is less likely to be diffused.

For the processing of the conductive film to be the conductive layer 223, one or both of a wet etching method and a dry etching method may be used.

As described above, the insulating layer 225 is not etched and covers the top surface and the side surface of the semiconductor layer 231 and the insulating layer 211, which prevents the semiconductor layer 231 and the insulating layer 211 from being partly etched and thinned in formation of the conductive layer 223.

Next, treatment for supplying (adding or injecting) an impurity element 145 to the semiconductor layer 231 through the insulating layer 225 is performed with the use of the conductive layer 223 as a mask (FIG. 22A). Thus, the low-resistance regions 231n can be formed in regions of the semiconductor layer 231 that are not covered with the conductive layer 223. At this time, the conditions of the treatment for supplying the impurity element 145 are preferably determined in consideration of the material and thickness of the conductive layer 223 serving as the mask and the like so that the impurity element 145 is supplied as little as possible to the region of the semiconductor layer 231 overlapping with the conductive layer 223. In this manner, a channel formation region with a sufficiently reduced impurity concentration can be formed in the region of the semiconductor layer 231 overlapping with the conductive layer 223.

A plasma ion doping method or an ion implantation method can be suitably used for the supply of the impurity element 145. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of an impurity element to be supplied.

In the treatment for supplying the impurity element 145, treatment conditions are preferably controlled such that the concentration is the highest at an interface between the semiconductor layer 231 and the insulating layer 225, a portion in the semiconductor layer 231 near the interface, or a portion in the insulating layer 225 near the interface. Accordingly, the impurity element 145 at an optimal concentration can be supplied to both the semiconductor layer 231 and the insulating layer 225 in one treatment.

Examples of the impurity element 145 include hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use boron, phosphorus, aluminum, magnesium, or silicon.

As a source gas of the impurity element 145, a gas containing any of the above impurity elements can be used. In the case where boron is supplied, typically, one or more of a B₂H₆ gas and a BF₃ gas can be used. In the case where phosphorus is supplied, typically, a PH₃ gas can be used. A mixed gas in which any of these source gases is diluted with a noble gas may be used.

Besides, any of CH₄, N₂, NH₃, AlH₃, AlCl₃, SiH₄, Si₂H₆, F₂, HF, H₂, (C₅H₅)₂ Mg, a noble gas, and the like can be used as the source gas. An ion source is not limited to a gas, and a solid or a liquid that is vaporized by heating may be used.

Addition of the impurity element 145 can be controlled by setting the conditions such as the acceleration voltage and the dosage in consideration of the compositions, densities, thicknesses, and the like of the insulating layer 225 and the semiconductor layer 231.

For example, in the case where boron is added by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus ions are added by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity element 145 is not limited thereto; plasma treatment, treatment using thermal diffusion by heating, or the like may be used, for example. In a plasma treatment method, plasma is generated in a gas atmosphere containing an impurity element to be added and plasma treatment is performed, so that the impurity element can be added. A dry etching apparatus, an ashing apparatus, a plasma CVD apparatus, a high-density plasma CVD apparatus, or the like can be used as an apparatus for generating the plasma.

For example, when plasma treatment is performed with a plasma CVD apparatus in an atmosphere containing a hydrogen gas, hydrogen can be supplied as the impurity element 145 to the semiconductor layer 231 in a region that does not overlap with the conductive layer 223. With the use of a plasma CVD apparatus for the treatment for supplying the impurity element 145 and the formation of the insulating layer 218, the treatment for supplying the impurity element 145 and the formation of the insulating layer 218 can be successively performed in the apparatus, so that the productivity can be increased.

In one embodiment of the present invention, the impurity element 145 can be supplied to the semiconductor layer 231 through the insulating layer 225. Thus, even in the case where the semiconductor layer 231 has crystallinity, damage to the semiconductor layer 231 is reduced at the time of supplying the impurity element 145, and degradation of crystallinity can be inhibited. Therefore, this is suitable for the case where a reduction in crystallinity increases electrical resistance.

Next, the insulating layer 218 is formed to cover the insulating layer 225 and the conductive layer 223 (FIG. 22B).

In the case where the deposition temperature of the insulating layer 218 is too high, impurities contained in the low-resistance region 231n and the like might be diffused into a surrounding portion including the channel formation region of the semiconductor layer 231 or the electric resistance of the low-resistance region 231n might be increased. Thus, the deposition temperature of the insulating layer 218 is determined in consideration of these.

The deposition temperature of the insulating layer 218 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Deposition of the insulating layer 218 at low temperatures enables the transistor to have favorable electrical characteristics even when it has a short channel length.

Heat treatment may be performed after the formation of the insulating layer 218. The heat treatment can allow the low-resistance region 231n to have low resistance more stably, in some cases. For example, by the heat treatment, the impurity element 145 diffuses moderately and homogenized locally, so that the low-resistance region 231n having an ideal concentration gradient of the impurity element can be formed. Note that when the temperature of the heat treatment is too high (e.g., higher than or equal to 500° C.), the impurity element 145 is also diffused into the channel formation region, so that the electrical characteristics or reliability of the transistor might be degraded.

For the conditions of the heat treatment, the above description can be referred to.

Note that the heat treatment is not necessarily performed. The heat treatment is not necessarily performed in this step, and heat treatment performed in a later step may also serve as the heat treatment in this step. In the case where treatment at a high temperature is performed (e.g., deposition step) in a later step, such treatment can serve as the heat treatment in this step in some cases.

Next, the insulating layer 218 and the insulating layer 225 are partly etched to form the opening 141a and the opening 141b that reach the low-resistance regions 231n.

Subsequently, a conductive film is formed over the insulating layer 218 to cover the opening 141a and the opening 141b, and the conductive film is processed, so that the conductive layer 222a and the conductive layer 222b are formed (FIG. 22C).

Through the above process, the transistor 205R can be fabricated. The transistor 205G and the transistor B can be formed over the same substrate through the same process as the transistor 205R.

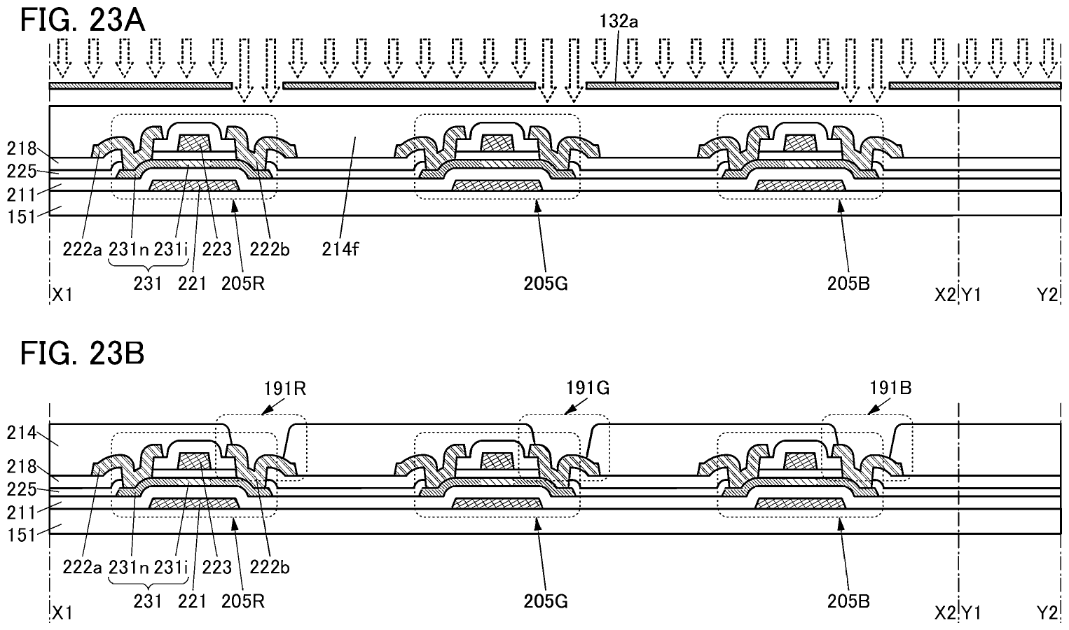

The following description will be performed with reference to FIG. 23A to FIG. 38. FIG. 23A to FIG. 38 illustrate the transistor 205R, the transistor 205G, and the transistor 205B. FIG. 23A to FIG. 38 each illustrate a cross-sectional view taken along the dashed-dotted line X1-X2 and a cross-sectional view taken along the dashed-dotted line Y1-Y2 in FIG. 16 side by side.

Next, an insulating film 214f to be the insulating layer 214 is formed to cover the transistor 205R, the transistor 205G, and the transistor 205B.

For example, in the case where a photosensitive organic material is used for the insulating film 214f, the insulating layer 214 can be formed in the following manner: a composition containing an organic material is applied by a spin coating method, and then the composition is subjected to selective light exposure and development. As another formation method, one or more of a sputtering method, an evaporation method, a droplet discharging method (an inkjet method), a screen printing method, and an offset printing method may be used.

FIG. 23A schematically illustrates a state in which a photosensitive organic material is used for the insulating film 214f and a region overlapping with the conductive layer 222b included in the transistor 205R, a region overlapping with the conductive layer 222b included in the transistor 205G, and a region overlapping with the conductive layer 222b included in the transistor 205B are exposed to light.

The light used for the light exposure preferably includes the i-line. The light used for the light exposure may include at least one of the g-line and the h-line. In FIG. 23A, light is indicated by arrows; a region where the insulating layer 214 is not formed is exposed to light, and regions where the insulating layer 214 is formed is shielded from light by a mask 132a.

By adjusting the amount of light exposure, the widths 191d of the opening 191R, the opening 191G, and the opening 191B can be controlled.

Next, development is performed to remove the region of the insulating film 214f exposed to light, so that the insulating layer 214 including the opening 191R, the opening 191G, and the opening 191B is formed (FIG. 23B). In the opening 191R, the opening 191G, and the opening 191B, the conductive layers 222b of the transistor 205R, the transistor 205G, and the transistor 205B are exposed.

Although an example in which a positive photosensitive resin is used for the insulating film 214f is described here, the present invention is not limited thereto. For example, a negative photosensitive resin may be used for the insulating film 214f. In that case, a region where the insulating layer 214 is formed is exposed to light, and a region where the insulating layer 214 is not formed is shielded from light by a mask. In the development, the insulating layer 214 is formed in the region of the insulating film 214f exposed to light.

After the insulating layer 214 is formed, heat treatment is preferably performed. In the case where an organic material is used for the insulating layer 214, the heat treatment can cure the organic material.

The temperature of the heat treatment is preferably lower than the heat resistant temperature of the organic material. For example, the temperature of the heat treatment is preferably higher than or equal to 150° C. and lower than or equal to 350° C., further preferably higher than or equal to 180° C. and lower than or equal to 300° C., still further preferably higher than or equal to 200° C. and lower than or equal to 270° C., yet still further preferably higher than or equal to 200° C. and lower than or equal to 250° C., yet still further preferably higher than or equal to 220° C. and lower than or equal to 250° C.

The heat treatment can be performed in an atmosphere containing a noble gas or nitrogen. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment.

Next, an insulating film 238f to be the insulating layer 238 is formed to cover the insulating layer 214, the opening 191R, the opening 191G, and the opening 191B.

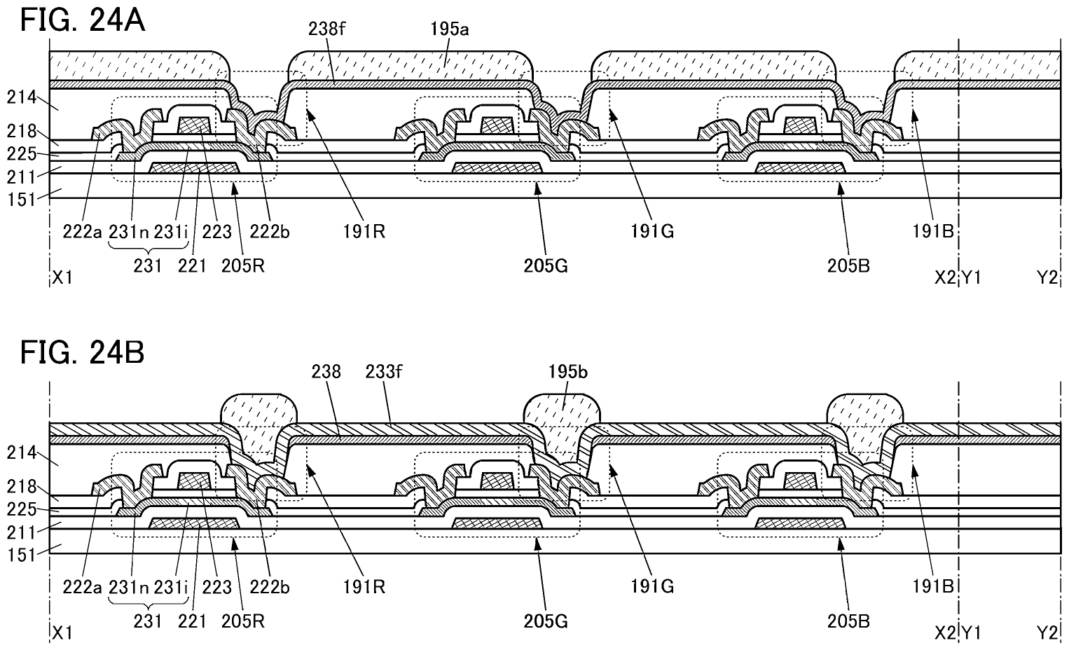

Next, a resist mask 195a is formed over the insulating film 238f (FIG. 24A). The resist mask 195a may be formed using either a positive resist or a negative resist. The resist mask 195a is not provided in the opening 191R, the opening 191G, and the opening 191B.

Next, the insulating film 238f is processed using the resist mask 195a as a mask, whereby the insulating layer 238 is formed. Thus, the conductive layers 222b of the transistor 205R, the transistor 205G, and the transistor 205B are exposed. For the processing of the insulating film 238f, one or both of a wet etching method and a dry etching method are used.

After that, the resist mask 195a is removed.

Next, a conductive film 233f to be the conductive layer 233 is formed to cover the insulating layer 238, the insulating layer 214, and the conductive layer 222b.

Next, a resist mask 195b is formed over the conductive film 233f (FIG. 24B). The resist mask 195b may be formed using either a positive resist or a negative resist. The resist mask 195b includes regions overlapping with the conductive layers 222b of the transistor 205R, the transistor 205G, and the transistor 205B.

Next, the conductive film 233f is processed using the resist mask 195b as a mask, whereby the conductive layer 233 is formed. Thus, the conductive layers 233 in contact with the conductive layers 222b of the transistor 205R, the transistor 205G, and the transistor 205B are formed. For the processing of the conductive film 233f, one or both of a wet etching method and a dry etching method are used.

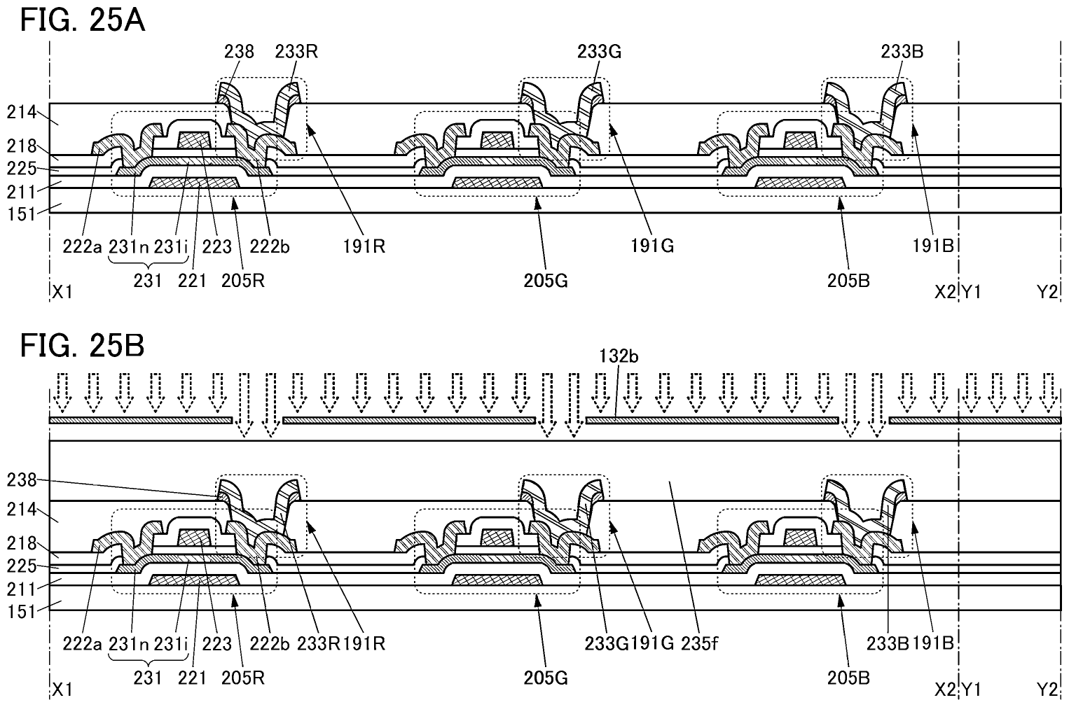

At the time of processing the conductive film 233f, the insulating layer 238 in a region not overlapping with the resist mask 195b may be removed (FIG. 25A). The insulating layer 238 remains between the conductive layer 233 and the insulating layer 214. Note that the insulating layer 238 in a region not overlapping with the resist mask 195b may remain. In this case, the structure illustrated in FIG. 15 can be employed.

After that, the resist mask 195b is removed.

Next, an insulating film 235f to be the insulating layer 235 is formed to cover the insulating layer 214, the insulating layer 238, and the conductive layer 233. For the formation of the insulating film 235f, a method similar to that for the insulating film 214f can be used.

FIG. 25B schematically illustrates a state in which a photosensitive organic material is used for the insulating film 235f and a region overlapping with the conductive layer 233 is exposed to light. In FIG. 25B, light is indicated by arrows; a region where the insulating layer 235 is not formed is exposed to light, and a region where the insulating layer 235 is formed is shielded from light by a mask 132b.

By adjusting the amount of light exposure, the widths 193d of the opening 193R, the opening 193G, and the opening 193B can be controlled. Here, the width 193d of the opening 193R is preferably smaller than the width 191d of the opening 191R. Similarly, the width 193d of the opening 193G is preferably smaller than the width 191d of the opening 191G. The width 193d of the opening 193B is preferably smaller than the width 191d of the opening 191B. The amount of light exposure is preferably adjusted such that the widths 193d of the opening 193R, the opening 193G, and the opening 193B are smaller than the widths 191d of the opening 191R, the opening 191G, and the opening 191B. For example, in the case where the insulating film 214f and the insulating film 235f are formed with the same material and have substantially the same thicknesses, the amount of light exposure of the insulating film 235f is preferably smaller than the amount of light exposure of the insulating film 214f. For example, the light exposure time of the insulating film 235f is shorter than the light exposure time of the insulating film 214f.

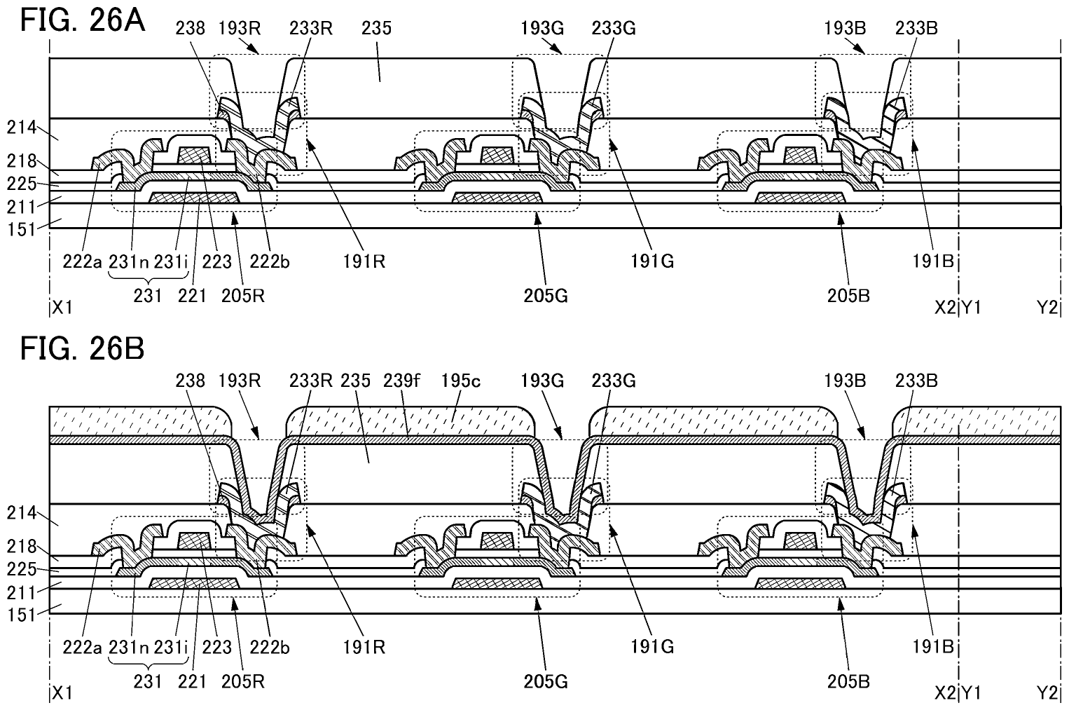

Next, development is performed to remove the region of the insulating film 235f exposed to light, so that the insulating layer 235 including the opening 193R, the opening 193G, and the opening 193B is formed (FIG. 26A). In the opening 193R, the opening 193G, and the opening 193B, the conductive layers 233 are exposed.

Although an example in which a positive photosensitive resin is used for the insulating film 235f is described here, the present invention is not limited thereto. For example, a negative photosensitive resin may be used for the insulating film 235f.

After the insulating layer 235 is formed, heat treatment is preferably performed. For the heat treatment, the description of the heat treatment after the formation of the insulating layer 214 can be referred to; thus, the detailed description thereof is omitted.

Next, an insulating film 239f to be the insulating layer 239 is formed to cover the insulating layer 235 and the conductive layer 233.

Next, a resist mask 195c is formed over the insulating film 239f (FIG. 26B). The resist mask 195c may be formed using either a positive resist or a negative resist. The resist mask 195c is not provided in the opening 193R, the opening 193G, and the opening 193B.

Next, the insulating film 239f is processed using the resist mask 195c as a mask, whereby the insulating layer 239 is formed. Thus, the conductive layers 233 are exposed. For the processing of the insulating film 239f, one or both of a wet etching method and a dry etching method are used.

After that, the resist mask 195c is removed.

Next, the conductive film 112f to be the conductive layer 112R, the conductive layer 112G, the conductive layer 112B, and the conductive layer 112p is formed to cover the insulating layer 239, the insulating layer 235, and the conductive layer 233.

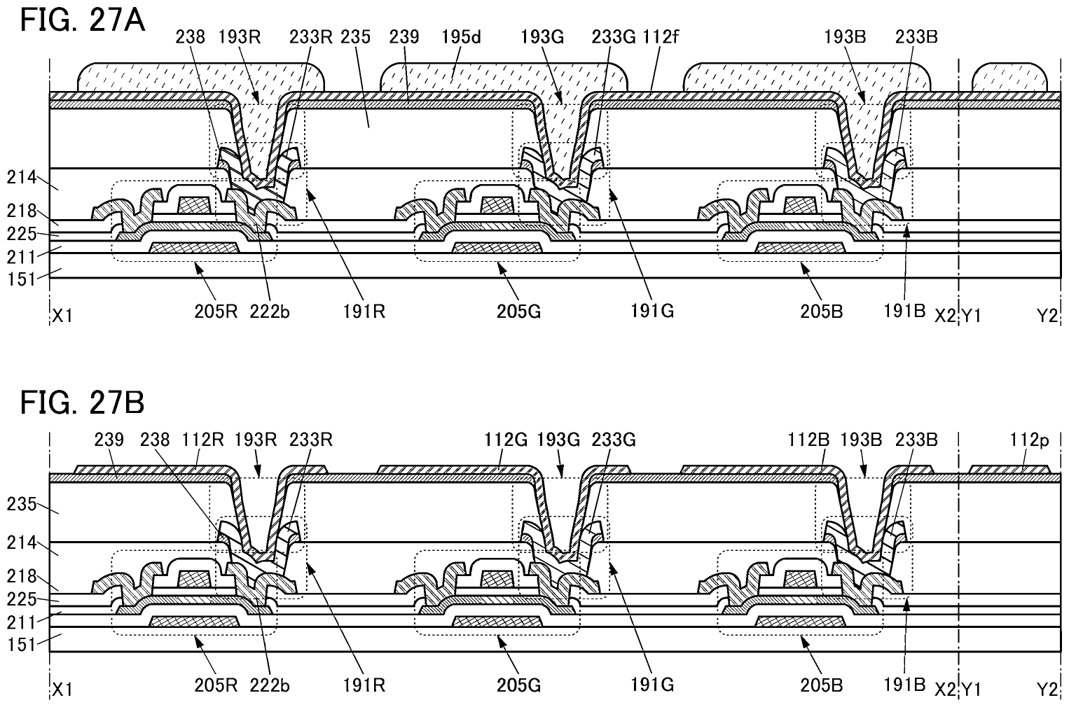

Subsequently, a resist mask 195d is formed over the conductive film 112f (FIG. 27A). The resist mask 195d may be formed using either a positive resist or a negative resist. The resist mask 195d includes a region overlapping with the conductive layer 223.

Next, the conductive film 112f is processed using the resist mask 195d as a mask, whereby the conductive layer 112R, the conductive layer 112G, the conductive layer 112B, and the conductive layer 112p are formed. Thus, the conductive layer 112R, the conductive layer 112G, and the conductive layer 112B which are in contact with the conductive layer 223 are formed. For processing of the conductive film 112f, either one or both of a wet etching method and a dry etching method are used.

At the time of processing the conductive film 233f, part of the insulating layer 238 is removed in some cases. For example, the thickness of the insulating layer 238 in a region overlapping with any of the conductive layer 112R, the conductive layer 112G, and the conductive layer 112B may be smaller than the thickness of the insulating layer 238 in a region overlapping with none of the conductive layer 112R, the conductive layer 112G, and the conductive layer 112B.

After that, the resist mask 195d is removed (FIG. 27B).

Next, a film 128f to be the layer 128 is formed to cover the insulating layer 239, the conductive layer 112R, the conductive layer 112R, the conductive layer 112G, the conductive layer 112B, and the conductive layer 112p. For the formation of the film 128f, a method similar to that for the insulating film 214f can be used.

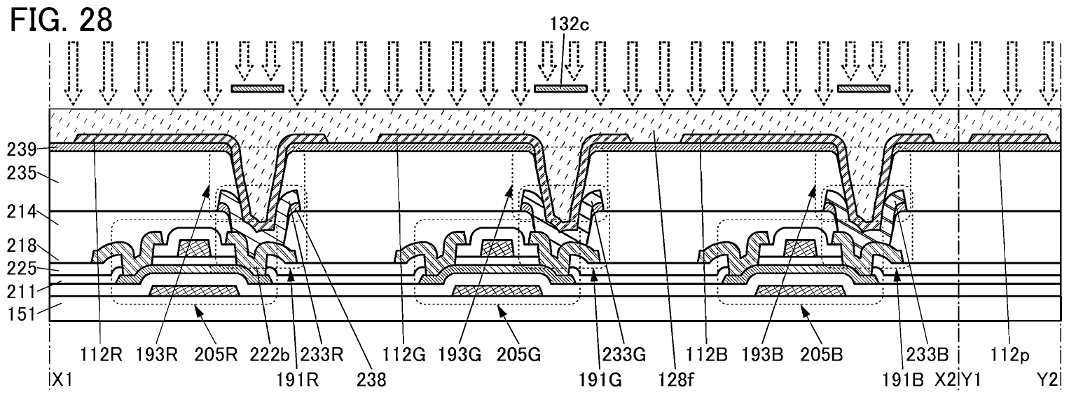

FIG. 28 schematically illustrates a state in which a photosensitive organic material is used for the film 128f and a region overlapping with the conductive layer 233 is exposed to light. In FIG. 28, light is indicated by arrows; a region where the layer 128 is not formed is exposed to light, and a region where the layer 128 is formed is shielded from light by a mask 132c. At this time, the shape of the layer 128 can be controlled by adjusting the amount of light exposure.

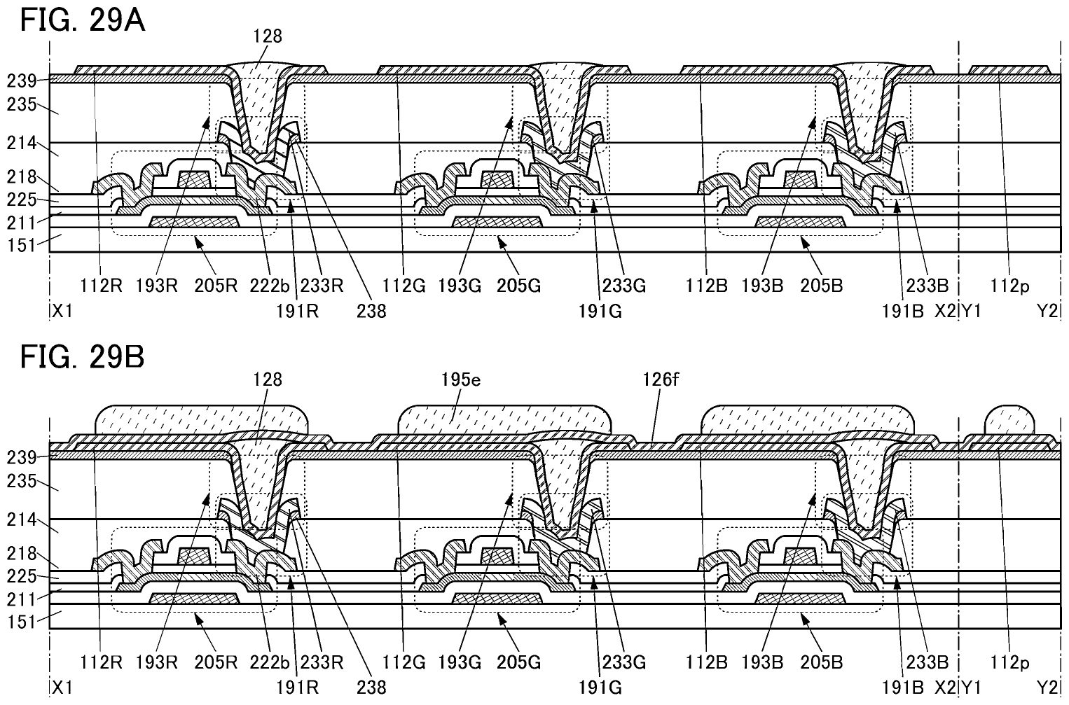

Next, development is performed to remove a region of the film 128f exposed to light, whereby the layer 128 is formed (FIG. 29A).

Although an example in which a positive photosensitive resin is used for the film 128f is described here, the present invention is not limited thereto. For example, a negative photosensitive resin may be used for the film 128f.

After the layer 128 is formed, heat treatment is preferably performed. For the heat treatment, the description of the heat treatment after the formation of the insulating layer 214 can be referred to; thus, the detailed description thereof is omitted.

Next, a conductive film 126f to be the conductive layer 126R, the conductive layer 126G, the conductive layer 126B, and the conductive layer 126p is formed to cover the insulating layer 239, the conductive layer 112R, the conductive layer 112G, the conductive layer 112B, the conductive layer 112p, and the layer 128.

Here, the conductive film 126f is provided over the insulating layer 239, the conductive layer 112R, the conductive layer 112G, the conductive layer 112B, the conductive layer 112p, and the layer 128. In the case where adhesion between the conductive film 126f and these films is low, film separation might occur. As a material used for the conductive film 126f, it is preferable to use a material having high adhesion to a formation surface of the conductive film 126f. For example, an alloy of silver, palladium, and copper (APC) has low adhesion with an insulating layer containing an inorganic material and film separation might occur when APC is provided over the insulating layer. In view of the above, in the case where an inorganic material is used for the insulating layer 239, a material that is highly adhesive to the insulating layer 239 is preferably used for the side of the conductive film 126f which is in contact with the insulating layer 239. For example, a stacked-layer structure of an In—Si—Sn oxide (ITSO), an alloy of silver, palladium, and copper (APC) over the In—Si—Sn oxide (ITSO) can be suitably used for the conductive film 126f. When a layer of the conductive film 126f which is in contact with the insulating layer 239 is an In—Si—Sn oxide (ITSO), film separation of the conductive film 126f can be inhibited even when an inorganic material is used for the insulating layer 239.

Note that a structure in which the insulating layer 239 is not provided and the conductive film 126f is provided over the insulating layer 235, the conductive layer 112R, the conductive layer 112G, the conductive layer 112B, the conductive layer 112p, and the layer 128 may be employed (see FIG. 2). In the case where an organic material is used for the insulating layer 235, a single-layer structure of silver, palladium, and copper (APC) can be used as the conductive film 126f.

Next, a resist mask 195e is formed over the conductive film 126f (FIG. 29B). The resist mask 195e may be formed using either a positive resist or a negative resist. The resist mask 195e is provided in a region overlapping with the conductive layer 112R, a region overlapping with the conductive layer 112G, a region overlapping with the conductive layer 112B, and a region overlapping with the conductive layer 112p.

Next, the conductive film 126f is processed using the resist mask 195e as a mask, whereby the conductive layer 126R, the conductive layer 126G, the conductive layer 126B, and the conductive layer 126p are formed. For processing of the conductive film 126f, either one or both of a wet etching method and a dry etching method are used.

After that, the resist mask 195e is removed.

Next, the conductive layer 129R, the conductive layer 129G, the conductive layer 129B, and the conductive layer 129p are formed. Here, a manufacturing method in which the conductive layer 129R, the conductive layer 129G, and the conductive layer 129B each have a stacked-layer structure and the conductive layer 129p has a single-layer structure is described. Note that one embodiment of the present invention is not limited thereto. The conductive layer 129R, the conductive layer 129G, and the conductive layer 129B may each have a single-layer structure or a stacked-layer structure. The conductive layer 129p may have a single-layer structure or a stacked-layer structure.

A conductive film 129af to be parts of the conductive layer 129R, the conductive layer 129G, and the conductive layer 129B is formed to cover the insulating layer 239, the conductive layer 112R, the conductive layer 112G, the conductive layer 112B, the conductive layer 112p, the conductive layer 126R, the conductive layer 126G, the conductive layer 126B, and the conductive layer 126p.

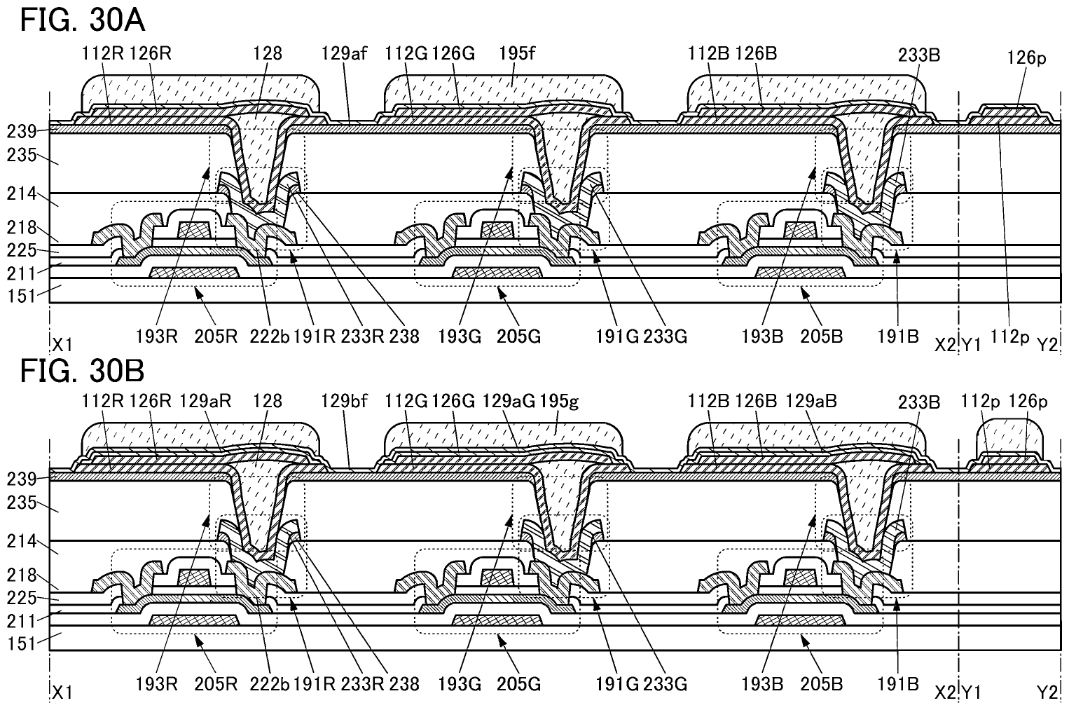

Subsequently, a resist mask 195f is formed over the conductive film 129af (FIG. 30A). The resist mask 195g may be formed using either a positive resist or a negative resist. The resist mask 195f is provided in a region overlapping with the conductive layer 112R, a region overlapping with the conductive layer 112G, and a region overlapping with the conductive layer 112B. Here, an example in which a resist mask is not provided in a region overlapping with the conductive layer 112p is described.

Next, the conductive film 129af is processed using the resist mask 195f as a mask, whereby a conductive layer 129aR, a conductive layer 129aG, and a conductive layer 129aB are formed. For processing of the conductive film 129af, either one or both of a wet etching method and a dry etching method are used.

After that, the resist mask 195f is removed.

Next, a conductive film 129bf to be parts of the conductive layer 129R, the conductive layer 129G, and the conductive layer 129B and the conductive layer 129p is formed to cover the insulating layer 239, the conductive layer 112R, the conductive layer 112G, the conductive layer 112B, the conductive layer 112p, the conductive layer 126R, the conductive layer 126G, the conductive layer 126B, the conductive layer 129aR, the conductive layer 129aG, the conductive layer 129aB, and the conductive layer 126p.

Subsequently, a resist mask 195g is formed over the conductive film 129bf (FIG. 30B). The resist mask 195g may be formed using either a positive resist or a negative resist. The resist mask 195g is provided in a region overlapping with the conductive layer 112R, a region overlapping with the conductive layer 112G, the conductive layer 112B, and a region overlapping with the conductive layer 112p.

Next, the conductive film 129bf is processed using the resist mask 195g as a mask, whereby a conductive layer 129bR, a conductive layer 129bG, a conductive layer 129bB, and the conductive layer 129p are formed. For processing of the conductive film 129bf, either one or both of a wet etching method and a dry etching method are used.

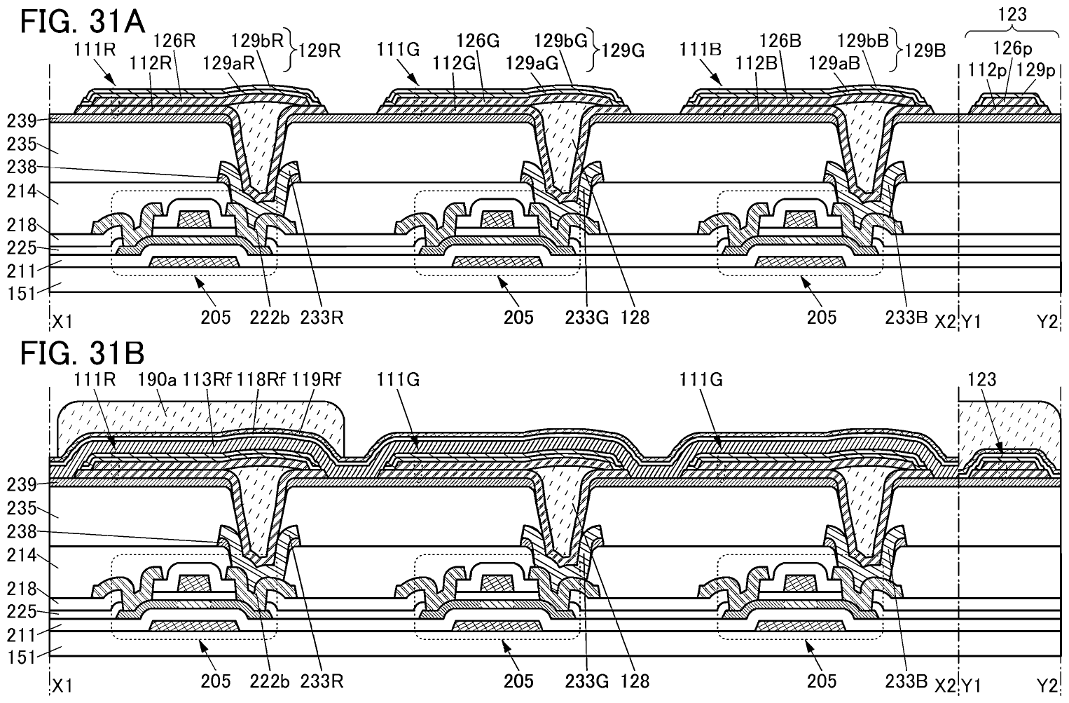

After that, the resist mask 195g is removed (FIG. 31A).

Thus, the conductive layer 129R having a stacked-layer structure of the conductive layer 129aR and the conductive layer 129bR, the conductive layer 129G having a stacked-layer structure of the conductive layer 129aG and the conductive layer 129bG, and the conductive layer 129B having a stacked-layer structure of the conductive layer 129aB and the conductive layer 129bB can be formed. The thickness of the conductive layer 129p can be smaller than the thickness of each of the conductive layer 129R, the conductive layer 129G, and the conductive layer 129B. For formation of these conductive films, a sputtering method or a vacuum evaporation method can be used, for example.

Then, the pixel electrode is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the pixel electrode can improve the adhesion between the pixel electrode and a film to be formed in a later step (here, a film 113Rf), thereby inhibiting film separation. Note that the hydrophobic treatment is not necessarily performed.

The hydrophobic treatment can be performed by fluorine modification of the pixel electrode, for example. The fluorine modification can be performed by treatment using a gas containing fluorine, heat treatment, plasma treatment in a gas atmosphere containing fluorine, or the like. A fluorine gas can be used as the gas containing fluorine, and for example, a fluorocarbon gas can be used. As the fluorocarbon gas, a low-molecular-weight carbon fluoride gas such as a carbon tetrafluoride (CF₄) gas, a C₄F₆ gas, a C₂F₆ gas, a C₄F₈ gas, or C₅F₈ can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

Treatment using a silylating agent is performed on the surface of the pixel electrode after plasma treatment is performed in a gas atmosphere containing a Group 18 element such as argon, so that the surface of the pixel electrode can have a hydrophobic property. As the silylating agent, hexamethyldisilazane (HMDS), trimethylsilylimidazole (TMSI), or the like can be used. Alternatively, treatment using a silane coupling agent is performed on the surface of the pixel electrode after plasma treatment is performed in a gas atmosphere containing a Group 18 element such as argon, so that the surface of the pixel electrode can have a hydrophobic property.

Plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. In addition, silane coupling by the silane coupling agent is likely to occur. As described above, treatment using a silylating agent or a silane coupling agent performed on the surface of the pixel electrode after plasma treatment in a gas atmosphere containing a Group 18 element such as argon enables the surface of the pixel electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the pixel electrode or the like by a gas phase method, for example. In a gas phase method, first, a material containing a silylating agent, a material containing a silane coupling agent, or the like is evaporated so that the silylating agent, the silane coupling agent, or the like is contained in an atmosphere. Next, a substrate where the pixel electrode and the like are formed is put in the atmosphere. Accordingly, a film containing the silylating agent, the silane coupling agent, or the like can be formed over the pixel electrode, so that the surface of the pixel electrode can have a hydrophobic property.

Next, the layer 113R, the layer 113G, and the layer 113B are formed. Although a method in which the layer 113R, the layer 113G, and the layer 113B are formed in this order is described here, one embodiment of the present invention is not limited thereto. For example, the layer 113R, the layer 113G, and the layer 113B can be formed in descending order of heat resistance of the materials included in the layers. The layer formed first preferably has high heat resistance because the layer passes through steps of forming the other layers. When the layer that includes a material with low heat resistance is formed at last, damage during the process can be reduced.

The film 113Rf to be the layer 113R is formed over the pixel electrode 111 (FIG. 31B).

As illustrated in FIG. 31B, the film 113Rf is not formed over the conductive layer 123 in the cross-sectional view along the dashed-dotted line Y1-Y2. For example, by using an area mask, the film 113Rf can be formed only in a desired region. A light-emitting device can be manufactured through a relatively simple process, by employing a film formation step using an area mask and a processing step using a resist mask.

As described in Embodiment 1, a material with high heat resistance is used for the light-emitting device of the display apparatus of one embodiment of the present invention. Specifically, the upper temperature limit of a compound contained in the film 113Rf is preferably higher than or equal to 100° C. and lower than or equal to 180° C., further preferably higher than or equal to 120° C. and lower than or equal to 180° C., still further preferably higher than or equal to 140° C. and lower than or equal to 180° C. In this case, the reliability of the light-emitting device can be improved. In addition, the upper limit of the temperature that can be applied in the manufacturing process of the display apparatus can be increased. Therefore, the range of choices of the materials and the formation method of the display apparatus can be widened, thereby improving the manufacturing yield and the reliability.

The film 113Rf can be formed by an evaporation method, specifically a vacuum evaporation method, for example. The film 113Rf may be formed by a method such as a transfer method, a printing method, an inkjet method, or a coating method.

Next, a mask film 118Rf to be the mask layer 118R and a mask film 119Rf to be a mask layer 119R are formed in this order over the film 113Rf and the conductive layer 123 (FIG. 31B).

Although this embodiment describes an example in which the mask film is formed with a two-layer structure of the mask film 118Rf and the mask film 119Rf, the mask film may have a single-layer structure of the mask film 118Rf or the mask film 119Rf or a stacked-layer structure of three or more layers.

Providing the mask layer over the film 113Rf can reduce damage to the film 113Rf in the manufacturing process of the display apparatus, resulting in an improvement in reliability of the light-emitting device.

As the mask film 118Rf, a film highly resistant to the processing conditions of the film 113Rf, specifically, a film having high etching selectivity to the film 113Rf is used. As the mask film 119Rf, a film having high etching selectivity to the mask film 118Rf is used.

The mask film 118Rf and the mask film 119Rf are formed at a temperature lower than the upper temperature limit of the film 113Rf. Each of the substrate temperatures at the time of forming the mask film 118Rf and the mask film 119Rf is preferably lower than or equal to 200° C., further preferably lower than or equal to 150° C., still further preferably lower than or equal to 120° C., yet still further preferably lower than or equal to 100° C., yet still further preferably lower than or equal to 80° C.

Examples of indicators of the upper temperature limit include the glass transition point, the softening point, the melting point, the thermal decomposition temperature, and the 5% weight loss temperature. The upper temperature limits of the layer 113R, the layer 113G, and the layer 113B can each be any of the above temperatures that are indicators of the upper temperature limit, preferably the lowest one among the temperatures.

As described above, a material with high heat resistance is used for the light-emitting device of the display apparatus of one embodiment of the present invention. Thus, the substrate temperature in formation of the mask film can be higher than or equal to 100° C., higher than or equal to 120° C., or higher than or equal to 140° C. For example, an inorganic insulating film formed at a higher temperature can be a film that is denser and has a higher barrier property. Therefore, forming the mask film at such a temperature can further reduce damage to the film 113Rf and improve the reliability of the light-emitting device.

As each of the mask film 118Rf and the mask film 119Rf, a film that can be removed by a wet etching method is preferably used. The use of a wet etching method can reduce damage to the film 113Rf in processing of the mask film 118Rf and the mask film 119Rf as compared with the case of using a dry etching method.

The mask film 118Rf and the mask film 119Rf can be formed by a sputtering method, an ALD method (a thermal ALD method or a PEALD method), a CVD method, or a vacuum evaporation method, for example. Alternatively, the aforementioned wet film formation method may be used for the formation.

The mask film 118Rf, which is formed over and in contact with the film 113Rf, is preferably formed by a formation method that causes less damage to the film 113Rf than a formation method of the mask film 119Rf. For example, the mask film 118Rf is preferably formed by an ALD method or a vacuum evaporation method rather than a sputtering method.

As each of the mask film 118Rf and the mask film 119Rf, it is possible to use one or more of a metal film, an alloy film, a metal oxide film, a semiconductor film, an organic insulating film, and an inorganic insulating film, for example.

For each of the mask film 118Rf and the mask film 119Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material capable of blocking ultraviolet rays is preferably used for one or both of the mask film 118Rf and the mask film 119Rf, in which case the film 113Rf can be inhibited from being irradiated with ultraviolet rays and deterioration of the film 113Rf can be inhibited.

A metal film or an alloy film is preferably used as one or both of the mask film 118Rf and the mask film 119Rf, in which case the film 113Rf can be inhibited from being damaged by plasma and deterioration of the film 113Rf can be inhibited. Specifically, the film 113Rf can be inhibited from being damaged by plasma in a step using a dry etching method, a step performing ashing, or the like. It is particularly preferable to use a metal film such as a tungsten film or an alloy film as the mask film 119Rf.

For each of the mask film 118Rf and the mask film 119Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (Mis one or more selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, Mis preferably one or more kinds selected from gallium, aluminum, and yttrium.

As the mask film, a film containing a material having a light-blocking property with respect to light, particularly ultraviolet rays, can be used. For example, a film having a reflecting property with respect to ultraviolet rays or a film absorbing ultraviolet rays can be used. Although a variety of materials, such as a metal having a light-blocking property with respect to ultraviolet rays, an insulator, a semiconductor, and a metalloid, can be used as the material having a light-blocking property, a film capable of being processed by etching is preferable, and a film having good processability is particularly preferable because part or the whole of the mask film is removed in a later step.

For example, a semiconductor material such as silicon or germanium can be used as a material with a high affinity for the semiconductor manufacturing process. Alternatively, an oxide or a nitride of the semiconductor material can be used. Alternatively, a non-metallic material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

The use of a film containing a material having a light-blocking property with respect to ultraviolet rays can inhibit the EL layer from being irradiated with ultraviolet rays in a light exposure step or the like. The EL layer is inhibited from being damaged by ultraviolet rays, so that the reliability of the light-emitting device can be improved.

Note that the film containing a material having a light-blocking property with respect to ultraviolet rays can have the same effect even when used as a material of an insulating film 125f that is described later.

As each of the mask film 118Rf and the mask film 119Rf, any of a variety of inorganic insulating films that can be used as the protective layer 131 can be used. In particular, an oxide insulating film is preferable because its adhesion to the film 113Rf is higher than that of a nitride insulating film. For example, an inorganic insulating material such as aluminum oxide, hafnium oxide, or silicon oxide can be used for each of the mask film 118Rf and the mask film 119Rf. As each of the mask film 118Rf and the mask film 119Rf, an aluminum oxide film can be formed by an ALD method, for example. The use of an ALD method is preferable because damage to a base (in particular, the EL layer) can be reduced.

For example, an inorganic insulating film (e.g., an aluminum oxide film) formed by an ALD method can be used as the mask film 118Rf, and an inorganic film (e.g., an In—Ga—Zn oxide film, a silicon film, or a tungsten film) formed by a sputtering method can be used as the mask film 119Rf.

Note that the same inorganic insulating film can be used for both the mask film 118Rf and the insulating layer 125 that is formed later. For example, an aluminum oxide film formed by an ALD method can be used for both the mask film 118Rf and the insulating layer 125. Here, for the mask film 118Rf and the insulating layer 125, the same film formation condition may be used or different film formation conditions may be used. For example, when the mask film 118Rf is formed under conditions similar to those for the insulating layer 125, the mask film 118Rf can be an insulating layer having a high barrier property against at least one of water and oxygen. Meanwhile, the mask film 118Rf is a layer most or all of which is to be removed in a later step, and thus is preferably easily processed. Therefore, the mask film 118Rf is preferably formed at a substrate temperature lower than that in formation of the insulating layer 125.

An organic material may be used for one or both of the mask film 118Rf and the mask film 119Rf. For example, as the organic material, a material that can be dissolved in a solvent chemically stable with respect to at least the uppermost film of the film 113Rf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 113Rf can be accordingly reduced.

For each of the mask film 118Rf and the mask film 119Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

For example, an organic film (e.g., a PVA film) formed by an evaporation method or the above wet film formation method can be used as the mask film 118Rf, and an inorganic film (e.g., a silicon nitride film) formed by a sputtering method can be used as the mask film 119Rf.

Note that as described in Embodiment 1, part of the mask film sometimes remains as a mask layer in the display apparatus of one embodiment of the present invention.

Next, a resist mask 190a is formed over the mask film 119Rf (FIG. 31B). For the resist mask 190a, either a positive resist or a negative resist may be used.

The resist mask 190a is provided at a position overlapping with the pixel electrode 111R. The resist mask 190a is preferably provided also at a position overlapping with the conductive layer 123. This can inhibit the conductive layer 123 from being damaged during the manufacturing process of the display apparatus. Note that the resist mask 190a is not necessarily provided over the conductive layer 123.

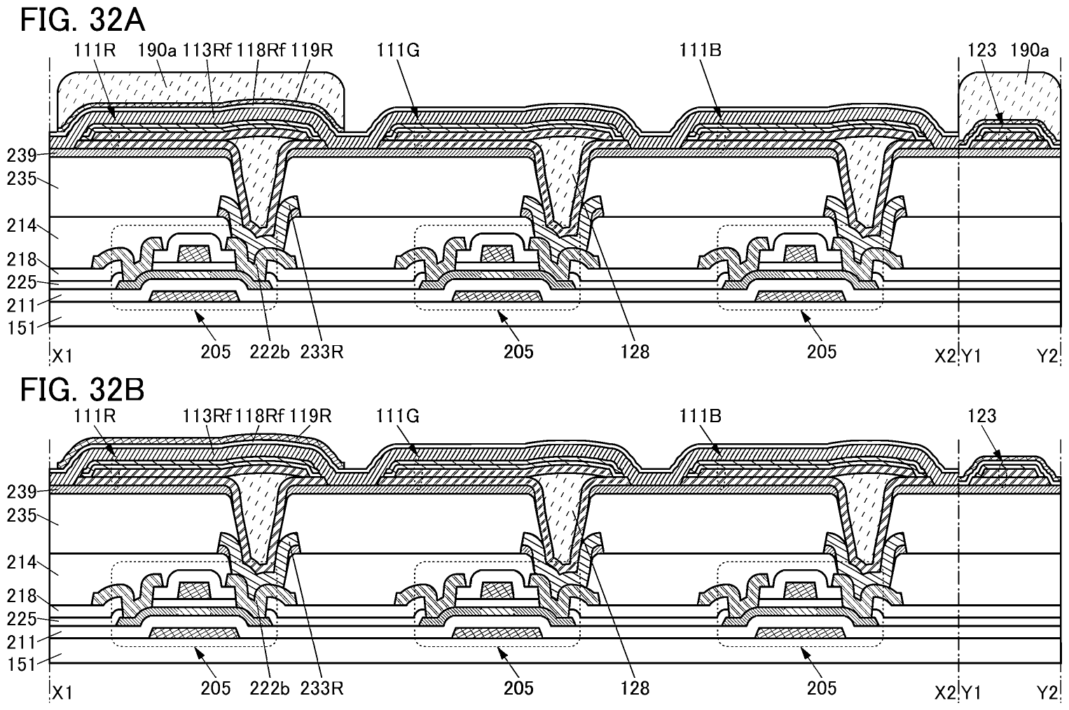

Next, part of the mask film 119Rf is removed with the use of the resist mask 190a as a mask, so that the mask layer 119R is formed (FIG. 32A). The mask layer 119R remains over the pixel electrode 111B and the conductive layer 123. After that, the resist mask 190a is removed (FIG. 32B). Next, part of the mask film 118Rf is removed using the mask layer 119R as a mask (also referred to as a hard mask), so that the mask layer 118R is formed.

The mask film 118Rf and the mask film 119Rf can be processed by a wet etching method or a dry etching method. The mask film 118Rf and the mask film 119Rf are preferably processed by anisotropic etching.

The use of a wet etching method can reduce damage to the film 113Rf in processing of the mask film 118Rf and the mask film 119Rf as compared with the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example.

Since the film 113Rf is not exposed in processing of the mask film 119Rf, the range of choices of the processing method is wider than that for processing of the mask film 118Rf. Specifically, deterioration of the film 113Rf can be further inhibited even when a gas containing oxygen is used as an etching gas for processing the mask film 119Rf.

In the case of using a dry etching method for processing the mask film 118Rf, deterioration of the film 113Rf can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas such as He as the etching gas, for example.

For example, when an aluminum oxide film formed by an ALD method is used as the mask film 118Rf, the mask film 118Rf can be processed by a dry etching method using CHF₃ and He or CHF₃, He, and CH₄. In the case where an In—Ga—Zn oxide film formed by a sputtering method is used as the mask film 119Rf, the mask film 119Rf can be processed by a wet etching method using a diluted phosphoric acid. Alternatively, the mask film 119Rf may be processed by a dry etching method using CH₄ and Ar. Alternatively, the mask film 119Rf can be processed by a wet etching method using a diluted phosphoric acid. When a tungsten film formed by a sputtering method is used as the mask film 119Rf, the mask film 119Rf can be processed by a dry etching method using SF₆, CF₄, and O₂ or CF₄, Cl₂, and O₂.

The resist mask 190a can be removed by ashing using oxygen plasma, for example. Alternatively, an oxygen gas and any of CF₄, C₄F₈, SF₆, CHF₃, Cl₂, H₂O, BCl₃, and a noble gas such as He may be used. Alternatively, the resist mask 190a may be removed by wet etching. At this time, the mask film 118Rf is positioned on the outermost surface, and the film 113Rf is not exposed; thus, the film 113Rf can be inhibited from being damaged in the step of removing the resist mask 190a. In addition, the range of choices of the method for removing the resist mask 190a can be widened.

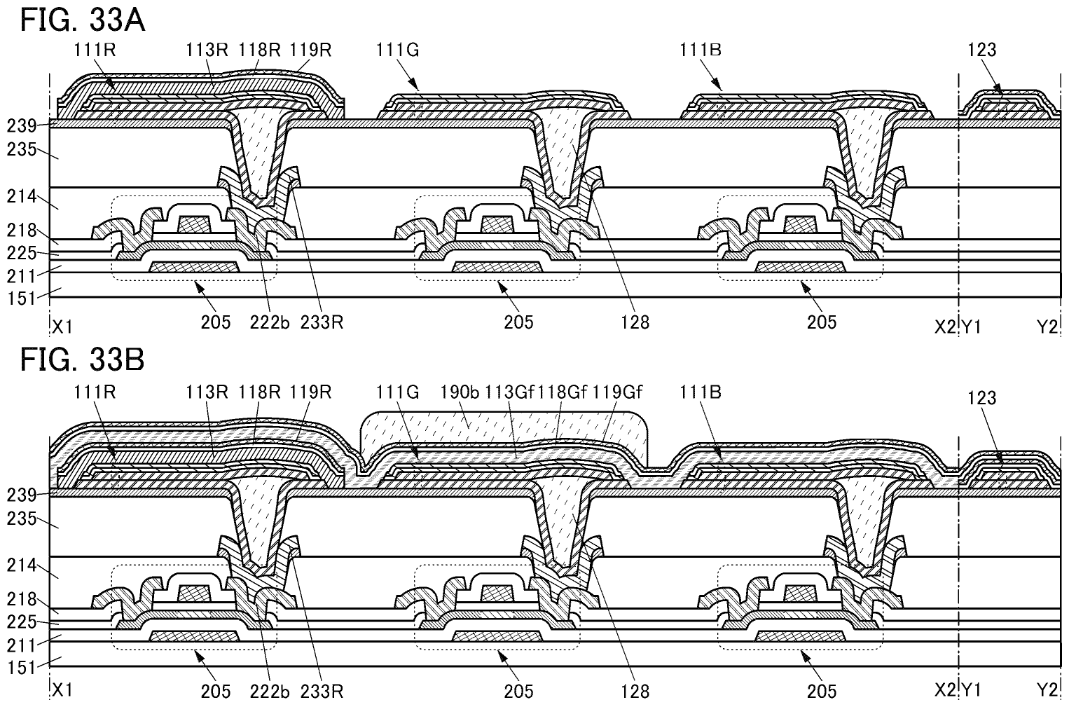

Next, the film 113Rf is processed to form the layer 113R. For example, part of the film 113Rf is removed using the mask layer 119R and the mask layer 118R as a hard mask, so that the layer 113R is formed (FIG. 33A).

Accordingly, as illustrated in FIG. 33A, the stacked-layer structure of the layer 113R, the mask layer 118R, and the mask layer 119R remains over the pixel electrode 111R. In addition, the pixel electrode 111G and the pixel electrode 111G are exposed.

Here, when the film 113Rf is processed, the surface of the pixel electrode 111G and the surface of the pixel electrode 111B are exposed to an etching gas or an etchant. On the other hand, the surface of the pixel electrode 111R is not exposed to an etching gas, an etchant, or the like. As described above, in the light-emitting device of the color formed first, the surface of the pixel electrode is not damaged by the etching process, whereby the interface between the pixel electrode and the EL layer can be kept favorable.

The film 113Rf is preferably processed by anisotropic etching. In particular, anisotropic dry etching is preferable. Alternatively, wet etching may be employed.

When the film 113Rf is processed by a dry etching method, the exposed surface is exposed to plasma. A metal film or an alloy film is preferably used for one or both of the mask layer 118R and the mask layer 119R, in which case a portion of the film 113Rf to be the layer 113R can be inhibited from being damaged by the plasma and thus deterioration of the layer 113R can be inhibited. In particular, a metal film such as a tungsten film or an alloy film is preferably used for the mask layer 119R.

In the case of using a dry etching method, deterioration of the film 113Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the film 113Rf can be reduced. Furthermore, a defect such as attachment of a reaction product generated at the etching can be inhibited.

In the case of using a dry etching method, it is preferable to use, as the etching gas, a gas containing one or more of H₂, CF₄, C₄F₈, SF₆, CHF₃, Cl₂, H₂O, BCl₃, and a noble gas such as He and Ar, for example. Alternatively, a gas containing oxygen and one or more of the above is preferably used as the etching gas. Alternatively, an oxygen gas may be used as the etching gas.

Specifically, for example, a gas containing H₂ and Ar or a gas containing CF₄ and He can be used as the etching gas. As another example, a gas containing CF₄, He, and oxygen can be used as the etching gas. As another example, a gas containing H₂ and Ar and a gas containing oxygen can be used as the etching gas.

A dry etching apparatus including a high-density plasma source can be used as the dry etching apparatus. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

FIG. 33A illustrates an example where the end portion of the layer 113R is positioned outward from the end portion of the pixel electrode 111R. Such a structure enables a high aperture ratio of a pixel. The insulating layer 239 can function as an etching protective film at the time of forming the layer 113, the mask layer 118, and the mask layer 119. When the insulating layer 239 is provided over the insulating layer 235, part of the insulating layer 235 can be inhibited from being removed at the time of forming the layer 113, the mask layer 118, and the mask layer 119.

When the layer 113R covers the top surface and side surfaces of the pixel electrode 111R, the following steps can be performed without exposing the pixel electrode 111R. When the end portions of the pixel electrode 111R are exposed, corrosion might occur in the etching step or the like. A product generated by corrosion of the electrode 111R might be unstable; for example, the product might be dissolved in a solution in wet etching and might be diffused in an atmosphere in dry etching. The product dissolved in a solution or diffused in an atmosphere might be attached to a surface to be processed, the side surface of the layer 113B, and the like, which may adversely affect the characteristics of the light-emitting device or may form a leakage path between the plurality of light-emitting devices. In a region where the end portion of the pixel electrode 111R is exposed, the adhesion between contacting layers is reduced, which might facilitate film separation of the layer 113R or the pixel electrode 111R.

Thus, when the layer 113R covers the top surface and side surfaces of the pixel electrode 111R, the yield and characteristics of the light-emitting device can be improved, for example.

When the layer 113R covers the top surface and the side surface of the pixel electrode 111R, the layer 113R is provided with a dummy region outside the light-emitting region (a region positioned between the pixel electrode 111R and the common electrode 115). Here, the end portion of the layer 113R is sometimes damaged at the time of processing the film 113Rf. In addition, the end portion of the layer 113R is sometimes damaged by being exposed to plasma in a later step. The end portion of the layer 113R and the vicinity thereof are dummy regions and not used as light-emitting regions; thus, such regions are less likely to adversely affect the characteristics of the light-emitting device even when being damaged. Meanwhile, the light-emitting region of the layer 113R is covered with the mask layer, and thus is not exposed to plasma and plasma damage is sufficiently reduced. The mask layer is preferably provided to cover not only a top surface of a flat portion of the layer 113R overlapping with the top surface of the pixel electrode 111R, but also top surfaces of an inclined portion and a flat portion of the layer 113R that are positioned on the outer side of the top surface of the pixel electrode 111R. A portion of the layer 113R with reduced damage in the manufacturing process is used as the light-emitting region in this manner; thus, a light-emitting device having high emission efficiency and a long lifetime can be achieved.

In a region corresponding to the connection portion 140, a stacked-layer structure of the mask layer 118R and the mask layer 119R remains over the conductive layer 123.

As described above, in one embodiment of the present invention, the resist mask 190a is formed over the mask film 119Rf and part of the mask film 119Rf is removed using the resist mask 190a, so that the mask layer 119R is formed. After that, part of the film 113Rf is removed using the mask layer 119R as a hard mask, so that the layer 113R is formed. Thus, it can be said that the layer 113R is formed by processing the film 113Rf by a photolithography method. Note that part of the film 113Rf may be removed using the resist mask 190a. Then, the resist mask 190a may be removed.

Next, the pixel electrode is preferably subjected to hydrophobic treatment. In processing of the film 113Rf, the surface state of the pixel electrode changes to a hydrophilic state in some cases. The hydrophobic treatment for the pixel electrode can improve the adhesion between the pixel electrode and a film to be formed in a later step (here, the film 113Gf), thereby inhibiting film separation. Note that the hydrophobic treatment is not necessarily performed.

Next, the film 113Gf to be the layer 113G is formed over the pixel electrode 111G, the pixel electrode 111B, and the mask layer 119R (FIG. 33B).

The film 113Gf can be formed by a method similar to a method that can be employed for forming the film 113Rf.

Next, over the film 113Gf, a mask film 118Gf to be the mask layer 118G and a mask film 119Gf to be a mask layer 119G later are formed in this order, and then a resist mask 190b is formed (FIG. 15C). The materials and the formation methods of the mask film 118Gf and the mask film 119Gf are similar to conditions applicable to the mask film 118Rf and the mask film 119Rf. The materials and the formation method of the resist mask 190b are similar to conditions applicable to the resist mask 190a.

The resist mask 190b is provided at a position overlapping with the pixel electrode 111G.

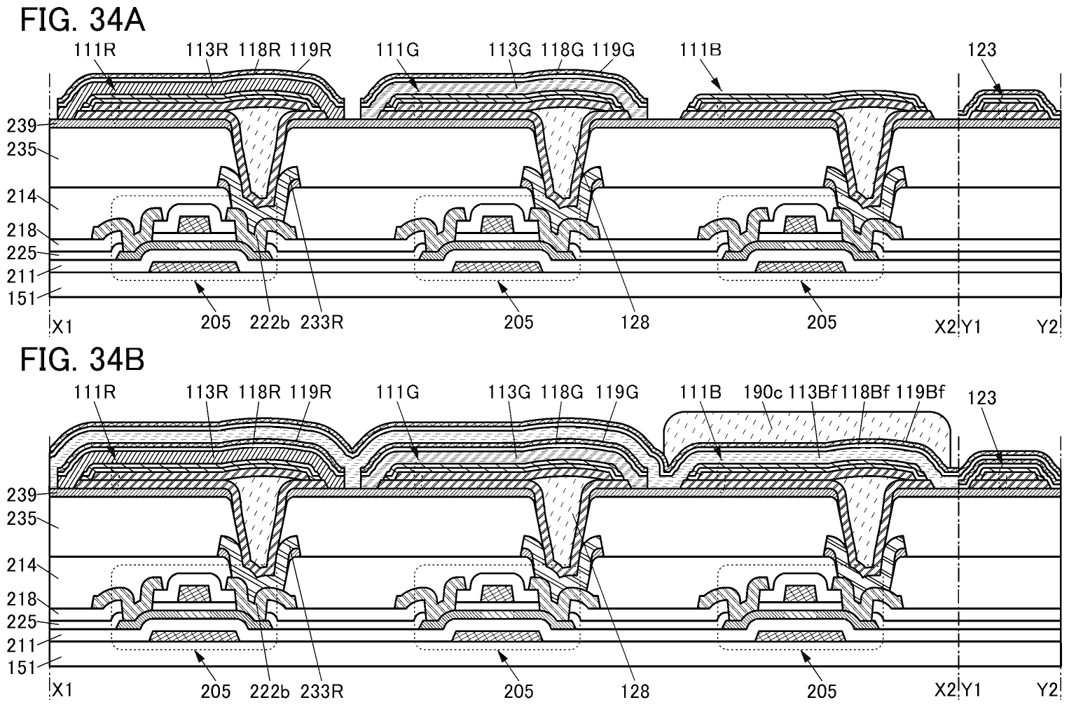

Next, part of the mask film 119Gf is removed with the use of the resist mask 190b, so that the mask layer 119G is formed. The mask layer 119G remains over the pixel electrode 111G. After that, the resist mask 190b is removed. Next, part of the mask film 118Gf is removed using the mask layer 119G as a mask, so that the mask layer 118G is formed. Next, the film 113Gf is processed to form the layer 113G. For example, part of the film 113Gf is removed using the mask layer 119G and the mask layer 118G as a hard mask, so that the layer 113G is formed (FIG. 34A).

Here, in processing of the film 113Gf, the surface of the pixel electrode 111B is exposed to an etching gas, an etchant, or the like. On the other hand, the surface of the pixel electrode 111R and the surface of the pixel electrode 111G are not exposed to an etching gas, an etchant, or the like. That is, the surface of the pixel electrode in the light-emitting device of the color formed second is exposed in one etching step, and the surface of the pixel electrode in the light-emitting device of the color formed third is exposed in two etching steps. Therefore, an island-shaped EL layer of a light-emitting device in which the surface state of a pixel electrode is more likely to affect its characteristics is preferably formed earlier. This can increase the characteristics of the light-emitting device of each color.

Accordingly, as illustrated in FIG. 17A, the stacked-layer structure of the layer 113G, the mask layer 118G, and the mask layer 119G remains over the pixel electrode 111G. In addition, the mask layer 119R and the pixel electrode 111B are exposed.

Next, the pixel electrode is preferably subjected to hydrophobic treatment. In processing of the film 113Gf, the surface state of the pixel electrode changes to a hydrophilic state in some cases. The hydrophobic treatment for the pixel electrode can improve the adhesion between the pixel electrode and a film to be formed in a later step (here, the film 113Bf), thereby inhibiting film separation. Note that the hydrophobic treatment is not necessarily performed.

Next, the film 113Bf to be the layer 113B is formed over the pixel electrode 111B, the mask layer 119R, and the mask layer 119G (FIG. 34B).

The film 113Bf can be formed by a method similar to a method that can be employed for forming the film 113Rf.

Next, over the film 113Bf, a mask film 118Bf to be the mask layer 118B and a mask film 119Bf to be a mask layer 119B are formed in this order, and then a resist mask 190c is formed (FIG. 34B). The materials and the formation methods of the mask film 118Bf and the mask film 119Bf are similar to conditions applicable to the mask film 118Rf and the mask film 119Rf. The materials and the formation method of the resist mask 190c are similar to conditions applicable to the resist mask 190a.

The resist mask 190c is provided at a position overlapping with the pixel electrode 111B.

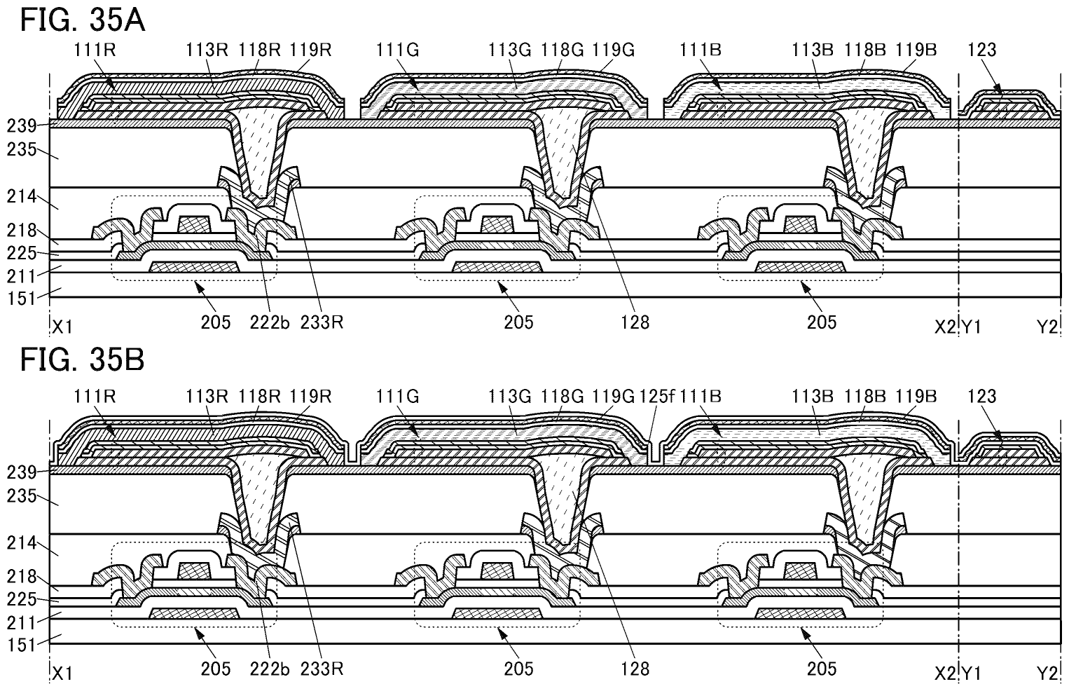

Next, part of the mask film 119Bf is removed with the use of the resist mask 190c as a mask, so that the mask layer 119B is formed. The mask layer 119B remains over the pixel electrode 111B. After that, the resist mask 190c is removed. Next, part of the mask film 118Bf is removed using the mask layer 119B as a mask, so that the mask layer 118B is formed. Next, the film 113Bf is processed to form the layer 113B. For example, part of the film 113Bf is removed using the mask layer 119B and the mask layer 118B as a hard mask, so that the layer 113B is formed (FIG. 35A).

Accordingly, as illustrated in FIG. 35A, the stacked-layer structure of the layer 113B, the mask layer 118B, and the mask layer 119B remains over the pixel electrode 111B. In addition, the mask layer 119R and the mask layer 119G are exposed.

Note that side surfaces of the layer 113R, the layer 113G, and the layer 113B are preferably perpendicular or substantially perpendicular to their formation surfaces. For example, the angle between the formation surfaces and these side surfaces is preferably greater than or equal to 60° and less than or equal to 90°.

As described above, the distance between adjacent two layers among the layer 113R, the layer 113G, and the layer 113B formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between facing end portions of adjacent two layers among the layer 113B, the layer 113G, and the layer 113R. When the distance between the island-shaped EL layers is shortened in this manner, a display apparatus with a high resolution and a high aperture ratio can be provided.

Next, the mask layer 119B, the mask layer 119G, and the mask layer 119R may be removed. For example, in the case where the mask layer 119R, the mask layer 119G, and the mask layer 119B each contain the aforementioned material having a light-blocking property with respect to ultraviolet rays, the mask layers preferably remain without being removed, in which case the island-shaped EL layers can be protected from ultraviolet rays.

In the case where the mask layers are removed, a method similar to that for the step of processing the mask layers can be used. In particular, the use of a wet etching method can reduce damage to the layer 113R, the layer 113G, and the layer 113B at the time of removing the mask layers compared with the case of using a dry etching method.

The use of a metal film or an alloy film for the mask layer 119R, the mask layer 119G, and the mask layer 119B can reduce plasma damage to the EL layer. Therefore, a dry etching method can be used in the process of manufacturing the light-emitting device. In the case where the mask layer 119B, the mask layer 119G, and the mask layer 119R are removed, the film inhibiting plasma damage to the EL layers does not exist in the step of removal and the steps after the removal; thus, film processing is preferably performed by a method that does not use plasma, such as a wet etching method.

The mask layer may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water contained in the layer 113R, the layer 113G, and the layer 113B and water adsorbed onto the surfaces of the layer 113R, the layer 113G, and the layer 113B. For example, heat treatment in an inert gas atmosphere such as a nitrogen atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because drying at a lower temperature is possible.

Next, the insulating film 125f to be the insulating layer 125 is formed to cover the insulating layer 239, the layer 113R, the layer 113G, the layer 113B, the mask layer 118R, the mask layer 118G, the mask layer 118B, the mask layer 119R, the mask layer 119G, the mask layer 119B, and the conductive layer 123 (FIG. 35B).

After that, an insulating film 127f to be the insulating layer 127 is formed in contact with a top surface of the insulating film 125f. Thus, the top surface of the insulating film 125f preferably has high adhesion to a resin composite (e.g., a photosensitive resin composite containing an acrylic resin) that is used for the insulating film 127f. To improve the adhesion, the top surface of the insulating film 125f is preferably made hydrophobic (or more hydrophobic) by surface treatment. For example, the treatment is preferably performed using a silylating agent such as hexamethyldisilazane (HMDS). By making the top surface of the insulating film 125f hydrophobic in this manner, the insulating film 127f to be the insulating layer 127 can be formed with high adhesion. Note that the above-described hydrophobic treatment may be performed as the surface treatment.

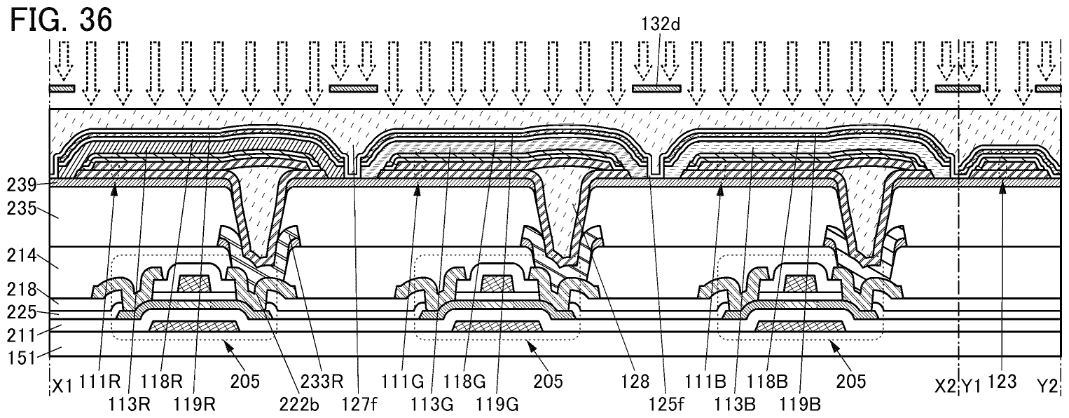

Then, the insulating film 127f to be the insulating layer 127 is formed over the insulating film 125f (FIG. 36).

The insulating film 125f and the insulating film 127f are preferably formed by a formation method that causes less damage to the layer 113R, the layer 113G, and the layer 113B. In particular, the insulating film 125f, which is formed in contact with the side surfaces of the layer 113R, the layer 113G, and the layer 113B, is preferably formed by a formation method that causes less damage to the layer 113R, the layer 113G, and the layer 113B than the method of forming the insulating film 127f.

The insulating film 125f and the insulating film 127f are formed at a temperature lower than the upper temperature limits of the layer 113R, the layer 113G, and the layer 113B. When the insulating film 125f is formed at a high substrate temperature, the formed film, even with a small thickness, can have a low impurity concentration and a high barrier property against at least one of water and oxygen.

The insulating film 125f and the insulating film 127f are preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As described above, a material with high heat resistance is used for the light-emitting device of the display apparatus of one embodiment of the present invention. Thus, the substrate temperature in formation of the insulating film 125f and the insulating film 127f can be higher than or equal to 100° C., higher than or equal to 120° C., or higher than or equal to 140° C. For example, an inorganic insulating film formed at a higher temperature can be a film that is denser and has a higher barrier property. Therefore, forming the insulating film 125f at such a temperature can further reduce damage to the layer 113B, the layer 113G, and the layer 113R and improve the reliability of the light-emitting device.

As the insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. The use of an ALD method is preferable because damage due to film formation can be reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display apparatus can be manufactured with high productivity.

The insulating film 127f is preferably formed by the aforementioned wet film formation method. For example, the insulating film 127f is preferably formed by spin coating using a photosensitive resin, specifically, a photosensitive resin composite containing an acrylic resin.

Heat treatment (also referred to as pre-baking) is preferably performed after formation of the insulating film 127f. The heat treatment is performed at a temperature lower than the upper temperature limits of the layer 113R, the layer 113G, and the layer 113B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 127f can be removed.

FIG. 36 schematically illustrates a state in which a photosensitive organic material is used for the insulating film 127f and a region overlapping with the pixel electrode 111R, a region overlapping with the pixel electrode 111G, a region overlapping with the pixel electrode 111B, and a region overlapping with the conductive layer 123 are exposed to light. In FIG. 36, light is indicated by arrows; the region where the insulating layer 127 is not formed is exposed to light, and the region where the insulating layer 127 is formed is shielded from light by the mask 132d.

At this time, the shape of the insulating layer 127 can be controlled by adjusting the amount of light exposure. The insulating layer 127 is preferably processed to include a portion overlapping with the top surface of the pixel electrode 111.

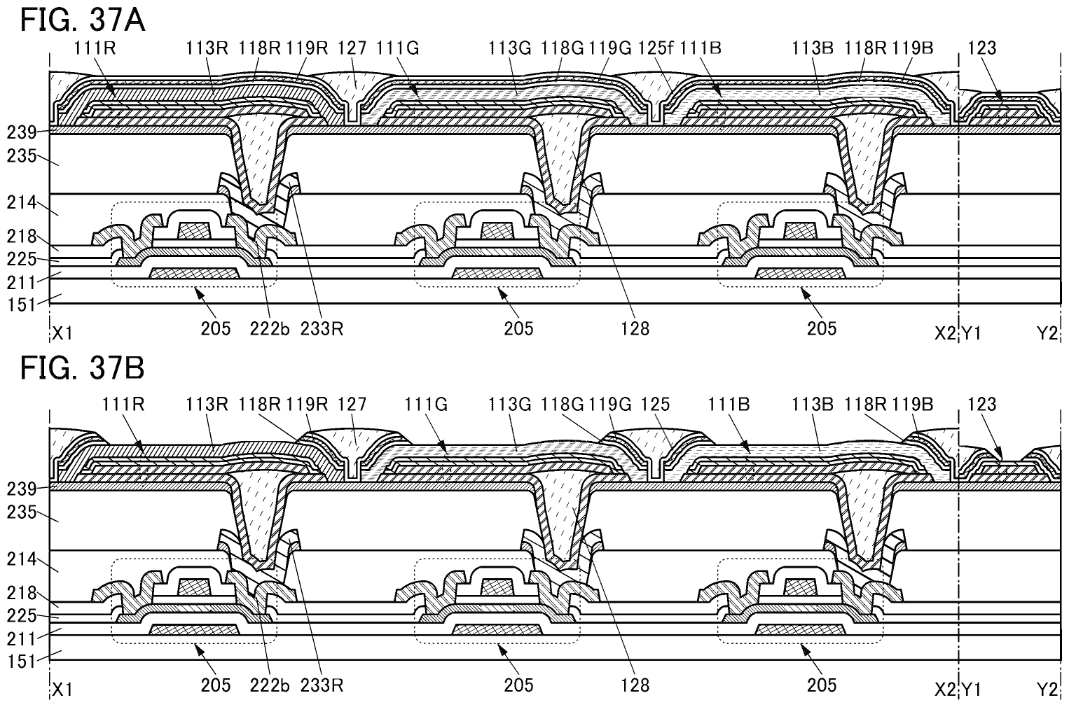

Next, development is performed to remove a region of the insulating film 127f exposed to light, whereby the insulating layer 127 is formed (FIG. 37A). The insulating layer 127 is provided in a region between adjacent pixel electrodes 111 and a region surrounding the conductive layer 123. For example, in the case where an acrylic resin is used for the insulating film 127f, an alkaline solution is preferably used as a developer, and for example, an aqueous solution of tetramethyl ammonium hydroxide (TMAH) can be used.

Although an example in which a positive photosensitive resin is used for the insulating film 127f is described here, the present invention is not limited thereto. For example, a negative photosensitive resin may be used for the insulating film 127f.

Note that a process for removing a residue generated in development (what is called a scum) may be performed after development. For example, the residue can be removed by ashing using oxygen plasma. The process for removing a residue may be performed after each development step described below.

Etching may be performed to adjust the surface level of the insulating layer 127. The insulating layer 127 may be processed by ashing using oxygen plasma, for example.

Note that after development and before post-baking, light exposure may be performed on the entire substrate, by which the insulating layer 127 is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after development can improve the transparency of the insulating layer 127 in some cases. In addition, the insulating layer 127 can be changed into a tapered shape at low temperature in some cases.

In contrast, when light exposure is not performed on the insulating layer 127, the shape of the insulating layer 127 can be easily changed or the insulating layer 127 can be easily changed into a tapered shape in a later process in some cases. Thus, it is sometimes preferable not to perform light expose on the insulating layer 127 after the development.

After that, heat treatment (also referred to as post-baking) may be performed. The heat treatment can change the shape of the side surface of the insulating layer 127. Specifically, the taper angle of the insulating layer 127 can be small. The heat treatment is performed at a temperature lower than the upper temperature limit of the EL layers. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. A reduced-pressure atmosphere is preferable because drying at a lower temperature is possible. The heat treatment in this step is preferably performed at a higher substrate temperature than the heat treatment (pre-baking) after formation of the insulating film 127f. In this case, the adhesion between the insulating layer 127 and the insulating layer 125 and the corrosion resistance of the insulating layer 127 can be improved.

As illustrated in FIG. 6A and FIG. 6B, the side surface of the insulating layer 127 might have a concave shape depending on the materials for the insulating layer 127, or the temperature, time, and atmosphere of the post-baking. For example, the insulating layer 127 is more likely to be changed in shape to have a concave shape as the temperature is higher or the time is longer in the post-baking conditions. In addition, as described above, in the case where light exposure is not performed on the insulating layer 127 after development, the shape of the insulating layer 127 is sometimes easily changed at the time of the post-baking.

Next, parts of the insulating film 125f, the mask layer 119R, the mask layer 119G, the mask layer 119B, the mask layer 118R, the mask layer 118G, and the mask layer 118B are removed using the insulating layer 127 as a mask. Thus, the insulating layer 125 is formed and openings are formed in the mask layer 119R, the mask layer 119G, the mask layer 119B, the mask layer 118R, the mask layer 118G, and the mask layer 118B to expose parts of the top surfaces of the layer 113G, the layer 113G, the layer 113R, and the conductive layer 123 (FIG. 37B).

For the processing of the insulating film 125f, the mask layer 119R, the mask layer 119G, the mask layer 119B, the mask layer 118R, the mask layer 118G, and the mask layer 118B, one or both of a wet etching method and a dry etching method may be used. Using a wet etching method can reduce damage to the layer 113B, the layer 113G, and the layer 113R, as compared with the case of using a dry etching method. For example, for wet etching of an aluminum oxide film, it is preferable to use an aqueous solution of tetramethyl ammonium hydroxide (TMAH) that is an alkaline solution. For wet etching of an In—Ga—Zn oxide film, phosphoric acid or an etchant containing phosphoric acid is preferably used.

In the case of using a dry etching method, a chlorine-based gas is preferably used. As the chlorine-based gas, Cl₂, BCl₃, SiCl₄, CCl₄, or the like can be used alone or two or more of the gases can be mixed and used. Moreover, one or more of an oxygen gas, a hydrogen gas, a helium gas, an argon gas, and the like can be mixed with the chlorine-based gas. Moreover, one or more of an oxygen gas, a hydrogen gas, a helium gas, an argon gas, and the like can be mixed with the chlorine-based gas as appropriate.

In the case of using a dry etching method, a by-product or the like generated by the dry etching is sometimes deposited on the top surface and the side surface of the insulating layer 127. Thus, a component contained in the etching gas, a component contained in the insulating film 125f, components contained in the mask layer 118R, the mask layer 118G, the mask layer 118B, the mask layer 119R, the mask layer 119G, and the mask layer 119B might be contained in the insulating layer 127.

As described above, providing the insulating layer 127, the insulating layer 125, the mask layer 118R, the mask layer 118G, the mask layer 118B, the mask layer 119R, the mask layer 119G, and the mask layer 119B can inhibit the common layer 114 and the common electrode 115 between the light-emitting devices from having connection defects due to a disconnected portion and an increase in electric resistance due to a locally thinned portion. Thus, the display quality of the display apparatus of one embodiment of the present invention can be improved.

After parts of the layer 113B, the layer 113G, and the layer 113R are exposed, additional heat treatment may be performed. The heat treatment can remove water contained in the EL layer, water adsorbed onto the surface of the EL layer, and the like. In addition, the heat treatment changes the shape of the insulating layer 127 in some cases. Specifically, the insulating layer 127 may extend to cover at least one of end portions of the insulating layer 125, the mask layer 118R, the mask layer 118G, the mask layer 118B, the mask layer 119R, the mask layer 119G, and the mask layer 119B (see FIG. 6B). Furthermore, the insulating layer 127 may extend to cover at least one of the top surfaces of the layer 113R, the layer 113G, and the layer 113B (see FIG. 6B to FIG. 8B). For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because dehydration at a lower temperature is possible. Note that the temperature range of the heat treatment is preferably determined as appropriate in consideration of the upper temperature limit of the EL layer. In consideration of the upper temperature limit of the EL layer, temperatures higher than or equal to 70° C. and lower than or equal to 120° C. are particularly preferable in the above temperature range.

Here, when the insulating layer 125 and the mask layer are collectively etched after the post-baking, the insulating layer 125 and the mask layer below the end portion of the insulating layer 127 are eliminated by side etching and accordingly a cavity is formed in some cases. The cavity causes unevenness in the formation surface of the common layer 114 and the common electrode 115, so that step disconnection is likely to occur in the common layer 114 and the common electrode 115. To avoid this, the etching treatment for the insulating layer 125 and etching treatment for the mask layer are preferably performed separately before and after the post-baking.

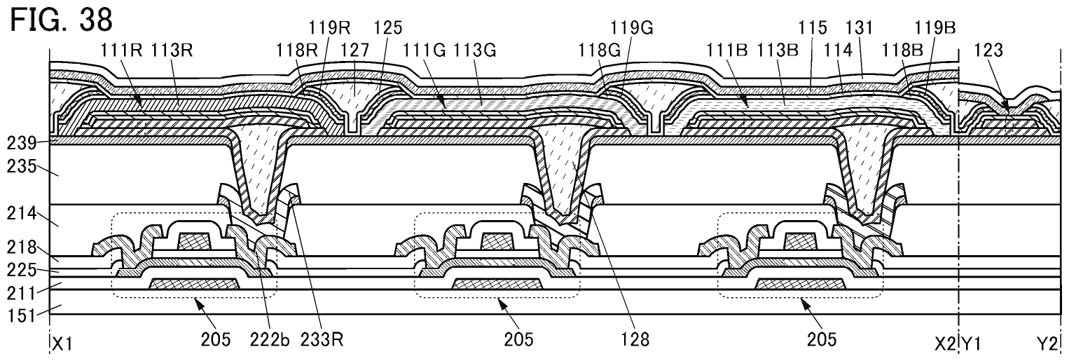

Next, the common layer 114, the common electrode 115, and the protective layer 131 are formed over the insulating layer 127, the layer 113R, the layer 113G, and the layer 113B (FIG. 38).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

Examples of methods for forming the protective layer 131 include a vacuum evaporation method, a sputtering method, a CVD method, and an ALD method.

Next, the substrate 120 is prepared, and the light-blocking layer 117 is formed over the substrate 120. Then, the substrate 120 and the light-blocking layer 117 are bonded to each other with the resin layer 122 over the protective layer 131, whereby the display apparatus can be manufactured (FIG. 16).

By providing the insulating layer 214 and the insulating layer 235 functioning as planarization layers, unevenness of the formation surface of the light-emitting device 130 and the like is reduced. Accordingly, the processing accuracy of the light-emitting devices 130 and the like provided over the insulating layer 235 is increased, whereby the display apparatus can have high resolution.

A film to be the layer 113R, the layer 113G, and the layer 113R is formed on an entire surface and then processed to form the layer 113R with an island shape, the layer 113G with an island shape, and the layer 113R with an island shape; in this manner, an island-shaped layer with a uniform thickness can be formed. Consequently, a high-resolution display apparatus or a high-aperture ratio display apparatus can be obtained. Furthermore, even when the resolution or the aperture ratio is high and the distance between subpixels is extremely short, the layer 113R, the layer 113G, and the layer 113B can be inhibited from being in contact with one another between adjacent subpixels. Accordingly, generation of leakage current between subpixels can be inhibited. Thus, the display apparatus of one embodiment of the present invention can have both a higher resolution and higher display quality.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display apparatus of one embodiment of the present invention can have both a higher resolution and higher display quality.

### Manufacturing Method Example 2

A method of manufacturing the display apparatus illustrated in FIG. 18 is described. Note that description of the same portions as the above is omitted and different portions will be described.

First, as in Manufacturing method example 1, the pixel electrode 111R, the pixel electrode 111G, the pixel electrode 111B, and the conductive layer 123 are formed (FIG. 31A). The above description can be referred to for the formation of components up to the pixel electrode 111R, the pixel electrode 111G, the pixel electrode 111B, and the conductive layer 123; thus, the detailed description thereof is omitted.

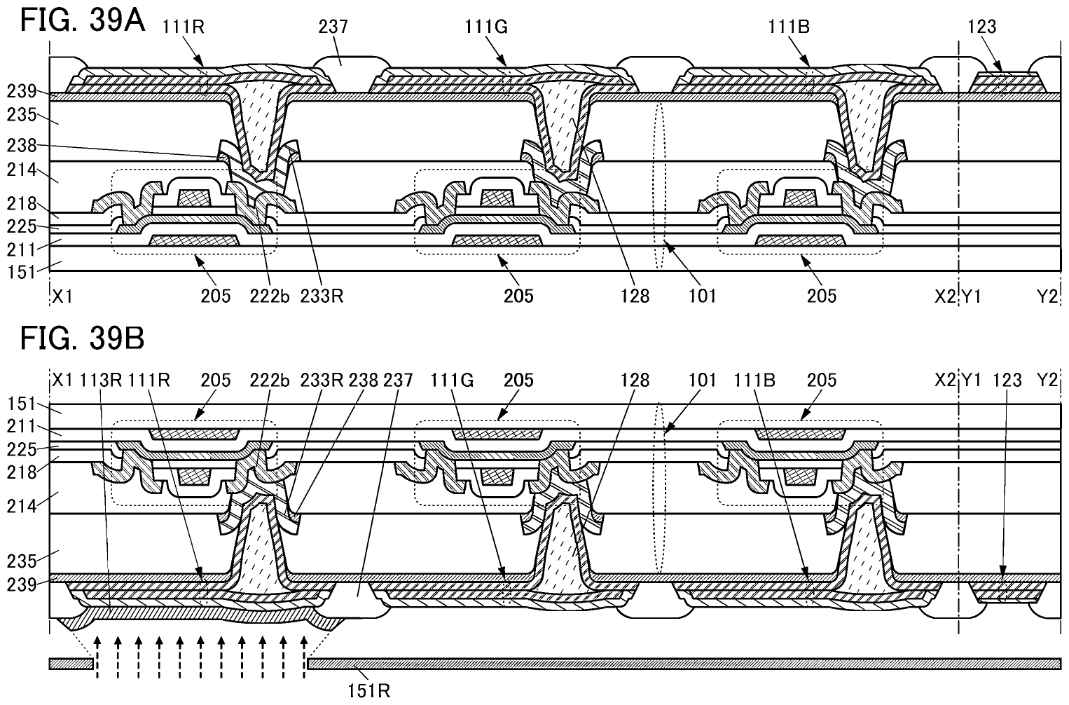

Then, the insulating layer 237 is formed to cover the end portions of the pixel electrode 111R, the pixel electrode 111G, the pixel electrode 111B, and the conductive layer 123 (FIG. 39A). An organic insulating film or an inorganic insulating film can be used for the insulating layer 237. End portions of the insulating layer 237 are preferably tapered. When the end portion of the insulating layer 237 has a tapered shape, coverage with the film formed later can be increased. In particular, a photosensitive material is preferably used as the organic insulating film, in which case the shape of the end portion can be easily controlled by the conditions of light exposure and development. Note that for the insulating layer 237, an inorganic insulating film may be used. Using an inorganic insulating film for the insulating layer 237 enables the display apparatus 100 to have high resolution.

Next, the layer 113R with an island shape is formed on the surface of the pixel electrode 111R (FIG. 39B).

The layer 113R is preferably formed by a vacuum evaporation method using a fine metal mask. Note that the island-shaped layer 113R may be formed by a sputtering method using a fine metal mask or an inkjet method.

FIG. 39B schematically illustrates a state in which the layer 113R is formed using the fine metal mask 151R. FIG. 39B illustrates a state of forming the layer 113R by what is called a face-down method, in which deposition is performed with the substrate turned upside down such that the surface where the layer 113R is formed faces downward.

In the vacuum evaporation method using a fine metal mask, deposition is performed in an area wider than an opening of the fine metal mask in many cases. As indicated by the dashed line in FIG. 39B, the layer 113R can be formed in an area wider than an opening of the fine metal mask 151R. The end portion of the layer 113R is tapered. The layer 113R may also be formed on the surface of the insulating layer 237.

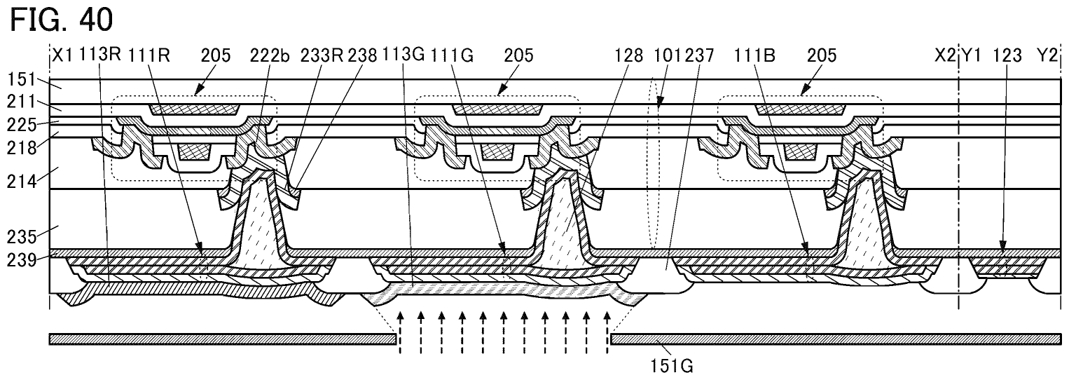

Next, the layer 113G is formed on the surface of the pixel electrode 111G using a fine metal mask 151G (FIG. 40). The end portion of the layer 113G is tapered. The layer 113G may also be formed on the surface of the insulating layer 237.

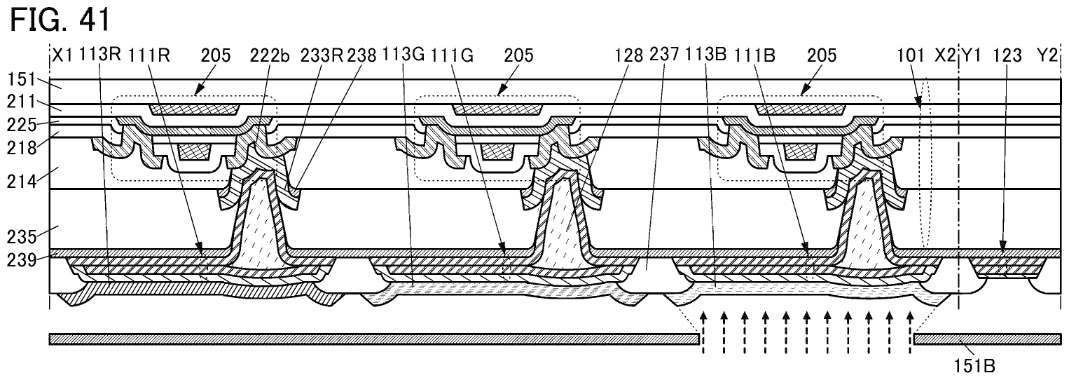

Next, the layer 113B is formed on the surface of the pixel electrode 111B using a fine metal mask 151B (FIG. 41). The end portion of the layer 113B is tapered. The layer 113B may also be formed on the surface of the insulating layer 237.

Preferably, none of the layer 113R, the layer 113G, and the layer 113B are provided over the surface of the conductive layer 123.

Although an example in which the layer 113R, the layer 113G, and the layer 113B are formed in this order is described here, one embodiment of the present invention is not limited thereto. The order of forming the layer 113R, the layer 113G, and the layer 113B is not particularly limited. Although FIG. 41 and the like illustrate an example in which the layer 113R, the layer 113G, and the layer 113B are separated from one another, that is, the adjacent layers 113 are not in contact with each other and are separated from each other, one embodiment of the present invention is not limited thereto. The adjacent layers 113 may be in contact with each other.

For example, over the insulating layer 237, the layer 113R may include a region overlapping with the layer 113G, the layer 113G may include a region overlapping with the layer 113B, and the layer 113R may include a region overlapping with the layer 113B.

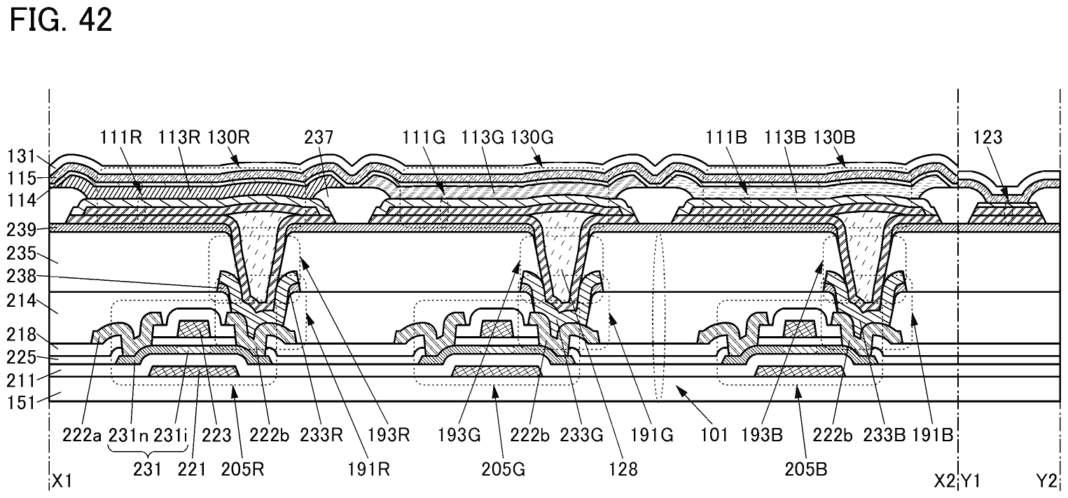

Next, the common layer 114, the common electrode 115, and the protective layer 131 are formed over the insulating layer 127, the layer 113R, the layer 113G, and the layer 113B (FIG. 42). Since the above description can be referred to for formation of the common layer 114, the common electrode 115, and the protective layer 131, the detailed description thereof is omitted.

Next, the substrate 120 is prepared, and the light-blocking layer 117 is formed over the substrate 120. Then, the substrate 120 and the light-blocking layer 117 are bonded to each other with the resin layer 122 over the protective layer 131, whereby the display apparatus can be manufactured (FIG. 18).

By providing the insulating layer 214 and the insulating layer 235 functioning as planarization layers, unevenness of the formation surface of the light-emitting device 130 and the like is reduced. Since a connection defect due to disconnection of the common electrode and an increase in electric resistance due to the locally thinned regions of the common electrode 115 can be prevented, the display apparatus can have high display quality.

This embodiment can be combined with the other embodiments as appropriate.

### Embodiment 3

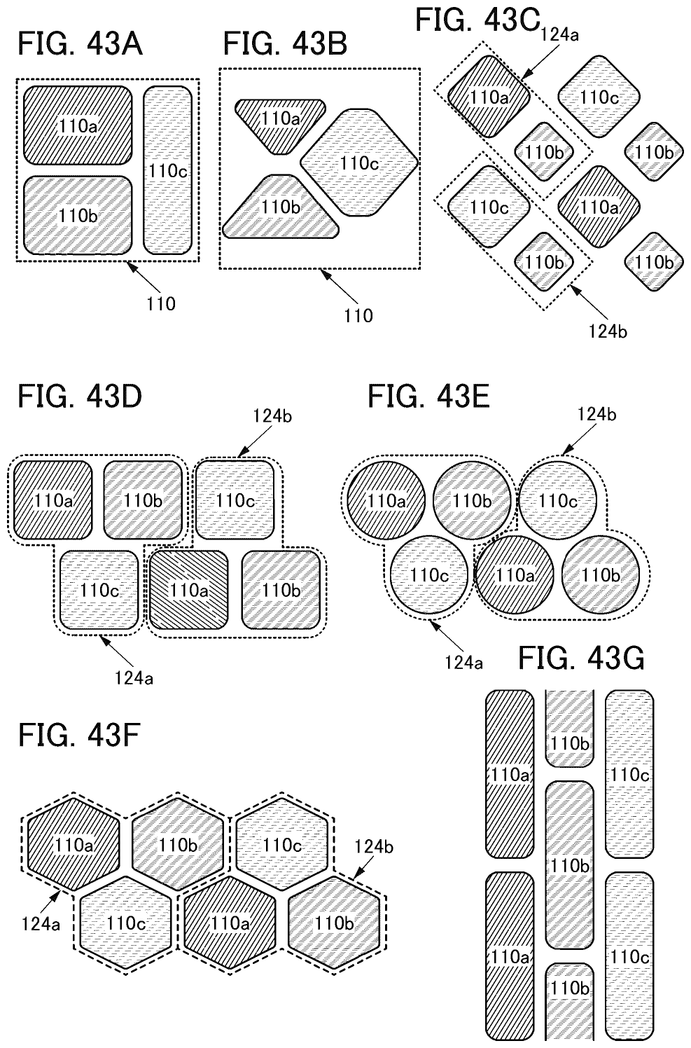

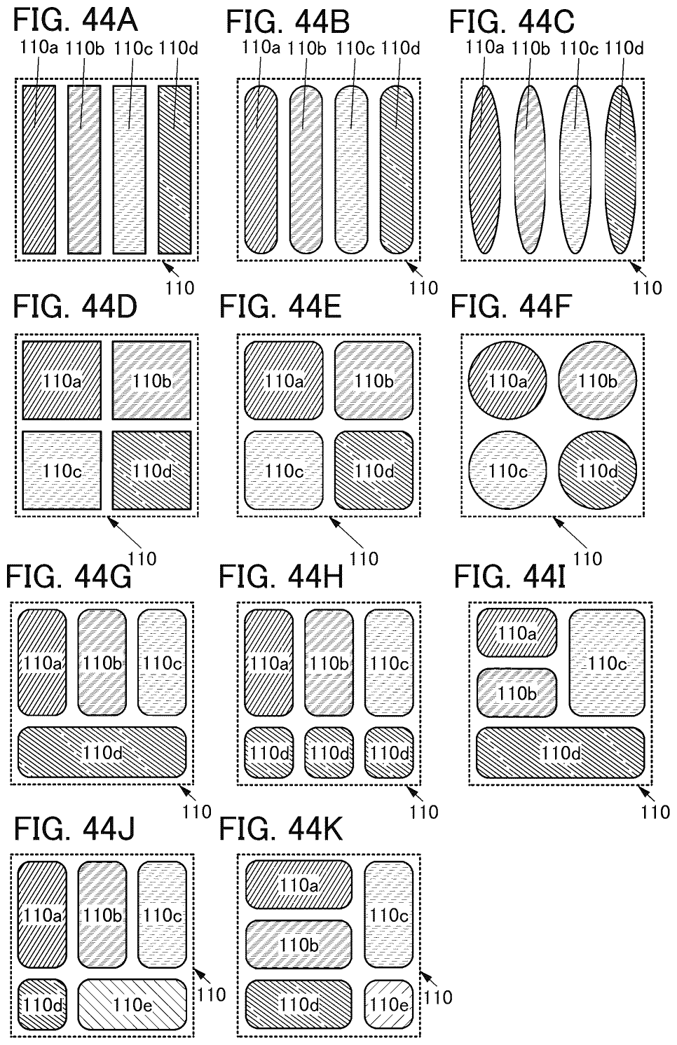

In this embodiment, a display apparatus of one embodiment of the present invention is described with reference to FIG. 43 and FIG. 44.

### [Pixel Layout]

Pixel layouts different from that in FIG. 1 will be mainly described in this embodiment. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region (or a light-receiving region). Note that in this specification and the like, a top surface shape refers to a shape in a plan view, i.e., a shape seen from above.

Examples of a top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and the components in the circuit may be placed outside the range of the subpixels.

The pixel 110 illustrated in FIG. 43A employs S-stripe arrangement. The pixel 110 illustrated in FIG. 43A is composed of three kinds of subpixels: a subpixel 110a, a subpixel 110b, and a subpixel 110c.

The pixel 110 illustrated in FIG. 43B includes the subpixel 110a and the subpixel 110b whose top surfaces have a rough trapezoidal or rough triangle shape with rounded corners and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b illustrated in FIG. 43C employ PenTile arrangement. FIG. 43C illustrates an example in which the pixels 124a including the subpixel 110a and the subpixel 110b and the pixels 124b including the subpixel 110b and the subpixel 110c are alternately arranged.

The pixels 124a and 124b illustrated in FIG. 43D to FIG. 43F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 43D illustrates an example in which each subpixel has a rough tetragonal top surface shape with rounded corners, FIG. 43E illustrates an example in which each subpixel has a circular top surface shape, and FIG. 43F illustrates an example in which each subpixel has a rough hexagonal top surface shape with rounded corners.

In FIG. 43F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, three subpixels 110b and three subpixels 110c are arranged to surround the subpixel 110a, so that the subpixel 110a, the subpixel 110b, and the subpixel 110c are alternately arranged.

FIG. 43G illustrates an example in which subpixels of different colors are arranged in a zigzag manner. Specifically, the positions of the top sides of two subpixels arranged in the row direction (e.g., the subpixel 110a and the subpixel 110b or the subpixel 110b and the subpixel 110c) are not aligned in a top view.

For example, in each pixel illustrated in FIG. 43A to FIG. 43G, it is preferable that the subpixel 110a be a subpixel R emitting red light, the subpixel 110b be a subpixel G emitting green light, and the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, a circular shape, or the like, in some cases.

Furthermore, in the method of manufacturing the display apparatus of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 44A to FIG. 44I, the pixel can include four types of subpixels.

The pixels 110 illustrated in FIG. 44A to FIG. 44C employ stripe arrangement.

FIG. 44A illustrates an example in which each subpixel has a rectangular top surface shape, FIG. 44B illustrates an example in which each subpixel has a top surface shape formed by combining two half circles and a rectangle, and FIG. 44C illustrates an example in which each subpixel has an elliptical top surface shape.

The pixels 110 illustrated in FIG. 44D to FIG. 44F employ matrix arrangement.

FIG. 44D illustrates an example in which each subpixel has a square top surface shape, FIG. 44E illustrates an example in which each subpixel has a rough square top surface shape with rounded corners, and FIG. 44F illustrates an example in which each subpixel has a circular top surface shape.

FIG. 44G and FIG. 44H each illustrate an example in which one pixel 110 is composed of two rows and three columns.

The pixel 110 illustrated in FIG. 44G includes three subpixels (the subpixels 110a, 110b, and 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 44H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 44H enables efficient removal of dust and the like that would be produced in the manufacturing process. Thus, a display apparatus with high display quality can be provided.

FIG. 44I illustrates an example in which one pixel 110 is composed of three rows and two columns.

The pixel 110 illustrated in FIG. 44I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 44A to FIG. 44I are each composed of four subpixels: the subpixels 110a, 110b, 110c, and 110d.

The subpixels 110a, 110b, 110c, and 110d can include light-emitting devices whose emission colors are different. The subpixels 110a, 110b, 110c, and 110d are subpixels of four colors of R, G, B, and white (W), subpixels of four colors of R, G, B, and Y, or subpixels of R, G, B, and infrared light (IR), for example.

In the pixels 110 illustrated in FIG. 44A to FIG. 44I, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 44G and FIG. 44H, leading to higher display quality. In addition, what is called S-stripe arrangement is employed as the layout of R, G, and B in the pixel 110 illustrated in FIG. 44I, leading to higher display quality.

The pixel 110 may include a subpixel including a light-receiving device.

In the pixels 110 illustrated in FIG. 44A to FIG. 44I, any one of the subpixel 110a to the subpixel 110d may be a subpixel including a light-receiving device.

In the pixels 110 illustrated in FIG. 44A to FIG. 44I, for example, it is preferable that the subpixel 110a be the subpixel R emitting red light, the subpixel 110b be the subpixel G emitting green light, the subpixel 110c be the subpixel B emitting blue light, and the subpixel 110d be a subpixel S including a light-receiving device. In the case of such a structure, stripe arrangement is employed as the layout of R, G, and B in the pixels 110 illustrated in FIG. 44G and FIG. 44H, leading to higher display quality. In addition, what is called S-stripe arrangement is employed as the layout of R, G, and B in the pixel 110 illustrated in FIG. 44I, leading to higher display quality.

There is no particular limitation on the wavelength of light detected by the subpixel S including a light-receiving device. The subpixel S can have a structure in which one or both of visible light and infrared light are detected.

As illustrated in FIG. 44J and FIG. 44K, the pixel can include five types of subpixels.

FIG. 44J illustrates an example in which one pixel 110 is composed of two rows and three columns.

The pixel 110 illustrated in FIG. 44J includes three subpixels (the subpixels 110a, 110b, and 110c) in the upper row (first row) and two subpixels (the subpixel 110d and a subpixel 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 44K illustrates an example in which one pixel 110 is composed of three rows and two columns.

The pixel 110 illustrated in FIG. 44K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

In the pixels 110 illustrated in FIG. 44J and FIG. 44K, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIG. 44J, leading to higher display quality. In addition, what is called S-stripe arrangement is employed as the layout of R, G, and B in the pixel 110 illustrated in FIG. 44K, leading to higher display quality.

In the pixels 110 illustrated in FIG. 44J and FIG. 44K, for example, it is preferable to use the subpixel S including a light-receiving device as at least one of the subpixel 110d and the subpixel 110e. In the case where light-receiving devices are used in both the subpixel 110d and the subpixel 110e, the light-receiving devices may have different structures. For example, the wavelength ranges of detected light may be different at least partly. Specifically, one of the subpixel 110d and the subpixel 110e may include a light-receiving device mainly detecting visible light and the other may include a light-receiving device mainly detecting infrared light.

In the pixels 110 illustrated in FIG. 44J and FIG. 44K, it is referable that, for example, the subpixel S including a light-receiving device be used as one of the subpixel 110d and the subpixel 110e and a subpixel including a light-emitting device that can be used as a light source be used as the other. For example, it is preferable that one of the subpixel 110d and the subpixel 110e be the subpixel IR emitting infrared light and the other be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. Also in this case, any of a variety of layouts can be employed.

This embodiment can be combined with any of the other embodiments as appropriate.

### Embodiment 4

In this embodiment, a display apparatus of one embodiment of the present invention will be described.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus of this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Apparatus 100G]

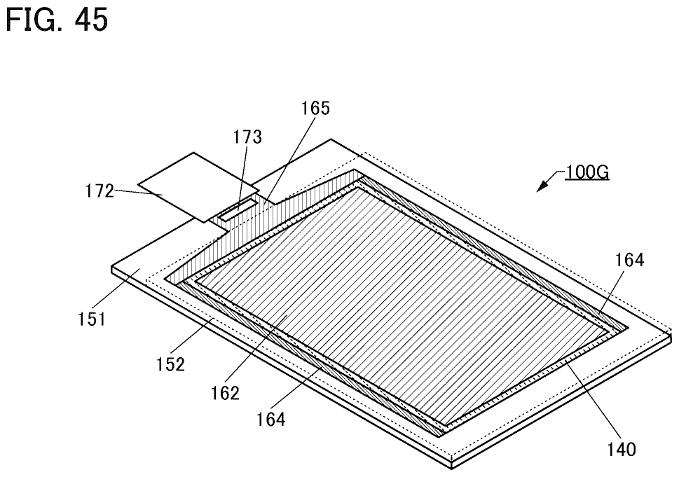

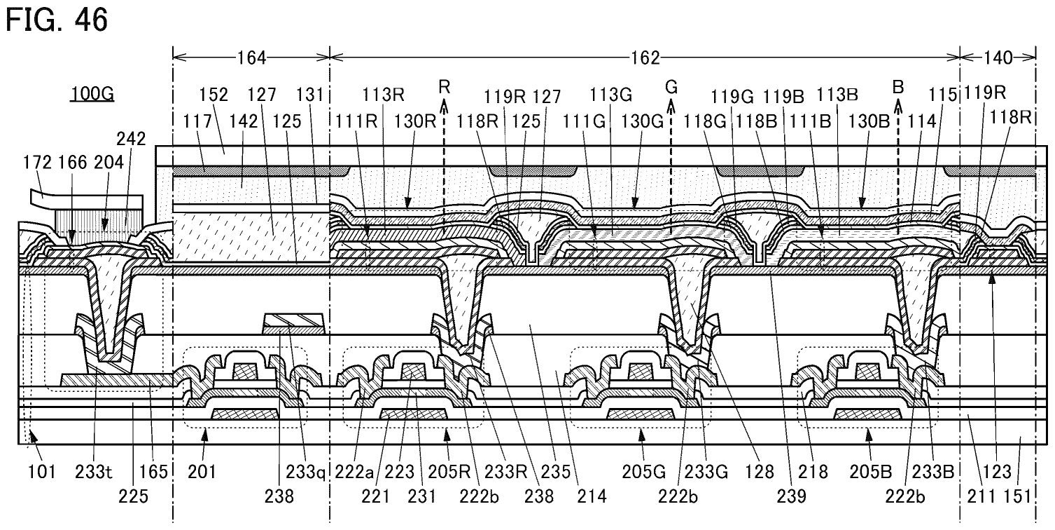

FIG. 45 is a perspective view of a display apparatus 100G, and FIG. 46 is a cross-sectional view of the display apparatus 100G.

In the display apparatus 100G, a substrate 152 and a substrate 151 are bonded to each other. In FIG. 45, the substrate 152 is denoted by a dashed line.

The display apparatus 100G includes a display portion 162, the connection portion 140, a circuit 164, a wiring 165, and the like. FIG. 45 illustrates an example in which an IC 173 and an FPC 172 are mounted on the display apparatus 100G. Thus, the structure illustrated in FIG. 45 can also be regarded as a display module including the display apparatus 100G, the IC (integrated circuit), and the FPC.

The connection portion 140 is provided outside the display portion 162. The connection portion 140 can be provided along one or more sides of the display portion 162. The number of the connection portions 140 can be one or more. FIG. 45 illustrates an example in which the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 45 illustrates an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 46 illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 46 includes a transistor 201, a transistor 205, the light-emitting device 130R, the light-emitting device 130G, the light-emitting device 130B, and the like between the substrate 151 and the substrate 152.

A side surface and part of a top surface of each of the layer 113R, the layer 113G, and the layer 113B are covered with the insulating layer 125 and the insulating layer 127. The mask layer 118R and the mask layer 119R are positioned between the layer 113R and the insulating layer 125. The mask layer 118G and the mask layer 119G are positioned between the layer 113G and the insulating layer 125, and the mask layer 118B and the mask layer 119B are positioned between the layer 113B and the insulating layer 125. The common layer 114 is provided over the layer 113B, the layer 113G, the layer 113R, the insulating layers 125, and the insulating layer 127, and the common electrode 115 is provided over the common layer 114. The common layer 114 and the common electrode 115 are each a continuous film provided to be shared by a plurality of light-emitting devices.

The protective layer 131 is provided over the light-emitting device 130R, the light-emitting device 130G, and the light-emitting device 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting devices. In FIG. 46, a solid sealing structure is employed in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting device. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit 164. It is also preferable that the protective layer 131 be provided to extend to an end portion of the display apparatus 100G. Meanwhile, a connection portion 204 has a portion not provided with the protective layer 131 so that the FPC 172 and a conductive layer 166 are electrically connected to each other.

The connection portion 204 is provided in the substrate 151 in a region that does not overlap with the substrate 152. In the connection portion 204, the wiring 165 is electrically connected to the FPC 172 through a conductive layer 233t, the conductive layer 166, and a connection layer 242. The conductive layer 233t is electrically connected to the wiring 165 through the opening provided in the insulating layer 214. The conductive layer 233t can be formed in the same step as the conductive layer 233R, the conductive layer 233G, and the conductive layer 233B. The conductive layer 166 can be formed in the same step as the pixel electrode 111R, the pixel electrode 111G, and the pixel electrode 111B. The conductive layer 166 is exposed from the top surface of the connection portion 204. Thus, the connection portion 204 and the FPC 172 can be electrically connected to each other through the connection layer 242.

For example, the protective layer 131 is formed over the entire surface of the display apparatus 100G and then a region of the protective layer 131 overlapping with the conductive layer 166 is removed, so that the conductive layer 166 can be exposed.

A stacked-layer structure of at least one organic layer and a conductive layer may be provided over the conductive layer 166, and the protective layer 131 may be provided over the stacked-layer structure. Then, a peeling trigger (a portion that can be a trigger of peeling) may be formed in the stacked-layer structure using a laser or a sharp cutter (e.g., a needle or a utility knife) to selectively remove the stacked-layer structure and the protective layer 131 thereover, so that the conductive layer 166 may be exposed. For example, the protective layer 131 can be selectively removed when an adhesive roller is pressed to the substrate 151 and then moved relatively while being rolled. Alternatively, an adhesive tape may be attached to the substrate 151 and then peeled. Since the adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 113B, the layer 113G, and the layer 113R, for example. The organic layer may be formed concurrently with the layer 113B, the layer 113G, and the layer 113R, or may be provided separately. The conductive layer can be formed using the same step and the same material as those for the common electrode 115. An ITO film is preferably formed as the common electrode 115 and the conductive layer, for example. Note that in the case where a stacked-layer structure is used for the common electrode 115, at least one of the layers included in the common electrode 115 is provided as the conductive layer.

A top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 235 in the connection portion 140. FIG. 46 illustrates an example in which the conductive layer 123 has a stacked-layer structure of a conductive film obtained by processing the same conductive film as the conductive layer 112R, the conductive layer 112G, and the conductive layer 112B; a conductive film obtained by processing the same conductive film as the conductive layer 126R, the conductive layer 126G, and the conductive layer 126B; and a conductive film obtained by processing the same conductive film as the conductive layer 129R, the conductive layer 129G, and the conductive layer 129B. An end portion of the conductive layer 123 is covered with the mask layer 118R, the mask layer 119R, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are in direct contact with each other to be electrically connected to each other.

A wiring 233q is provided over the insulating layer 214. The wiring 233q can be formed in the same step as the conductive layer 233R, the conductive layer 233G, the conductive layer 233B, and the conductive layer 233t. In the display apparatus of one embodiment of the present invention, a wiring can be provided over the insulating layer 214 in addition to a wiring that can be formed in the same step as the conductive layer included in the transistor. Accordingly, the layout flexibility of transistors, capacitors, and wirings in a circuit included in the display apparatus (e.g., a pixel circuit) is increased, so that the area occupied by the circuit can be reduced. In addition, since the layout flexibility of wirings is increased, the parasitic capacitance between the wirings can be reduced.

Although FIG. 46 illustrates the structure in which the insulating layer 238 is provided between the wiring 233q and the insulating layer 214, a structure in which the insulating layer 238 is not provided as illustrated in FIG. 2 and the like may be employed. In the case where the insulating layer 238 is not provided, the wiring 233q is provided in contact with the top surface of the insulating layer 214.

The display apparatus 100G has a top-emission structure. Light emitted by the light-emitting device is emitted toward the substrate 152 side. For the substrate 152, a material having a high visible-light-transmitting property is preferably used. The pixel electrode contains a material reflecting visible light, and the counter electrode (the common electrode 115) contains a material transmitting visible light.

The transistor 201 and the transistor 205 are formed over the substrate 151. These transistors can be fabricated using the same material in the same step. Note that the structures of the transistor 201 and the transistor 205 are not particularly limited.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The semiconductor layer of the transistor preferably includes a metal oxide (also referred to as an oxide semiconductor) showing semiconductor characteristics. That is, a transistor including a metal oxide in its channel formation region (hereinafter, referred to as an OS transistor) is preferably used for the display apparatus of this embodiment.

As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the display apparatus and a reduction in component cost and mounting cost.

An OS transistor has much higher field-effect mobility than a transistor using amorphous silicon. In addition, an OS transistor has an extremely low leakage current between a source and a drain in an off state (hereinafter also referred to as off-state current), and electric charge accumulated in a capacitor that is connected in series to the transistor can be retained for a long period. Furthermore, the power consumption of the display apparatus can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be fed through the OS transistor than through a Si transistor. Thus, by using an OS transistor as the driving transistor, a stable current can be fed through the light-emitting device even when the current-voltage characteristics of the EL device vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black floating”, “increase in emission luminance”, “increase in the number of gray levels”, “inhibition of variation in light-emitting devices”, and the like.

A metal oxide used for the semiconductor layer preferably contains indium, the element M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, In:M:Zn=5:2:5 or a composition in the neighborhood thereof, In:M:Zn=10:1:3 or a composition in the neighborhood thereof, In:M:Zn=10:1:6 or a composition in the neighborhood thereof, a composition in the neighborhood thereof, and In:M:Zn=10:1:8 or a composition in the neighborhood thereof. Note that a composition in the neighborhood includes the range of ±30% of an intended atomic ratio. Note that in the case where two or more kinds of elements are contained as the element M, the proportion of the element M in the above atomic ratio can be calculated from the sum of the numbers of atoms of the two or more kinds of metal elements.

For example, in the case where the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, in the case where the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, in the case where the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. A structure in which an LTPS transistor and an OS transistor are used in combination is referred to as LTPO in some cases. For a more suitable example, it is preferable that the OS transistor be used as a transistor or the like functioning as a switch for controlling conduction or non-conduction between wirings, and the LTPS transistor be used as a transistor or the like for controlling current.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. This structure can significantly reduce the leakage current that might flow through a transistor, and the leakage current that might flow between adjacent light-emitting devices (also referred to as a lateral leakage current or a side leakage current). With the structure, a viewer can observe any one or more of image crispness, image sharpness, a high chroma, and a high contrast ratio in an image displayed on the display apparatus. Note that when the leakage current that might flow through a transistor and the lateral leakage current between light-emitting devices are extremely low, light leakage or the like (what is called black blurring) that might occur in black display can be reduced as much as possible.

In particular, in the case where a light-emitting device having the MML structure employs the above-described SBS structure, a layer provided between light-emitting devices (for example, an organic layer shared by the light-emitting devices, also referred to as a common layer) is disconnected; accordingly, lateral leakage can be eliminated or reduced as much as possible.

The light-blocking layer 117 is preferably provided on the surface of the substrate 152 that faces the substrate 151. The light-blocking layer 117 can be provided between adjacent light-emitting devices, in the connection portion 140, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Apparatus 100H]

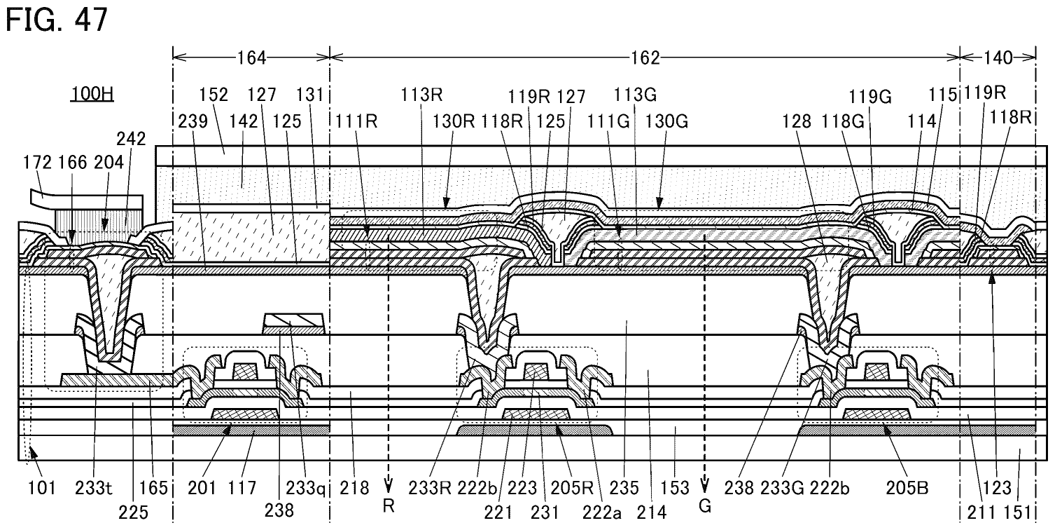

A display apparatus 100H illustrated in FIG. 47 is different from the display apparatus 100G mainly in being a bottom-emission display apparatus.

Light emitted by the light-emitting device is emitted toward the substrate 151 side. For the substrate 151, a material having a high visible-light-transmitting property is preferably used. In contrast, there is no limitation on the light-transmitting property of a material used for the substrate 152.

The light-blocking layer 117 is preferably formed between the substrate 151 and the transistor 201 and between the substrate 151 and the transistor 205. FIG. 47 illustrates an example in which the light-blocking layer 117 is provided over the substrate 151, an insulating layer 153 is provided over the light-blocking layer 117, and the transistors 201 and 205 and the like are provided over the insulating layer 153.

The light-emitting device 130R includes the conductive layer 112R, the conductive layer 126R over the conductive layer 112R, and the conductive layer 129R over the conductive layer 126R.

The light-emitting device 130G includes the conductive layer 112G, the conductive layer 126G over the conductive layer 112G, and the conductive layer 129G over the conductive layer 126G.

A material having a high visible-light-transmitting property is used for each of the conductive layers 112R, 112G, 126R, 126G, 129R, and 129G. A material reflecting visible light is preferably used for the common electrode 115.

### [Display Apparatus 100J]

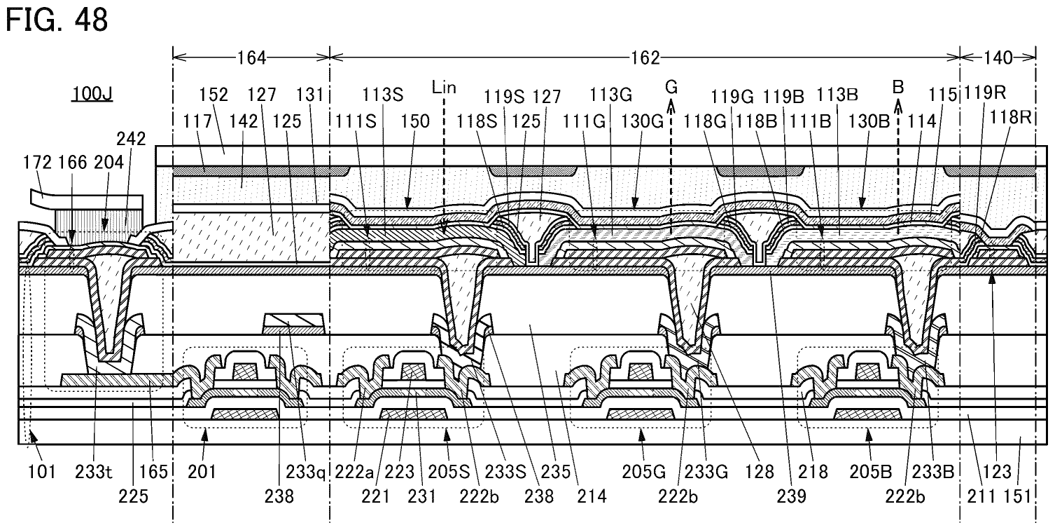

A display apparatus 100J illustrated in FIG. 48 is different from the display apparatus 100G mainly in including the light-receiving device 150.

The light-receiving device 150 includes the pixel electrode 111S, the layer 113S, the common layer 114, and the common electrode 115. The layer 113S includes at least an active layer. The pixel electrode 111S can be formed through the same process as the pixel electrode 111R, the pixel electrode 111G, and the pixel electrode 111B.

The pixel electrode 111S is connected to the conductive layer 222b included in the transistor 205S through the conductive layer 233S.

A top surface and a side surface of the pixel electrode 111S are covered with the layer 113S.

A side surface and part of a top surface of the layer 113S are covered with the insulating layer 125 and the insulating layer 127. The mask layer 118S and the mask layer 119S are positioned between the layer 113S and the insulating layer 125. The common layer 114 is provided over the layer 113S and the insulating layer 125 and the insulating layer 127, and the common electrode 115 is provided over the common layer 114. The common layer 114 is a continuous film provided to be shared by the light-receiving device and the light-emitting devices.

The display apparatus 100J can employ any of the pixel layouts that are described in Embodiment 3 with reference to FIG. 44A to FIG. 44K, for example. Embodiment 1 and Embodiment 6 can be referred to for the details of the display apparatus including the light-receiving device.

This embodiment can be combined with any of the other embodiments as appropriate.

### Embodiment 5

In this embodiment, a light-emitting device that can be used in the display apparatus of one embodiment of the present invention is described.

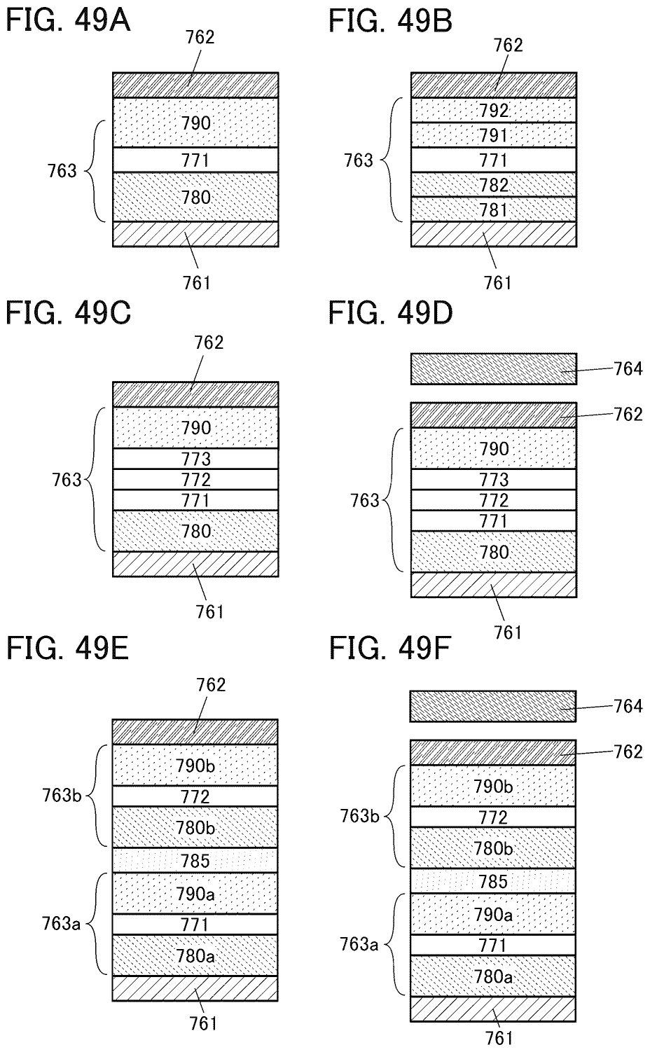

As illustrated in FIG. 49A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a material having a high hole-injection property (hole-injection layer), a layer including a material having a high hole-transport property (hole-transport layer), and a layer including a material having a high electron-blocking property (electron-blocking layer). Furthermore, the layer 790 includes one or more of a layer including a material having a high electron-injection property (electron-injection layer), a layer including a material having a high electron-transport property (electron-transport layer), and a layer including a material having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 49A is referred to as a single structure in this specification.

FIG. 49B is a modification example of the EL layer 763 included in the light-emitting device illustrated in FIG. 49A. Specifically, the light-emitting device illustrated in FIG. 49B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771, 772, and 773) are provided between the layers 780 and 790 as illustrated in FIG. 49C and FIG. 49D are other variations of the single structure. Although FIG. 49C and FIG. 49D each illustrate an example in which three light-emitting layers are included, the number of light-emitting layers in a light-emitting device having a single structure may be two or four or more. A light-emitting device having a single structure may include a buffer layer between two light-emitting layers.

A structure in which a plurality of light-emitting units (light-emitting units 763a and 763b) are connected in series with a charge-generation layer (also referred to as an intermediate layer) 785 therebetween as illustrated in FIG. 49E and FIG. 49F is referred to as a tandem structure in this specification. The tandem structure may be referred to as a stack structure. The tandem structure enables a light-emitting device capable of high-luminance light emission. Furthermore, the tandem structure allows the amount of current needed for obtaining the same luminance to be reduced as compared with the case of using a single structure, and thus can improve the reliability.

Note that FIG. 49D and FIG. 49F each illustrate an example in which the display apparatus includes a layer 764 overlapping with the light-emitting device. FIG. 49D illustrates an example in which the layer 764 overlaps with the light-emitting device illustrated in FIG. 49C and FIG. 49F illustrates an example in which the layer 764 overlaps with the light-emitting device illustrated in FIG. 49E. In FIG. 49D and FIG. 49F, a conductive film that transmits visible light is used for the upper electrode 762 so that light is extracted through the upper electrode 762.

One or both of a color conversion layer and a color filter (coloring layer) can be used as the layer 764.

In FIG. 49C and FIG. 49D, light-emitting materials that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 49D for converting blue light emitted from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 49C and FIG. 49D, light-emitting substances that emit light of different colors may be used for the light-emitting layer 771, the light-emitting layer 772, and the light-emitting layer 773. White light emission can be obtained by mixing of light emitted from the light-emitting layer 771, the light-emitting layer 772, and the light-emitting layer 773. The light-emitting device having a single structure preferably includes a light-emitting layer including a light-emitting substance emitting blue light and a light-emitting layer including a light-emitting substance emitting visible light with a longer wavelength than blue light, for example.

A color filter may be provided as the layer 764 illustrated in FIG. 49D. When white light passes through a color filter, light of a desired color can be obtained.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance emitting blue (B) light and a light-emitting layer including a light-emitting substance emitting yellow (Y) light are preferably included. Such a structure may be referred to as a BY single structure.

In the light-emitting device that emits white light, two or more kinds of light-emitting substances are preferably included. To obtain white light emission, the two or more kinds of light-emitting substances are selected so as to emit light of complementary colors. For example, when emission colors of a first light-emitting layer and a second light-emitting layer are complementary colors, the light-emitting device can emit white light as a whole. In the case of a structure containing three or more kinds of light-emitting substances, white light emission can be obtained by mixing light emitted from the light-emitting layers.

In FIG. 49C and FIG. 49D, the layer 780 and the layer 790 may each have a stacked-layer structure of two or more layers as illustrated in FIG. 49B.

In FIG. 49E and FIG. 49F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In the subpixel that emits blue light, blue light emitted from the light-emitting device can be extracted. In each of the subpixel that emits red light and the subpixel that emits green light, a color conversion layer is provided as the layer 764 illustrated in FIG. 49F for converting blue light emitted from the light-emitting device into light with a longer wavelength, so that red light or green light can be extracted. As the layer 764, both a color conversion layer and a coloring layer are preferably used.

In the case where light-emitting devices with the structure illustrated in FIG. 49E or FIG. 49F are used in subpixels emitting light of different colors, light-emitting substances may be different between the subpixels. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light may be used for each of the light-emitting layer 771 and the light-emitting layer 772. In the light-emitting device included in the subpixel emitting blue light, a light-emitting substance that emits blue light may be used for each of the light-emitting layer 771 and the light-emitting layer 772. A display apparatus with such a structure includes a light-emitting device with a tandem structure and can be regarded to have an SBS structure. Thus, the display apparatus can have advantages of both of a tandem structure and an SBS structure. Accordingly, a highly reliable light-emitting device capable of high-luminance light emission can be obtained.

In FIG. 49E and FIG. 49F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 49F. When white light passes through a color filter, light of a desired color can be obtained.

Although FIG. 49E and FIG. 49F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 49E and FIG. 49F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively.

In each of FIG. 49E and FIG. 49F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

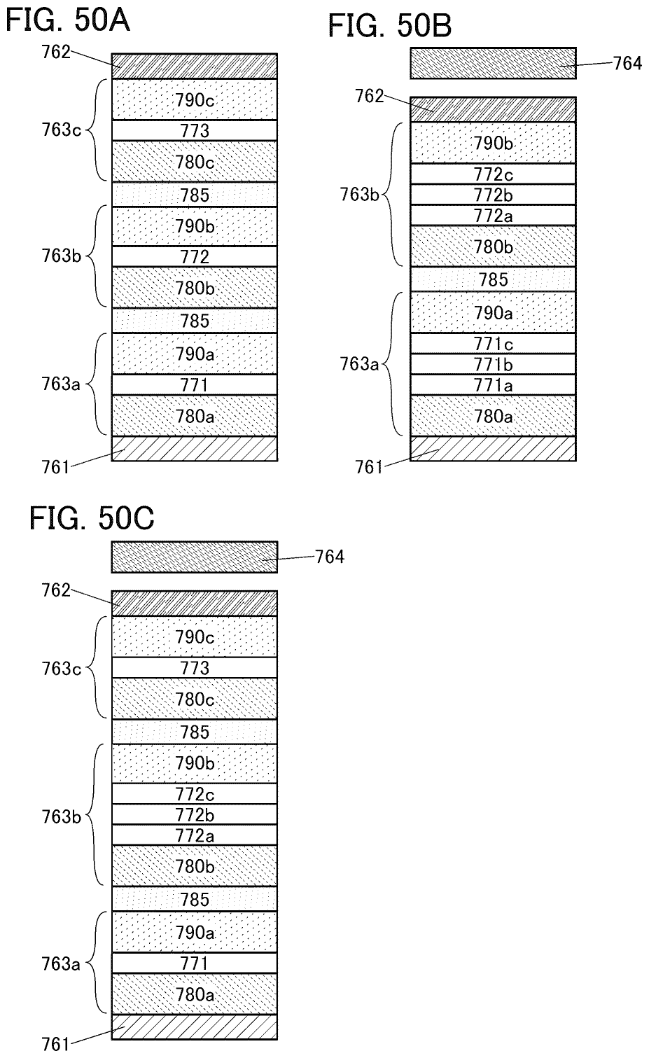

Examples of the light-emitting device with a tandem structure are structures illustrated in FIG. 50A to FIG. 50C.

FIG. 50A illustrates a structure including three light-emitting units. In the structure illustrated in FIG. 50A, a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 50A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (i.e., an R\R\R three-unit tandem structure), can each include a light-emitting substance that emits green (G) light (i.e., a G\G\G three-unit tandem structure), or can each include a light-emitting substance that emits blue (B) light (i.e., a B\B\B three-unit tandem structure). Note that “a\b” means that a light-emitting unit including a light-emitting substance that emits light of a color “b” is provided over a light-emitting unit including a light-emitting substance that emits light of a color “a” with a charge-generation layer therebetween, and “a” and “b” each mean a color.

In FIG. 50A, light-emitting substances that emit light of different colors may be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

Note that the light-emitting substances that emit light of the same color is not limited to the above structure. For example, a light-emitting device with a tandem structure may be employed in which light-emitting units each including a plurality of light-emitting layers are stacked as illustrated in FIG. 50B. FIG. 50B illustrates a structure in which two light-emitting units (light-emitting unit 763a and light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 50B, by selecting light-emitting substances for the light-emitting layer 771a, the light-emitting layer 771b, and the light-emitting layer 771c such that white light emission is obtained when light from the light-emitting layers is mixed, the light-emitting unit 763a enables white (W) light emission. Furthermore, by selecting light-emitting substances for the light-emitting layer 772a, the light-emitting layer 772b, and the light-emitting layer 772c such that white light emission is obtained when light from the light-emitting layers is mixed, the light-emitting unit 763b enables white (W) light emission. That is, the structure illustrated in FIG. 50B is a two-unit tandem structure of WWW. Note that there is no particular limitation on the stacking order of light-emitting substances, and a practitioner can select an optimum stacking order as appropriate. Although not illustrated, a three-unit tandem structure of W\W\W or a tandem structure with four or more units may be employed.

In the case of a light-emitting device with a tandem structure, any of the following structure may be employed, for example: a two-unit tandem structure of BY or YB including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a color “a” and a light-emitting substance that emits light of a color “b”.

Alternatively, a light-emitting unit including one light-emitting layer and a light-emitting unit including a plurality of light-emitting layers may be used in combination as illustrated in FIG. 50C.

Specifically, in the structure illustrated in FIG. 50C, a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 50C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display apparatus includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display apparatus.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a material having a high hole-injection property, a material having a high hole-transport property, a hole-blocking material, a material having a high electron-transport property, an electron-blocking material, a material having a high electron-injection property, a material having a bipolar property (a material with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a material with a high hole-transport property (a hole-transport material) and a material with a high electron-transport property (an electron-transport material) can be used. As the hole-transport material, it is possible to use any of after-mentioned materials each having a high hole-transport property that can be used for the hole-transport layer. As the electron-transport material, it is possible to use any of after-mentioned materials each having a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and includes a material having a high hole-injection property. Examples of a material having a high hole-injection property include an aromatic amine compound and a composite material including a hole-transport material and an acceptor material (electron-accepting material).

As the hole-transport material, any of after-mentioned materials each having a high hole-transport property that can be used for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material preferably has a hole mobility higher than or equal to 1× 10⁻⁶ cm²/Vs. Note that other materials can also be used as long as the materials have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material preferably has an electron mobility higher than or equal to 1×10⁻⁶ cm²/Vs. Note that other materials can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a T-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and includes a material having a high electron-injection property. As the material having a high electron-injection property, an alkali metal, an alkaline earth metal, or a compound thereof can be used. As the material having a high electron-injection property, a composite material including an electron-transport material and a donor material (electron-donating material) can also be used.

The LUMO level of the material having a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di (naphthalen-2-yl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a material having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper (II) phthalocyanine (abbreviation: CuPc), or a metal complex having a metal-oxygen bond and an aromatic ligand is preferably used.

Note that the charge-generation region, the electron-injection buffer layer, and the electron-relay layer cannot be clearly distinguished from one another on the basis of the cross-sectional shape or properties in some cases.

The charge-generation layer may contain a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

This embodiment can be combined with any of the other embodiments as appropriate.

### Embodiment 6

In this embodiment, a light-receiving device that can be used for the display apparatus of one embodiment of the present invention and a display apparatus having a light-emitting and light-receiving function will be described.

### [Light-Receiving Device]

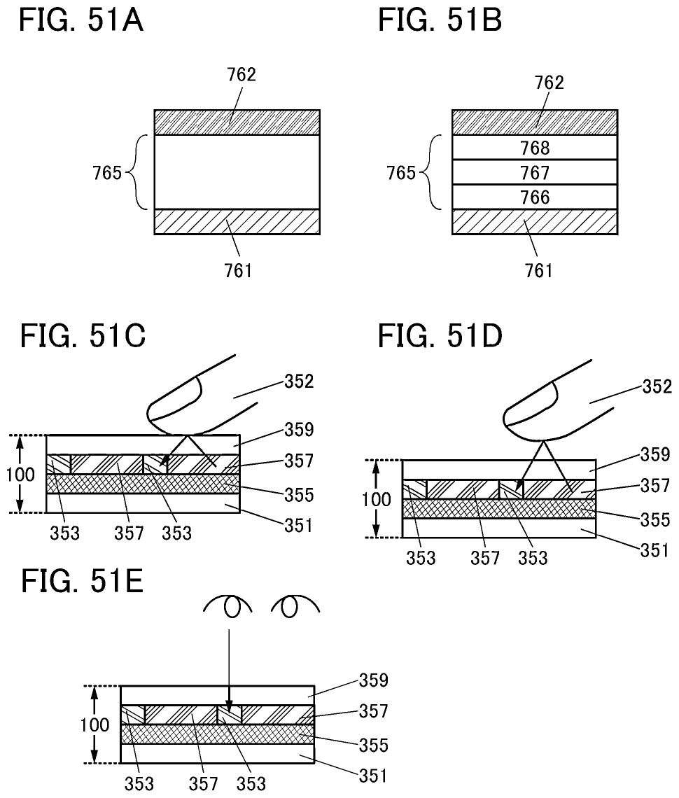

As illustrated in FIG. 51A, the light-receiving device includes a layer 765 between a pair of electrodes (the lower electrode 761 and the upper electrode 762). The layer 765 includes at least one active layer, and may further include another layer.

FIG. 51B is a variation example of the layer 765 included in the light-receiving device illustrated in FIG. 51A. Specifically, the light-receiving device illustrated in FIG. 51B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layers 766 and 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed by a method such as an evaporation method (including a vacuum evaporation method), a transfer method, a printing method, an inkjet method, or a coating method.

The active layer included in the light-receiving device includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-Phenyl-C71-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C₆₀ (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

Three or more kinds of materials may be used for the active layer. For example, a third material may be mixed with an n-type semiconductor material and a p-type semiconductor material in order to extend the wavelength range. The third material may be a low molecular compound or a high molecular compound.

In addition to the active layer, the light-receiving device may further include a layer containing a material with a high hole-transport property, a material with a high electron-transport property, a material with a bipolar property (a material with a high electron-transport property and a high hole-transport property), or the like. Without limitation to the above, the light-receiving device may further include a layer containing a material with a high hole-injection property, a hole-blocking material, a material with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/polystyrenesulfonic acid (abbreviation: PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, a biometric authentication device, a capacitive touch panel for scroll operation, or the like is not necessarily provided separately from the electronic device. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

In the display apparatus including light-emitting devices and a light-receiving device in each pixel, the pixel has a light-receiving function; thus, the display apparatus can detect a contact or approach of an object while displaying an image. For example, all the subpixels included in the display apparatus can display an image; alternatively, some of the subpixels can emit light as a light source, and the other subpixels can display an image.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without direct contact of an object. In other words, the display apparatus can be operated in a contactless (touchless) manner. With the above structure, the display apparatus can have a reduced risk of being dirty or damaged, or can be operated without the object directly touching a dirt (e.g., dust or a virus) attached to the display apparatus.

The refresh rate can be variable in the display apparatus of one embodiment of the present invention. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display apparatus 100 illustrated in FIG. 51C to FIG. 51E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed.

For example, after light emitted by the light-emitting device in the layer 357 including the light-emitting device is reflected by a finger 352 in contact with the display apparatus 100 as illustrated in FIG. 51C, the light-receiving device in the layer 353 including the light-receiving device detects the reflected light. Thus, the contact of the finger 352 with the display apparatus 100 can be detected.

The display apparatus may have a function of detecting an object that is approaching (not in contact with) the display apparatus as illustrated in FIG. 51D and FIG. 51E or capturing an image of such an object. FIG. 51D illustrates an example in which a human finger is detected, and FIG. 51E illustrates an example in which information on the periphery, surface, or inside of the human eye (e.g., the number of blinks, movement of an eyeball, and movement of an eyelid) is detected.

This embodiment can be combined with any of the other embodiments as appropriate.

### Embodiment 7

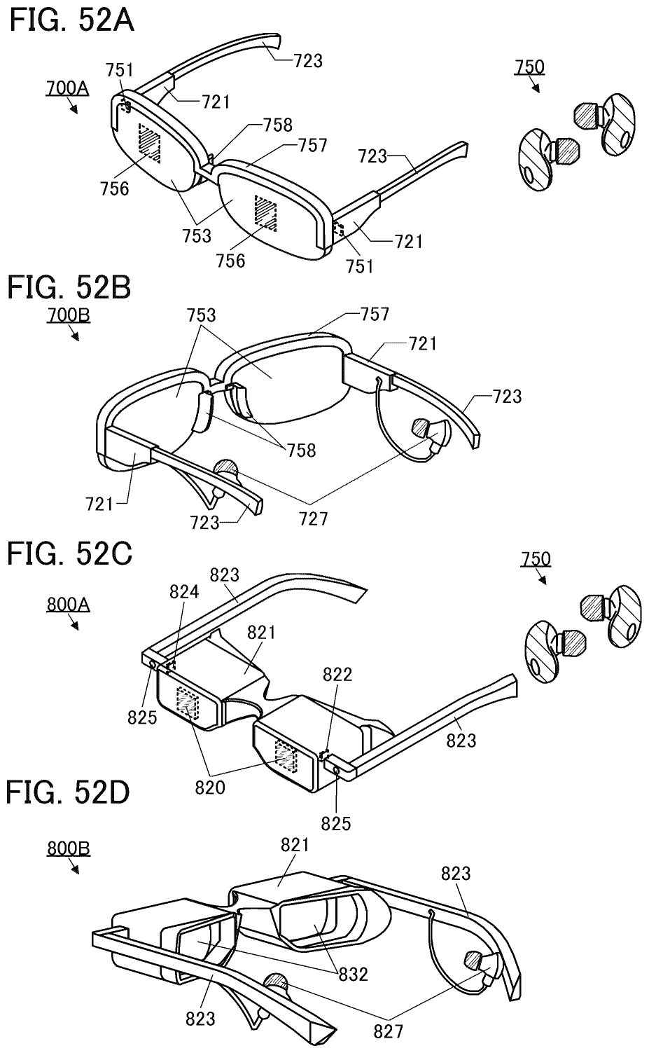

In this embodiment, electronic devices of one embodiment of the present invention will be described with reference to FIG. 52 to FIG. 54.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display apparatus having one or both of such high definition and high resolution can further increase realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 52A to FIG. 52D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 52A and an electronic device 700B illustrated in FIG. 52B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (photoelectric conversion element) can be used as a light-receiving device. One or both of an inorganic semiconductor and an organic semiconductor can be used for an active layer of the photoelectric conversion device.

An electronic device 800A illustrated in FIG. 52C and an electronic device 800B illustrated in FIG. 52D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 52C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 52A has a function of transmitting information to the earphones 750 with the wireless communication function. As another example, the electronic device 800A in FIG. 52C has a function of transmitting information to the earphones 750 with the wireless communication function.

The electronic device may include an earphone portion. The electronic device 700B illustrated in FIG. 52B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 52D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

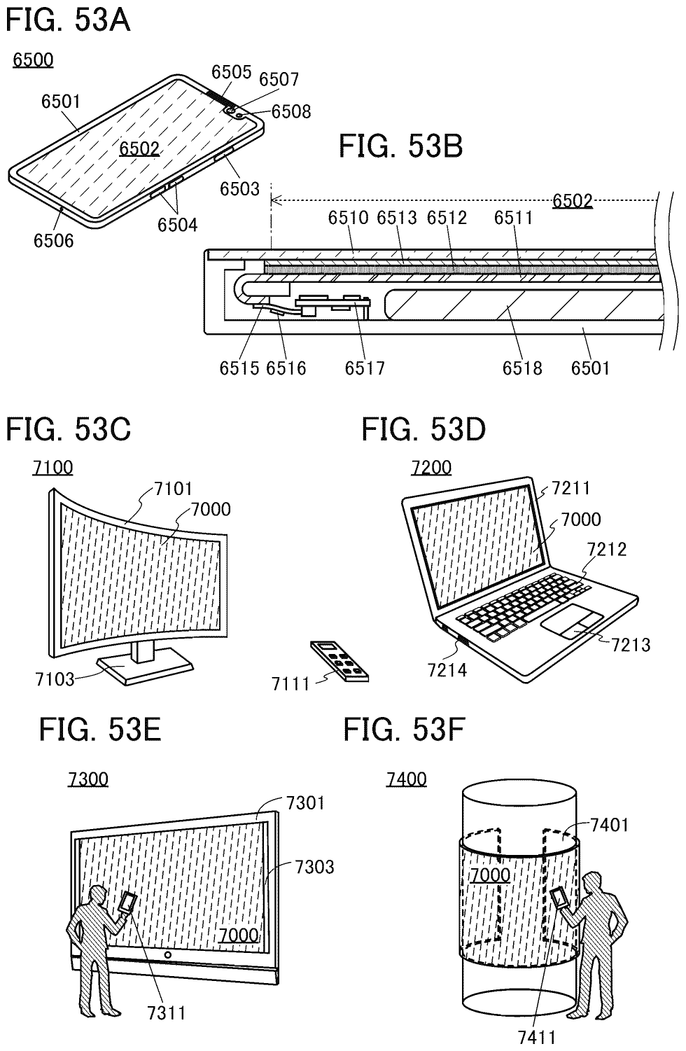

An electronic device 6500 illustrated in FIG. 53A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 53B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is provided on the back side of the pixel portion, whereby an electronic device with a narrow bezel can be obtained.

FIG. 53C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 53C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 53D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 53E and FIG. 53F illustrate examples of digital signage.

Digital signage 7300 illustrated in FIG. 53E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 53F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 53E and FIG. 53F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 53E and FIG. 53F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

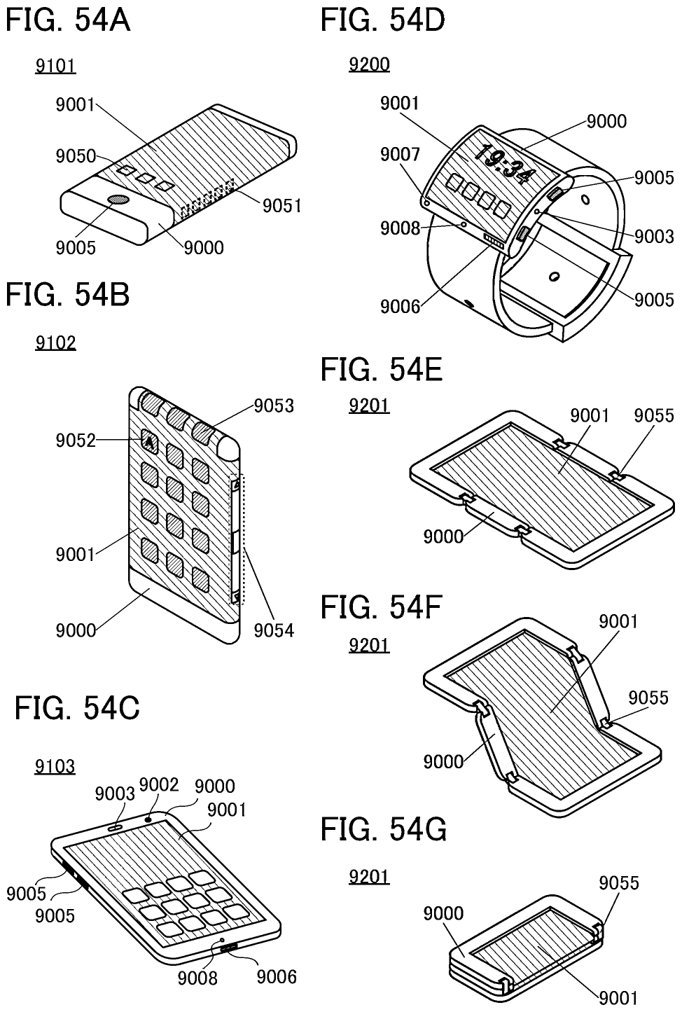

Electronic devices illustrated in FIG. 54A to FIG. 54G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 54A to FIG. 54G have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 54A to FIG. 54G are described in detail below.

FIG. 54A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 54A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 54B is a perspective view illustrating a portable information terminal 9102. The portable information terminal 9102 has a function of displaying information on three or more surfaces of the display portion 9001. Shown here is an example where information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 54C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 54D is a perspective view illustrating a watch-type portable information terminal 9200. For example, the portable information terminal 9200 can be used for a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 54E to FIG. 54G are perspective views illustrating a foldable portable information terminal 9201. FIG. 54E is a perspective view of an opened state of the portable information terminal 9201, FIG. 54G is a perspective view of a folded state thereof, and FIG. 54F is a perspective view of a state in the middle of change from one of FIG. 54E and FIG. 54G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example 1

In this example, transistors were fabricated and changes in electrical characteristics by an NBTIS test were evaluated, and deterioration factors in the NBTIS test were analyzed.

For the structure of the samples used in this example, the description of the transistor 205R illustrated in FIG. 11B can be referred to. Here, two kinds of samples (Sample A and Sample B) were fabricated with different substrate temperatures in formation of the insulating layer 225 functioning as the first gate insulating layer.

### <Fabrication of Samples>

First, an approximately 100-nm-thick tungsten film was formed over the substrate 151 by a sputtering method and processed to obtain the conductive layer 221 functioning as a second gate electrode (a bottom gate electrode). A glass substrate was used as the substrate 151.

Next, the insulating layer 211 functioning as a second gate insulating layer was formed by a plasma CVD method. The insulating layer 211 had a structure in which an approximately 290-nm-thick first silicon nitride film, an approximately 60-nm-thick silicon nitride film, and an approximately 3-nm-thick silicon oxynitride film were stacked in this order.

Next, the surface of the second gate insulating layer was removed with use of 0.5% hydrofluoric acid. The treatment with the hydrofluoric acid was performed for 60 seconds.

Next, an approximately 25-nm-thick first metal oxide film was formed and processed to obtain the semiconductor layer 231. The first metal oxide film was formed by a sputtering method using an In—Ga—Zn oxide target (In:Ga:Zn=1:1:1 [atomic ratio]).

Next, heat treatment was performed at 350° C. in a dry air atmosphere for two hours. An oven apparatus was used for the heat treatment.

Next, as the insulating layer 225 functioning as the first gate insulating layer, an approximately 100-nm-thick silicon oxynitride film was formed by a plasma CVD method. Here, the substrate temperature in formation of the insulating layer 225 was different between the samples. The substrate temperature in formation of the insulating layer 225 for Sample A was 300° C., and that for Sample B was 400° C.

Next, heat treatment was performed at 350° C. in a dry air atmosphere for one hour. An oven apparatus was used for the heat treatment.

Next, a 20-nm-thick second metal oxide film was formed over the insulating layer 225. The second metal oxide film was formed by a sputtering method using an In—Ga—Zn oxide target (In:Ga:Zn=1:1:1 [atomic ratio]).

Next, heat treatment was performed at 350° C. in a dry air atmosphere for one hour. An oven apparatus was used for the heat treatment.

Then, part of the insulating layer 211, part of the insulating layer 225, and part of the second metal oxide film were etched to form an opening reaching the conductive layer 221.

Next, an approximately 50-nm-thick molybdenum film, an approximately 200-nm-thick aluminum film, and an approximately 50-nm-thick titanium film were formed in this order by a sputtering method to cover the opening. Then, the second metal oxide film, the molybdenum film, the aluminum film, and the titanium film were processed to obtain the conductive layer 223 functioning as a first gate electrode (a top gate electrode).

Next, boron was added as an impurity element with use of the conductive layer 223 as a mask. A plasma ion doping method was used for the addition treatment. A B₂H₆ gas was used as a gas for supplying boron. By the addition treatment, the low-resistance region 231n was formed in a region of the semiconductor layer 231 which does not overlap with the conductive layer 223.

Next, as the insulating layer 218, an approximately 300-nm-thick silicon nitride oxide film was formed by a plasma CVD method.

Then, part of the insulating layer 218 and part of the insulating layer 225 were removed by etching to form an opening reaching the low-resistance region 231n.

Then, an approximately 50-nm-thick titanium film, an approximately 300-nm-thick aluminum film, and an approximately 50-nm-thick titanium film were formed in this order by a sputtering method to cover the opening. After that, the conductive films were processed to obtain the conductive layer 222a and the conductive layer 222b functioning as a source and a drain. Through the above process, the samples were obtained.

### <NBTIS Test 1>

Next, an NBTIS test was performed on the samples fabricated in the above manner. In the NBTIS test, transistors with a channel length of 6 μm and a channel width of 50 μm were used.

First, the Id-Vg characteristics of the transistors were measured. For the Id-Vg measurement, a voltage applied to the gate electrode (hereinafter also referred to as a gate voltage (Vg)) was applied from −15 V to +2 V in increments of 0.1 V. Moreover, a voltage applied to the source (hereinafter also referred to as a source voltage (Vs)) was 0 V (comm), and a voltage applied to the drain (hereinafter also referred to as a drain voltage (Vd)) was 10 V. Note that the upper limit in the measurement of the drain current (Id) was set to 1×10⁻³ A.

Here, the Id-Vg characteristics in the case of application of the same gate voltage to the second gate electrode and the first gate electrode were measured.

Next, stress was applied to the transistors. Specifically, a substrate over which the transistors were formed was held at 70° C., a voltage of 0 V was applied to the source and the drain of the transistors and a voltage of −20 V was applied to the gate in a state where irradiation with white LED light at 5000 lx was performed; this state was held for two hours. The irradiation with white LED light was performed from the glass substrate side.

Then, Id-Vg characteristics were measured. For the Id-Vg characteristics measurement, the above description can be referred to, and thus detailed description is omitted.

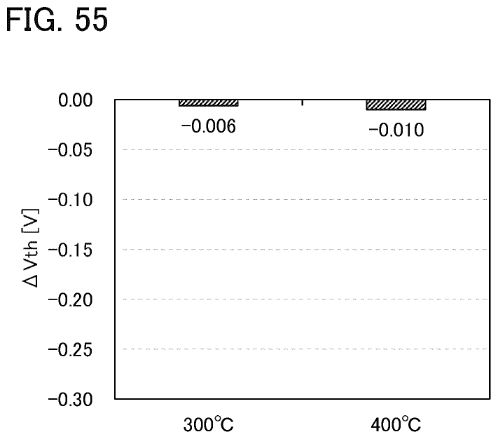

FIG. 55 shows the amount of change in threshold voltage of the transistors in the NBTIS test. In FIG. 55, the horizontal axis represents the substrate temperature at the time of depositing the insulating layer 225, and the vertical axis represents the amount of change in threshold voltage (ΔVth). The amount of change in threshold voltage (ΔVth) indicates a difference between the threshold voltage after stress application and the threshold voltage before the NBTIS test. In FIG. 55, there is no significant difference in the amount of change in threshold voltage between the samples.

### <NBTIS Test 2>

Changes in electrical characteristics were evaluated under the conditions where the temperature and the illuminance were higher than those in the aforementioned NBTIS test.

First, the Id-Vg characteristics of the transistors were measured. For the Id-Vg characteristics measurement, the above description can be referred to, and thus detailed description is omitted.

Next, stress was applied to the transistors. Specifically, a substrate over which the transistors were formed was held at 150° C., a voltage of 0 V was applied to the source and the drain of the transistors and a voltage of −20 V was applied to the gate in a state where irradiation with white LED light at 20000 lx was performed. The irradiation with white LED light was performed from the glass substrate side.

Then, Id-Vg characteristics were measured. For the Id-Vg characteristics measurement, the above description can be referred to, and thus detailed description is omitted.

The above-described stress application and Id-Vg characteristics measurement were repeated until the amount of change in threshold voltage was almost saturated.

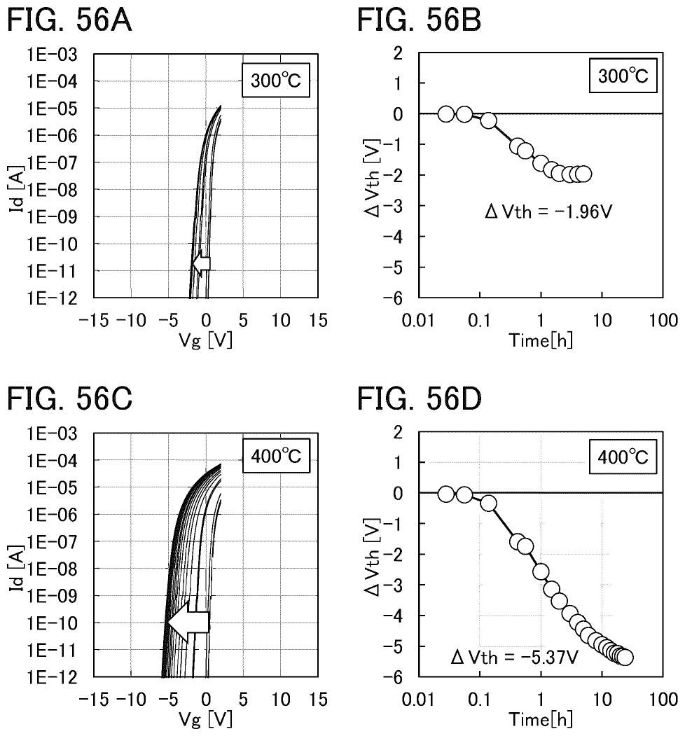

FIG. 56A shows the Id-Vg characteristics of Sample A. In FIG. 56A, the horizontal axis represents a gate voltage (Vg) and the vertical axis represents a drain current (Id). FIG. 56A shows superimposed Id-Vg characteristics that were repeatedly measured. FIG. 56B shows the amount of change in threshold voltage of the transistor in the NBTIS test of Sample A. In FIG. 56B, the horizontal axis represents accumulated time (Time) of stress application and the vertical axis represents the amount of change in threshold voltage (ΔVth).

FIG. 56C shows the Id-Vg characteristics of Sample B. In FIG. 56C, the horizontal axis represents a gate voltage (Vg) and the vertical axis represents a drain current (Id). FIG. 56C shows superimposed Id-Vg characteristics that were repeatedly measured. FIG. 56D shows the amount of change in threshold voltage of the transistor in the NBTIS test of Sample B. In FIG. 56D, the horizontal axis represents accumulated time (Time) of stress application and the vertical axis represents the amount of change in threshold voltage (ΔVth).

As shown in FIG. 56A to FIG. 56D, it was confirmed that the amount of change in threshold voltage of Sample B in which the substrate temperature at the time of forming the insulating layer 225 was 400° C. was higher than that of Sample A in which the substrate temperature at the time of forming the insulating layer 225 was 300° C.

### <SIMS Analysis>

The indium concentration, the gallium concentration, and the zinc concentration in the insulating layer 225 in each of Sample A and Sample B were measured by secondary ion mass spectrometry (SIMS).

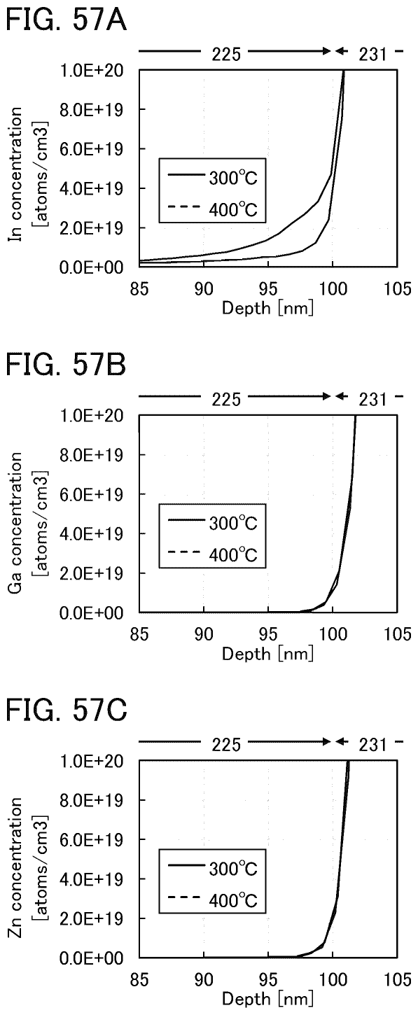

FIG. 57A shows the indium concentrations of Sample A and Sample B. FIG. 57B shows the gallium concentrations of Sample A and Sample B. FIG. 57C shows the zinc concentrations of Sample A and Sample B. In FIG. 57A to FIG. 57C, the horizontal axis represents a depth from the surface of the insulating layer 225 (Depth), the vertical axis represents the indium concentration (In concentration), the gallium concentration (Ga concentration), or the zinc concentration (Zn concentration).

As shown in FIG. 57A, it was confirmed that the indium concentration in the insulating layer 225 of Sample B in which the substrate temperature at the time of forming the insulating layer 225 was 400° C. was higher than that of Sample A in which the substrate temperature at the time of forming the insulating layer 225 was 300° C. Specifically, the indium concentration in the insulating layer 225 of Sample A (300° C.) was less than or equal to 2×10¹⁹ atoms/cm³, and the indium concentration in the insulating layer 225 of Sample B (400° C.) was less than or equal to 4×10¹⁹ atoms/cm³. It was found that both Sample A (300° C.) and Sample B (400° C.) had low gallium concentration in the insulating layer 225. If the substrate temperature at the time of forming the insulating layer 225 is high, the amount of indium diffused from the semiconductor layer 231 to the insulating layer 225 is probably increased.

### <Calculation of Defect State>

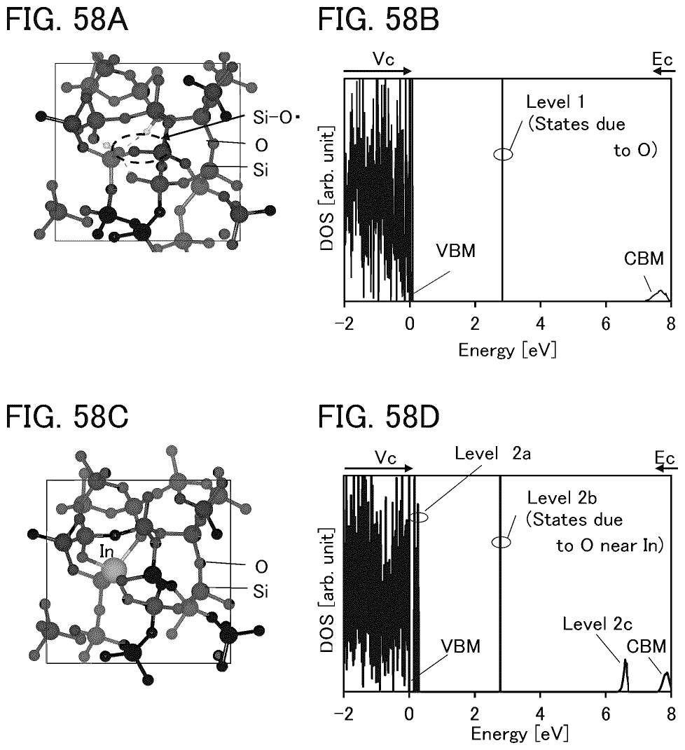

The defect state of the gate insulating layer was calculated by the first principles calculation. FIG. 58A shows the model of NBOHC used for the calculation, and FIG. 58C shows the model of In_{Si}. The models shown in FIG. 58A and FIG. 58C were based on amorphous SiO₂ of 60 atoms (20 silicon atoms and 40 oxygen atoms). For the calculation, a hybrid density functional theory (hybrid-DFT) method was used. In the hybrid-DFT method, the band gap value which is closer to the measured value than that of generalized gradient approximation (GGA) can be obtained.

FIG. 58B is a graph of the density of states of the model of NBOHC shown in FIG. 58A. FIG. 58D is a graph of the density of states of the model of In_{Si} shown in FIG. 58C. In FIG. 58B and FIG. 58D, the horizontal axis represents energy (Energy), and the vertical axis represents density of state (DOS). Note that in FIG. 58B and FIG. 58D, the valence band maximum (VBM) was adjusted to be 0 eV.

As shown in FIG. 58B, it was confirmed that a defect state at a deep position (a state 1 (States due to O) in FIG. 58B) exists in the model of NBOHC. This suggested that the defect state might be a state in which holes are trapped.

As shown in FIG. 58D, it was confirmed that a defect state at a deep position (a state 2b (States due to O near In) in FIG. 58D) and a defect state near VBM (a state 2a in FIG. 58D) exist in the model of InSi. This suggested that the defect state might be a state in which holes are trapped. Note that a defect state (a state 2c in FIG. 58D) near the conduction band minimum (CBM) is assumed to be an empty state in the steady state, which possibly becomes a state in which an electron is trapped.

### <Factorial Analysis of NBTIS Degradation>

Fitting with respect to the time dependence of the amount of change in threshold voltages shown in FIG. 56B and FIG. 56D was performed, and deterioration factors in the NBTIS test were analyzed. For the fitting, the exponential functions shown below were used.

$$\begin{matrix}[ Formula 1 ] & \\ \vert Δ Vth \vert = {A}_{1} \{ 1 - exp ( - \frac{t}{{τ}_{1}} ) \} & ( 1 )\end{matrix}$$

$$\vert Δ Vth \vert = {A}_{1} \{ 1 - exp ( - \frac{t}{{τ}_{1}} ) \} + {A}_{2} \{ 1 - exp ( - \frac{t}{{τ}_{2}} ) \} \qquad ( 2 )$$

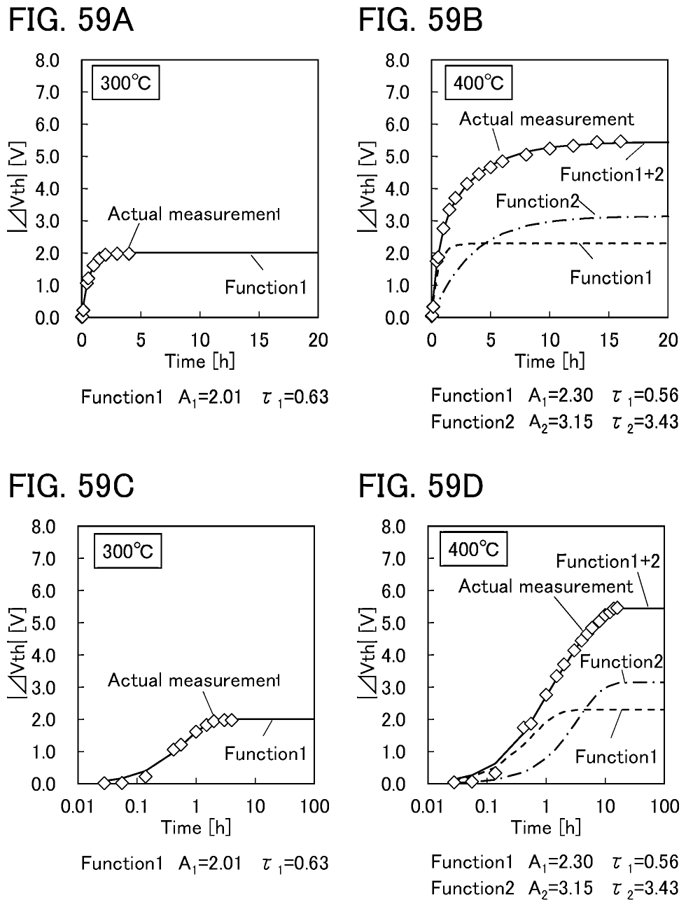

FIG. 59A shows an exponential function obtained by measured values and fitting of Sample A (300° C.). In FIG. 59A, the horizontal axis represents the cumulative time (Time) of stress application and the vertical axis represents the absolute value (|ΔVth|) of the amount of change in threshold voltage. The measured value (Actual measurement) is plotted, and the function obtained by the fitting is denoted by a solid line. As shown in FIG. 59A, Sample A (300° C.) substantially agrees with the measured value with one exponential function (Function 1). That is, the existence of one hole trap process involving NBTIS degradation in Sample A (300° C.) was confirmed.

FIG. 59B shows an exponential function obtained by measured values and fitting of Sample B (400° C.). In FIG. 59B, the horizontal axis represents the cumulative time (Time) of stress application and the vertical axis represents the absolute value (|ΔVth|) of the amount of change in threshold voltage. The measured value (Actual measurement) is plotted, and the functions obtained by the fitting are denoted by a solid line, a dashed line, and a dashed-dotted line. As shown in FIG. 59B, Sample B (400° C.) does not agree with the measured value with one exponential function (Function 1 or Function 2), and substantially agrees with the sum of two exponential functions (Function 1+Function 2). That is, the existence of two hole trap processes involving NBTIS degradation in Sample B (400° C.) was confirmed.

Note that in FIG. 59A and FIG. 59B, the horizontal axis represents time on a linear scale. FIG. 59C and FIG. 59D show graphs with time of the horizontal axis as a logarithm. As shown in FIG. 59C and FIG. 59D, even in the initial operation of the NBTIS test, the measured value and the functions obtained by fitting substantially agree with each other.

Table 1 shows the amounts of saturation changes (A₁ and A₂) in threshold voltage obtained by fitting and the time constants (τ₁ and τ₂). In Table 1, a smaller time constant of the two time constants obtained from Sample B (400° C.) is denoted by “τ₁”, the exponential function corresponding to the time constant τ₁ is denoted by “Function 1”, a larger time constant is denoted by “τ₂”, and the exponential function corresponding to the time constant τ₂ is denoted by “Function 2”. The time constant and the amount of saturation changes obtained from Sample A (300° C.) were approximately equal to the smaller time constant τ₁ and the amount of saturation change A₁ obtained from Sample B (400° C.); therefore, degradation factors of these are presumably the same. Note that degradation with a large time constant can be referred to as “slow degradation” and degradation with a small time constant can be referred to as “fast degradation”.

TABLE 1

| | | 300° C. | 400° C. |
|---|---|---|---|
| Function 1 | A₁ | 2.01 | 2.30 |
| (Fast degradation) | τ₁ | 0.63 | 0.56 |
| Function 2 | A₂ | — | 3.15 |
| (Slow degradation) | τ₂ | — | 3.43 |

In consideration of the indium concentration in the insulating layer 225 and the graph of density of states obtained by the first principles calculation, the slow degradation observed in Sample B (400° C.) is presumably derived from In_{Si}, and the fast degradations observed in Sample A (300° C.) and Sample B (400° C.) are presumably derived from factors other than In_{Si} (e.g., NBOHC or No).

In the case where a plurality of defect states serving as a hole trap exist in the insulating layer 225 functioning as the gate insulating layer, holes are presumably trapped in parallel from dDOS due to oxygen vacancies (Vo) in the metal oxide of the semiconductor layer 231 to the respective defect states (see FIG. 4B).

The structure described in this example can be combined with another embodiment or example as appropriate.

### Example 2

In this example, a display apparatus of one embodiment of the present invention was fabricated and its cross-sectional shape was observed.

For the structure of the samples used in this example, the description of the transistor 205R, the light-emitting device 130R, and the like illustrated in FIG. 9B can be referred to. Note that the insulating layer 239 illustrated in FIG. 14 and the like was provided over the insulating layer 235. For the fabrication method, the description of FIG. 21A to FIG. 22C and FIG. 23A to FIG. 38 can be referred to.

### <Fabrication of Samples>

First, the transistor 205R was formed. The conductive layer 221 had a structure in which an approximately 30-nm-thick copper film and an approximately 300-nm-thick tungsten film were stacked in this order. The insulating layer 211 had a structure in which an approximately 50-nm-thick first silicon nitride film, an approximately 230-nm-thick silicon nitride film, and an approximately 100-nm-thick silicon oxynitride film were stacked in this order. As the semiconductor layer 231, an approximately 20-nm-thick metal oxide film was used. As the insulating layer 225, an approximately 150-nm-thick silicon oxynitride film was used. The conductive layer 223 had a structure in which an approximately 50-nm-thick molybdenum film, an approximately 200-nm-thick aluminum film, and an approximately 50-nm-thick titanium film were stacked in this order. As the insulating layer 218, an approximately 300-nm-thick silicon nitride oxide film was used. The conductive layer 222a and the conductive layer 222b had a structure in which an approximately 100-nm-thick titanium film, an approximately 400-nm-thick aluminum film, and an approximately 100-nm-thick titanium film were stacked in this order.

Next, the insulating layer 214 was formed to cover the insulating layer 218, the conductive layer 222a, and the conductive layer 222b. The insulating layer 214 had a structure in which an approximately 200-nm-thick silicon oxynitride film and an approximately 2.0-μm-thick acrylic film were stacked in this order, and the opening 191R reaching the conductive layer 222b was provided.

Next, the conductive layer 233R was formed to cover the opening 191R. The conductive layer 233R had a structure in which an approximately 100-nm-thick titanium film, an approximately 400-nm-thick aluminum film, and an approximately 100-nm-thick titanium film were stacked in this order.

Then, the insulating layer 235 was formed to cover the insulating layer 214 and the conductive layer 233R. An approximately 2.0-μm-thick acrylic film was used as the insulating layer 235, and the opening 193R reaching the conductive layer 233R was provided.

Next, the insulating layer 239 was formed over the insulating layer 235. The insulating layer 239 had a structure in which an approximately 10-nm-thick silicon nitride film and an approximately 200-nm-thick silicon oxynitride film were stacked in this order, and an opening was provided in a region overlapping with the opening 193R.

Then, the conductive layer 112R was formed to cover the insulating layer 239 and the opening 193R. As the conductive layer 112R, an approximately 50-nm-thick ITSO film was used.

After that, the layer 128 was formed to fill a depressed portion of the conductive layer 112R. A polyimide film was used as the layer 128.

Next, the conductive layer 126R was formed to cover the conductive layer 112R and the layer 128. The conductive layer 126R had a structure in which an approximately 10-nm-thick ITSO film and an approximately 100-nm-thick APC film were stacked in this order.

Then, the conductive layer 129R was formed to cover the conductive layer 126R. Thus, the pixel electrode 111R including the conductive layer 112R, the conductive layer 126R, and the conductive layer 129R was formed. As the conductive layer 129R, an approximately 50-nm-thick ITSO film was used.

Next, the film 113Rf to be the layer 113R was formed to cover the pixel electrode 111R and the insulating layer 239. The layer 113R includes a light-emitting layer.

Next, the mask film 118Rf and the mask film 119Rf were formed. As the mask film 118Rf, a 30-nm-thick aluminum oxide film was used. As the mask film 119Rf, a 50-nm-thick In—Ga—Zn oxide film was used.

Then, the resist mask 190a was formed over the mask film 119Rf and the mask film 119Rf was processed using the resist mask 190a as a mask, whereby the mask layer 119R was formed.

Next, the resist mask 190a was removed.

Next, the mask film 118Rf and the film 113Rf were processed using the mask layer 119R as a mask, whereby the mask layer 118R and the layer 113R were formed.

Next, the insulating film 125f was formed. As the insulating film 125f, a 15-nm-thick aluminum oxide film was used.

Next, the insulating layer 127 was formed to fill a depressed portion of the insulating film 125f. As the insulating layer 127, a positive resist film was used.

Then, part of the insulating film 125f, part of the mask layer 119R, and part of the mask layer 118R were removed using the insulating layer 127 as a mask, whereby the layer 113R was exposed.

Next, the common layer 114, the common electrode 115, and the protective layer 131 were formed to cover the layer 113R and the insulating layer 127. As the common layer 114, an electron-injection layer was used. As the common electrode, a co-evaporation film of silver and magnesium was used. As the protective layer 131, an In—Ga—Zn oxide film was used.

Through the above process, the samples were obtained.

### <Observation of Cross-Sections of Samples>

Next, the samples were thinned by focused ion beam (FIB), and cross sections thereof were observed with a scanning transmission electron microscopy (STEM).

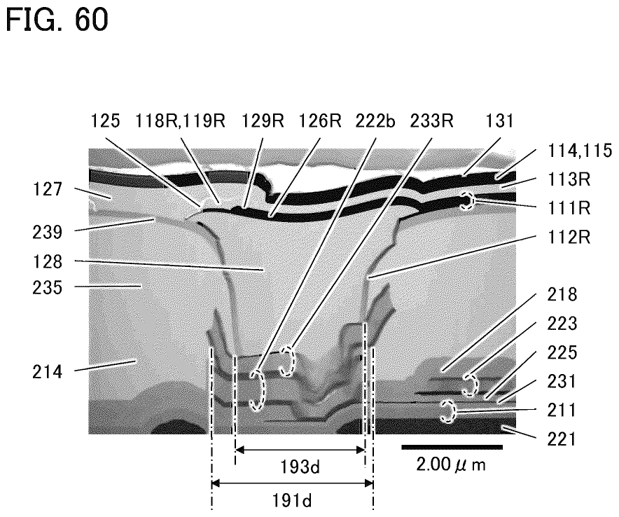

FIG. 60 shows a cross-sectional STEM image of the sample. FIG. 60 is an image of transmitted electrons (TE) at a magnification of 20000 times. As shown in FIG. 60, it was confirmed that the shape of the formation surface of the conductive layer 112R was gentle. The width 191d of the opening 191 was 3.15 μm, and the width 193d of the opening 193 was 2.54 μm.

Note that the insulating layer 214 and the insulating layer 235 were formed using the same material; therefore, the boundary between the insulating layer 214 and the insulating layer 235 is not clear in FIG. 60.

The structure described in this example can be combined with another embodiment or example as appropriate.

### REFERENCE NUMERALS

11B: subpixel, 11G: subpixel, 11R: subpixel, 11S: subpixel, 100G: display apparatus, 100H: display apparatus, 100J: display apparatus, 100: display apparatus, 101: layer, 110a: subpixel, 110b: subpixel, 110c: subpixel, 110d: subpixel, 110e: subpixel, 110: pixel, 111B: pixel electrode, 111G: pixel electrode, 111R: pixel electrode, 111S: pixel electrode, 111: pixel electrode, 112B: conductive layer, 112f: conductive film, 112G: conductive layer, 112p: conductive layer, 112R: conductive layer, 113_1: first region, 113_2: second region, 113B: layer, 113Bf: film, 113G: layer, 113Gf: film, 113R: layer, 113Rf: film, 113S: layer, 113W: layer, 113: layer, 114: common layer, 115: common electrode, 117: light-blocking layer, 118B: mask layer, 118Bf: mask film, 118G: mask layer, 118Gf: mask film, 118R: mask layer, 118Rf: mask film, 118S: mask layer, 118: mask layer, 119B: mask layer, 119Bf: mask film, 119G: mask layer, 119Gf: mask film, 119R: mask layer, 119Rf: mask film, 119S: mask layer, 119: mask layer, 120: substrate, 122: resin layer, 123: conductive layer, 124a: pixel, 124b: pixel, 125f: insulating film, 125: insulating layer, 126B: conductive layer, 126f: conductive film, 126G: conductive layer, 126p: conductive layer, 126R: conductive layer, 127f: insulating film, 127: insulating layer, 128f: film, 128: layer, 129aB: conductive layer, 129af: conductive film, 129aG: conductive layer, 129aR: conductive layer, 129B: conductive layer, 129bB: conductive layer, 129bf: conductive film, 129bG: conductive layer, 129bR: conductive layer, 129G: conductive layer, 129p: conductive layer, 129R: conductive layer, 130B: light-emitting device, 130G: light-emitting device, 130R: light-emitting device, 130: light-emitting device, 131: protective layer, 132a: mask, 132b: mask, 132B: coloring layer, 132c: mask, 132d: mask, 132G: coloring layer, 132R: coloring layer, 140: connection portion, 141a: opening, 141b: opening, 142: adhesive layer, 145: impurity element, 147: opening, 150: light-receiving device, 151B: fine metal mask, 151G: fine metal mask, 151R: fine metal mask, 151: substrate, 152: substrate, 153: insulating layer, 162: display portion, 164: circuit, 165: wiring, 166: conductive layer, 172: FPC, 173: IC, 190a: resist mask, 190b: resist mask, 190c: resist mask, 191B: opening, 191d: width, 191G: opening, 191R: opening, 191S: opening, 191: opening, 193B: opening, 193d: width, 193G: opening, 193R: opening, 193S: opening, 193: opening, 195a: resist mask, 195b: resist mask, 195c: resist mask, 195d: resist mask, 195e: resist mask, 195f: resist mask, 195g: resist mask, 201: transistor, 204: connection portion, 205B: transistor, 205G: transistor, 205R: transistor, 205S: transistor, 205: transistor, 211a: insulating film, 211b: insulating film, 211: insulating layer, 214f: insulating film, 214: insulating layer, 215: insulating layer, 218: insulating layer, 221: conductive layer, 222a: conductive layer, 222b: conductive layer, 223: conductive layer, 225: insulating layer, 227: metal oxide layer, 230: conductive layer, 231f: metal oxide film, 231i: channel formation region, 231l: region, 231n: low-resistance region, 231: semiconductor layer, 233B: conductive layer, 233f: conductive film, 233G: conductive layer, 233R: conductive layer, 233q: wiring, 233S: conductive layer, 233t: conductive layer, 233: conductive layer, 235f: insulating film, 235: insulating layer, 237: insulating layer, 238f: insulating film, 238: insulating layer, 239f: insulating film, 239: insulating layer, 242: connection layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 765: layer, 766: layer, 767: active layer, 768: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power supply button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a transistor;
a light-emitting device;
a first insulating layer;
a second insulating layer; and
a first conductive layer,
wherein the transistor comprises a semiconductor layer and a second conductive layer electrically connected to the semiconductor layer,
wherein the light-emitting device comprises a pixel electrode,
wherein the first insulating layer is provided over the transistor,
wherein the first insulating layer comprises a first opening reaching the second conductive layer,
wherein the first conductive layer covers the first opening,
wherein the second insulating layer is provided over the first insulating layer,
wherein the second insulating layer comprises a second opening in a region overlapping with the first opening,
wherein the pixel electrode covers a top surface of the second insulating layer and the second opening,
wherein the pixel electrode is electrically connected to the second conductive layer through the first conductive layer,
wherein in a cross-sectional view, an end portion of the first insulating layer on a first opening side is positioned over the second conductive layer,
wherein in the cross-sectional view, an end portion of the second insulating layer on a second opening side is positioned over the first conductive layer, and
wherein in the cross-sectional view, the end portion of the second insulating layer on the second opening side is positioned outward from the portion of the first insulating layer on the first opening side.

2. The display apparatus according to claim 1,
wherein each of the first insulating layer and the second insulating layer comprises an organic material.

3. The display apparatus according to claim 1, further comprising a layer,
wherein the pixel electrode comprises a third conductive layer and a fourth conductive layer over the third conductive layer,
wherein the third conductive layer covers a top surface of the second insulating layer and the second opening,
wherein the third conductive layer comprises a depressed portion along a shape of a side surface of the second insulating layer and a top surface of the second first conductive layer,
wherein the layer is provided to fill the depressed portion,
wherein the fourth conductive layer covers a top surface of the third conductive layer and a top surface of the layer, and
wherein the fourth conductive layer comprises a material having a property of reflecting visible light.

4. The display apparatus according to claim 2, further comprising a layer,
wherein the pixel electrode comprises a third conductive layer and a fourth conductive layer over the third conductive layer,
wherein the third conductive layer covers a top surface of the second insulating layer and the second opening,
wherein the third conductive layer comprises a depressed portion along a shape of a side surface of the second insulating layer and a top surface of the first conductive layer,
wherein the layer is provided to fill the depressed portion,
wherein the fourth conductive layer covers a top surface of the third conductive layer and a top surface of the layer, and
wherein the fourth conductive layer comprises a material having a property of reflecting visible light.

5. The display apparatus according to claim 3, wherein the layer is an insulating layer.

6. The display apparatus according to claim 3, wherein the layer is a conductive layer.

7. The display apparatus according to claim 1, further comprising a third insulating layer,
wherein the third insulating layer is provided in contact with the top surface of the second insulating layer,
wherein the third insulating layer comprises an inorganic material, and
wherein the pixel electrode comprises a region in contact with a top surface of the third insulating layer.

8. The display apparatus according to claim 1, further comprising a fourth insulating layer,
wherein the fourth insulating layer is provided in contact with a top surface of the first insulating layer,
wherein the fourth insulating layer comprises an inorganic material, and
wherein the first conductive layer comprises a region in contact with a top surface of the fourth insulating layer.

9. The display apparatus according to claim 1, further comprising:
a fifth insulating layer; and
a sixth insulating layer,
wherein the light-emitting device comprises the pixel electrode, a common electrode, and an EL layer interposed between the pixel electrode and the common electrode,
wherein the fifth insulating layer covers a side surface and part of a top surface of the EL layer,
wherein the sixth insulating layer covers a side surface and part of a top surface of the EL layer with the fifth insulating layer therebetween, and
wherein the common electrode covers the sixth insulating layer.

10. The display apparatus according to claim 9,
wherein the fifth insulating layer comprises an inorganic material, and
wherein the sixth insulating layer comprises an organic material.

11. The display apparatus according to claim 1, further comprising a fifth insulating layer,
wherein the light-emitting device comprises the pixel electrode, a common electrode, and an EL layer interposed between the pixel electrode and the common electrode,
wherein the fifth insulating layer covers a side surface and part of a top surface of the pixel electrode,
wherein the EL layer comprises a region in contact with a top surface of the fifth insulating layer, and
wherein the common electrode covers the fifth insulating layer.

12. The display apparatus according to claim 1,
wherein the transistor comprises a gate insulating layer interposed between the semiconductor layer and a gate electrode,
wherein the semiconductor layer comprises a metal oxide, and
wherein the concentration of a metal element included in the metal oxide in the gate insulating layer is lower than or equal to 2×10¹⁹ atoms/cm³.
